(19) United States
(12) Patent Application Publication
(10) Pub. No.: US 2025/0294891 A1
(43) Pub. Date: Sep. 18, 2025

(54) TVS DIODE

(71) Applicant: ROHM CO., LTD., Kyoto-shi (JP)

(72) Inventors: Keishi WATANABE, Kyoto-shi (JP); Kentaro WAKI, Kyoto-shi (JP); Satoki TANIGUCHI, Kyoto-shi (JP); Kohei MORITA, Kyoto-shi (JP)

(73) Assignee: ROHM CO., LTD., Kyoto-shi (JP)

(21) Appl. No.: 19/075,812

(22) Filed: Mar. 11, 2025

(30) Foreign Application Priority Data
Mar. 18, 2024 (JP) 2024-042495

(51) Int. Cl. H10D 89/60; H10D 8/01; H10D 8/50; H10D 62/10

(52) U.S. Cl. CPC H10D 89/60; H10D 8/50; H10D 62/115; H10D 62/126; H10D 8/043

(57) ABSTRACT

A semiconductor chip of a TVS diode includes a first surface and a second surface at aside opposite the first surface. The semiconductor chip includes first and second pin junctions fora first polarity direction, and a diode-paired region. The diode-paired region includes a high-concentration region of a first conductance type, first and second low-concentration regions that have a lower impurity concentration than the high-concentration region, an isolation region isolating the first and second low-concentration regions, first and second contact regions of a second conductance type, and an internal region of the second conductance type contacting the high-concentration region and arranged closer to the second surface than the high-concentration region. The internal region is arranged overlapping both the first and second low-concentration regions in plan view.

### CROSS-REFERENCE TO RELATED APPLICATION

This application is based upon and claims the benefit of priority from Japanese Patent Application No. 2024-042495, filed on Mar. 18, 2024, the entire contents of which are incorporated herein by reference.

### BACKGROUND

### 1. Field

The present disclosure is related to a TVS diode.

### 2. Description of Related Art

Japanese Laid-Open Patent Publication No. 2021-57490 discloses a diode chip including a transient voltage suppressor (TVS) circuit.

### BRIEF DESCRIPTION OF DRAWINGS

FIG. 1 is a schematic plan view of an exemplary TVS diode in accordance with a first embodiment.

FIG. 2 is a schematic cross-sectional view of the TVS diode taken along line F2-F2 in FIG. 1.

FIG. 3 is a schematic cross-sectional view of the TVS diode taken along line F3-F3 in FIG. 1.

FIG. 4 is a schematic plan view of a semiconductor chip.

FIG. 5 is a schematic cross-sectional view of the TVS diode taken along line F5-F5 in FIG. 3.

FIG. 6 is an enlarged, schematic cross-sectional view showing part of FIG. 5.

FIG. 7 is a schematic plan view of first to third connection electrodes and wiring that are arranged on the semiconductor chip.

FIG. 8 is a schematic circuit diagram of the TVS diode.

FIG. 9 is a schematic cross-sectional view illustrating an exemplary manufacturing step of the TVS diode in accordance with the first embodiment.

FIG. 10 is a schematic cross-sectional view illustrating a manufacturing step following the step of FIG. 9.

FIG. 11 is a schematic cross-sectional view illustrating a manufacturing step following the step of FIG. 10.

FIG. 12 is a schematic cross-sectional view illustrating a manufacturing step following the step of FIG. 11.

FIG. 13 is a schematic cross-sectional view illustrating a manufacturing step following the step of FIG. 12.

FIG. 14 is a schematic cross-sectional view illustrating a manufacturing step following the step of FIG. 13.

FIG. 15 is a schematic cross-sectional view illustrating a manufacturing step following the step of FIG. 14.

FIG. 16 is a schematic cross-sectional view illustrating a manufacturing step following the step of FIG. 15.

FIG. 17 is a schematic cross-sectional view illustrating a manufacturing step following the step of FIG. 16.

FIG. 18 is a schematic cross-sectional view illustrating a manufacturing step following the step of FIG. 17.

FIG. 19 is a schematic cross-sectional view illustrating a manufacturing step following the step of FIG. 18.

FIG. 20 is a schematic cross-sectional view illustrating a manufacturing step following the step of FIG. 19.

FIG. 21 is a schematic cross-sectional view illustrating a manufacturing step following the step of FIG. 20.

FIG. 22 is a schematic cross-sectional view illustrating a manufacturing step following the step of FIG. 21.

FIG. 23 is a schematic cross-sectional view illustrating a manufacturing step following the step of FIG. 22.

FIG. 24 is a schematic cross-sectional view illustrating a manufacturing step following the step of FIG. 23.

FIG. 25 is a schematic cross-sectional view illustrating a manufacturing step following the step of FIG. 24.

FIG. 26 is an enlarged, schematic cross-sectional view showing a diode-paired region of FIG. 2.

FIG. 27 is a schematic cross-sectional view showing a second pin junction and a third pin junction.

FIG. 28 is a schematic cross-sectional view of a TVS diode in accordance with a second embodiment.

FIG. 29 is a schematic cross-sectional view of the TVS diode at a position differing from FIG. 28.

FIG. 30 is an enlarged, schematic cross-sectional view showing part of FIG. 28.

FIG. 31 is a graph illustrating the position in the thickness direction of the semiconductor chip in relation to impurity concentration.

FIG. 32 is a schematic cross-sectional view illustrating an exemplary manufacturing step of the TVS diode in accordance with the second embodiment.

FIG. 33 is a schematic cross-sectional view illustrating a manufacturing step following the step of FIG. 32.

FIG. 34 is a schematic plan view of a semiconductor chip in a TVS diode in accordance with a third embodiment.

FIG. 35 is a schematic cross-sectional view of the TVS diode taken along line F35-F35 in FIG. 34.

FIG. 36 is a schematic cross-sectional view of the TVS diode taken along line F36-F36 in FIG. 34.

FIG. 37 is a schematic cross-sectional view illustrating an exemplary manufacturing step of the TVS diode in accordance with the third embodiment.

FIG. 38 is a schematic cross-sectional view illustrating a manufacturing step following the step of FIG. 37.

FIG. 39 is a schematic cross-sectional view illustrating a manufacturing step following the step of FIG. 38.

FIG. 40 is a schematic plan view of a semiconductor chip in a TVS diode in accordance with a fourth embodiment.

FIG. 41 is a schematic plan view of first to third connection electrodes and wiring that are arranged on the semiconductor chip.

FIG. 42 is a schematic cross-sectional view of the TVS diode taken along line F42-F42 in FIG. 40.

FIG. 43 is a schematic plan view of the TVS diode.

FIG. 44 is a schematic plan view of a semiconductor chip in a TVS diode in accordance with a fifth embodiment.

FIG. 45 is a schematic plan view of a first connection electrode, a second connection electrode, and wiring that are arranged on the semiconductor chip.

FIG. 46 is a schematic plan view of the TVS diode.

FIG. 47 is a schematic plan view of a semiconductor chip in a TVS diode in accordance with a sixth embodiment.

FIG. 48 is a schematic plan view of a first connection electrode, a second connection electrode, and wiring that are arranged on the semiconductor chip.

FIG. 49 is a schematic plan view of the TVS diode.

FIG. 50 is a schematic plan view of a semiconductor chip in a TVS diode in accordance with a seventh embodiment.

FIG. 51 is a schematic cross-sectional view of the TVS diode taken along line F51-F51 in FIG. 50.

FIG. 52 is a schematic plan view of first to fourth connection electrodes and wiring that are arranged on the semiconductor chip.

FIG. 53 is a schematic plan view of the TVS diode.

FIG. 54 is a schematic plan view of a semiconductor chip in a TVS diode in accordance with an eighth embodiment.

FIG. 55 is a schematic plan view of a first connection electrode, a second connection electrode, and wiring that are arranged on the semiconductor chip.

FIG. 56 is a schematic plan view of the TVS diode.

FIG. 57 is a schematic cross-sectional view showing a TVS diode of a modified example.

FIG. 58 is a schematic cross-sectional view showing a TVS diode of a modified example.

FIG. 59 is a schematic plan view of first to third connection electrodes and wiring that are arranged on a semiconductor chip in a TVS diode of a modified example.

FIG. 60 is a schematic cross-sectional view of the TVS diode taken along line F60-F60 in FIG. 59.

FIG. 61 is a schematic plan view showing a TVS diode of a modified example.

FIG. 62 is a schematic cross-sectional view of the TVS diode taken along line F62-F62 in FIG. 61.

FIG. 63 is a schematic cross-sectional view of the TVS diode taken along line F63-F63 in FIG. 61.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Several embodiments of a TVS diode will now be described with reference to the accompanying drawings. Elements in the figures are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description includes exemplary embodiments of devices, systems, and methods in accordance with the present disclosure. Further, this detailed description is illustrative and is not intended to limit embodiments of the present disclosure or the application and use of the embodiments.

In this specification, the phrase “at least one of” as used in this disclosure means “one or more” of a desired choice. As one example, the phrase “at least one of” as used in this disclosure means “only one of the two choices” or “both of the two choices” in a case where the number of choices is two. In another example, the phrase “at least one of” as used in this disclosure means “only one single choice” or “any combination of two or more choices” if the number of its choices is three or more.

In this specification, “the dimension (depth, width, length) of A is equal to the dimension (depth, width, length) of B,” and “the dimension (depth, width, length) of A and the dimension (depth, width, length) of B are equal” includes a relationship in which the difference between the dimension (depth, width, length) of A and the dimension (depth, width, length) of Bis, for example, within 10% of the dimension (depth, width, length) of A. Also, in the present disclosure, “the concentration of A is equal to the concentration of B” and “the concentration of A and the concentration of B are equal” includes a relationship in which the difference between the concentration of A and the concentration of B is, for example, within 10% of the concentration of A.

### First Embodiment

### Structure of the TVS Diode

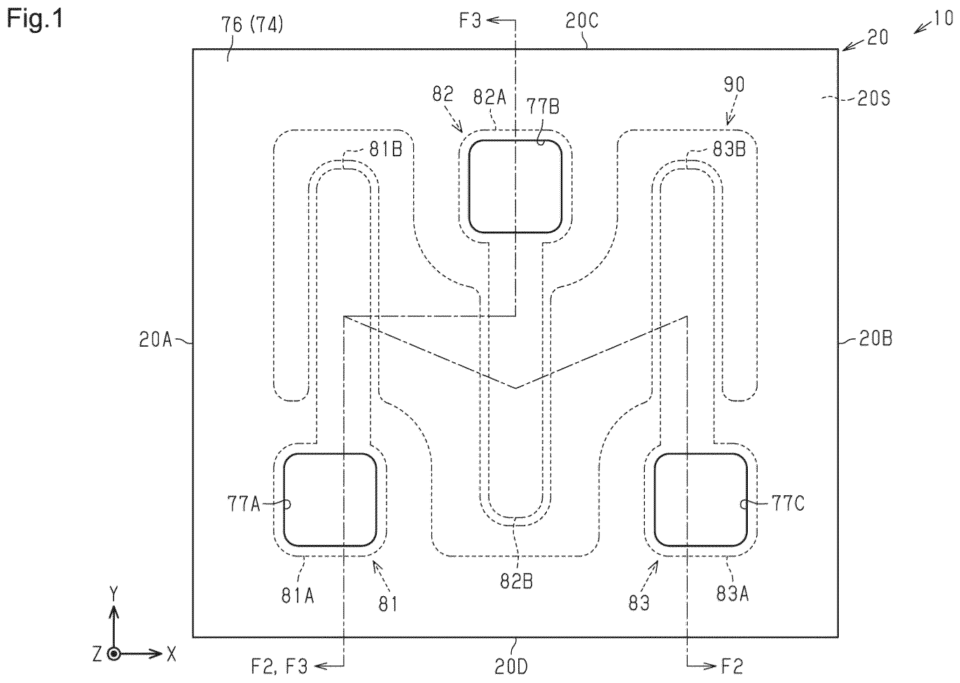

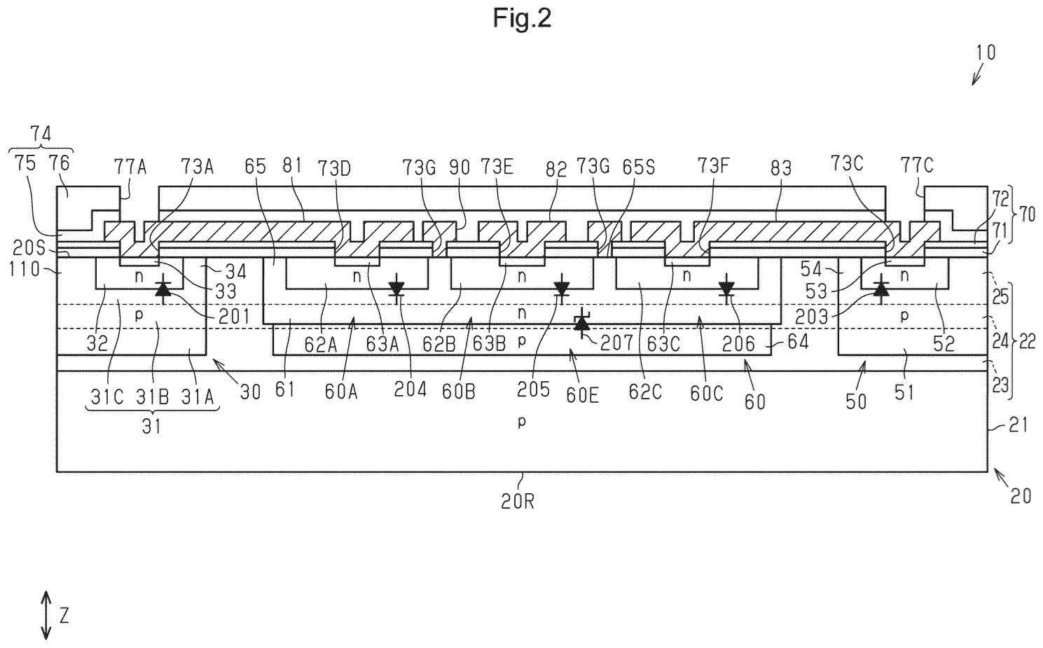

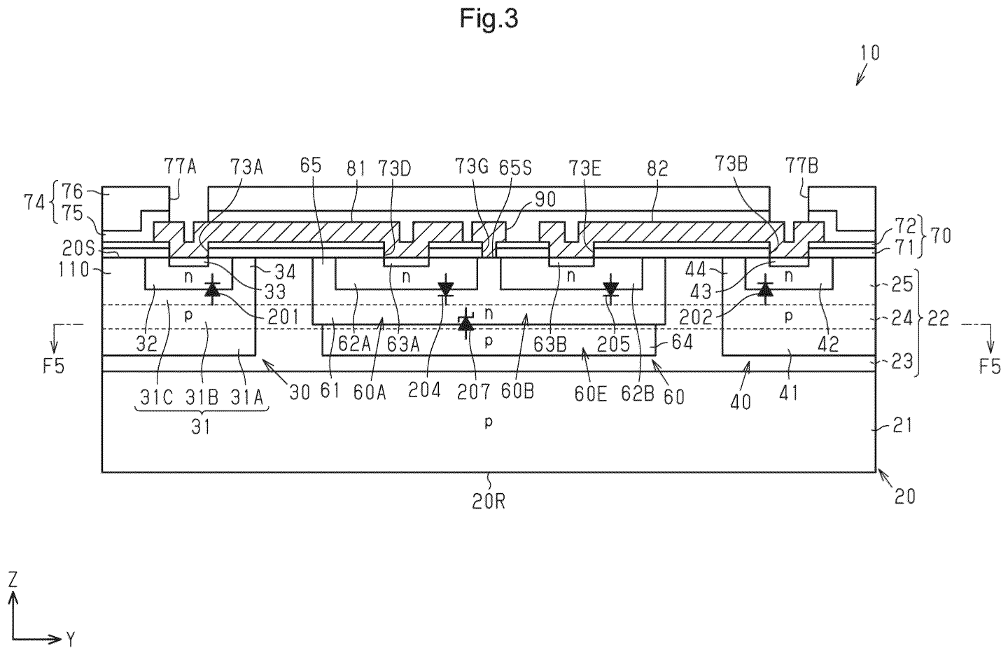

With reference to FIGS. 1 to 3, the structure of a TVS diode 10 in accordance with the first embodiment will now be described. FIG. 1 is a schematic plan view of the TVS diode 10. FIG. 2 is a schematic cross-sectional view taken along line F2-F2 in FIG. 1. FIG. 3 is a schematic cross-sectional view taken along line F3-F3 in FIG. 1.

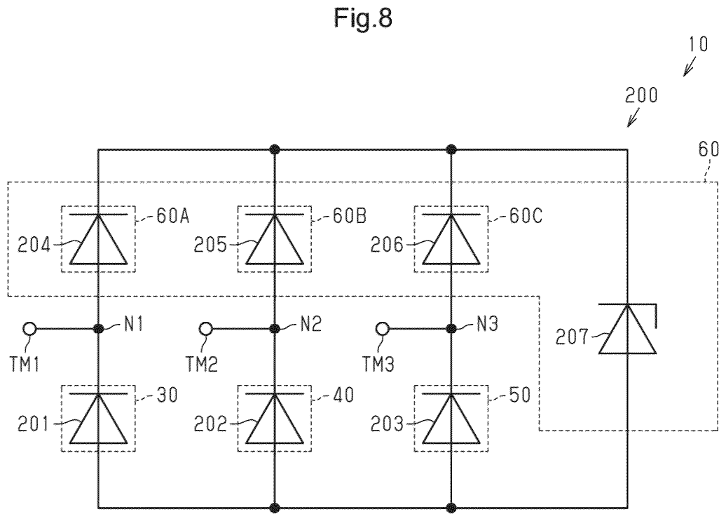

As shown in FIG. 1, the TVS diode 10 is a diode chip including a TVS circuit 200 (refer to FIG. 8) to protect electric circuits from electro-static discharge (ESD). The TVS circuit 200 will be described in detail later with reference to FIG. 8. The TVS diode 10 is used, for example, to protect an interface of an electronic gadget such as a wearable device, a smartphone, or the like.

The TVS diode 10 includes a semiconductor chip 20 having the form of a parallelepiped. The semiconductor chip 20 is composed of a material containing, for example, silicon (Si). The semiconductor chip 20 is a flat plate of which the thickness direction is the Z-direction. In the description hereafter, a view of the TVS diode 10 taken in the Z-direction will be referred to as “plan view.” Directions orthogonal to the Z-direction will be referred to as “the X-direction” and “the Y-direction,” which are orthogonal to each other. The X-direction is one example of “the second direction”, and the Y-direction is one example of “the first direction.”

The semiconductor chip 20 includes a first surface 20S, a second surface 20R (refer to FIG. 2) opposite the first surface 20S, and four side surfaces, namely, first to fourth side surfaces 20A to 20D, connecting the first surface 20S and the second surface 20R. In one example, the first surface 20S and the second surface 20R are planes orthogonal to the Z-direction. The first side surface 20A and the second side surface 20B define the two X-direction end surfaces of the semiconductor chip 20. The third side surface 20C and the fourth side surface 20D define the two Y-direction end surfaces of the semiconductor chip 20.

### Cross-Sectional Structure of the TVS Diode

As shown in FIGS. 2 and 3, the semiconductor chip 20 includes a semiconductor substrate 21 and a semiconductor layer 22 arranged on the semiconductor substrate 21.

The semiconductor substrate 21 is composed of a material containing silicon (Si). In one example, the semiconductor substrate 21 is a Si substrate. The semiconductor substrate 21 may be a silicon carbide (SiC) substrate. The semiconductor substrate 21 is a flat plate of which the thickness direction is the Z-direction. The semiconductor substrate 21 may have a thickness within a range from 10 μm to 800 m, inclusive. In one example, the thickness of the semiconductor substrate 21 is within a range from 30 μm to 400 m, inclusive.

The semiconductor substrate 21 contains p-type impurities. In one example, the semiconductor substrate 21 has a substantially constant p-type impurity concentration throughout. The p-type impurity concentration in the semiconductor substrate 21 may be within a range from 1×10¹⁹ cm⁻³ to 1×10²¹ cm⁻³, inclusive. In one example, the p-type impurity concentration in the semiconductor substrate 21 is within a range from 1×10¹⁹ cm⁻³ to 1×10²⁰ cm⁻³, inclusive.

The semiconductor layer 22 is formed by an epitaxial layer arranged on the semiconductor substrate 21. In one example, the semiconductor layer 22 has a laminate structure of a first semiconductor layer 23, a second semiconductor layer 24, and a third semiconductor layer 25. In FIGS. 2 and 3, the boundary of the first semiconductor layer 23 and the second semiconductor layer 24 and the boundary of the second semiconductor layer 24 and the third semiconductor layer 25 are each depicted by broken lines.

The first semiconductor layer 23 is formed by a p-type epitaxial layer arranged on the upper surface of the semiconductor substrate 21. The first semiconductor layer 23 may have a thickness within a range from 5 μm to 20 m, inclusive. In one example, the thickness of the first semiconductor layer 23 is within a range from 10 μm to 18 m, inclusive. In one example, the thickness of the first semiconductor layer 23 is approximately 15 m.

The p-type impurity concentration in the first semiconductor layer 23 is less than the p-type impurity concentration in the semiconductor substrate 21. The first semiconductor layer 23 has a concentration gradient, where the p-type impurity concentration decreases gradually from the semiconductor substrate 21 in the crystal growth direction. That is, the p-type impurity concentration in the first semiconductor layer 23 becomes lower at parts farther from the semiconductor substrate 21 in the Z-direction. The p-type impurity concentration in the first semiconductor layer 23 decreases at a rate that becomes greater as the semiconductor substrate 21 becomes farther. The p-type impurity concentration in the first semiconductor layer 23 decreases gradually until its minimum value is within a range from 1×10¹⁵ cm⁻³ to 1×10¹⁷ cm⁻³, inclusive. The minimum value of the p-type impurity concentration in the first semiconductor layer 23 may be, for example, within a range from 1×10¹⁶ cm⁻³ to 1×10¹⁷ cm⁻³, inclusive.

The second semiconductor layer 24 is formed by an n-type epitaxial layer arranged on the upper surface of the first semiconductor layer 23. The second semiconductor layer 24 may have a thickness within a range from 1 μm to 10 m, inclusive. In one example, the thickness of the second semiconductor layer 24 is within a range from 5 μm to 8 m, inclusive. In one example, the thickness of the second semiconductor layer 24 is approximately 7 m. In this case, the n-type is one example of “the first conductance type.” The second semiconductor layer 24 may be formed by a p-type epitaxial layer.

The second semiconductor layer 24 may have an n-type impurity concentration with a peak value within a range from 5×10¹⁴ cm⁻³ to 1×10¹⁵ cm⁻³, inclusive. In one example, the peak value of the n-type impurity concentration in the second semiconductor layer 24 is approximately 1×10¹⁵ cm⁻³. In one example, the n-type impurity concentration in the second semiconductor layer 24 increases gradually from the first semiconductor layer 23 toward the central part of the second semiconductor layer 24 in the Z-direction. The n-type impurity concentration in the second semiconductor layer 24 then decreases gradually from the central part of the second semiconductor layer 24 in the Z-direction toward the third semiconductor layer 25.

The third semiconductor layer 25 is formed by an n-type epitaxial layer arranged on the upper surface of the second semiconductor layer 24. The third semiconductor layer 25 includes the first surface 20S of the semiconductor chip 20. The third semiconductor layer 25 may have a thickness within a range from 5 μm to 20 m, inclusive. In one example, the thickness of the third semiconductor layer 25 is within a range from 8 μm to 15 m, inclusive. In one example, the thickness of the third semiconductor layer 25 is approximately 13 m. In this manner, the third semiconductor layer 25 may be thicker than the second semiconductor layer 24. The third semiconductor layer 25 may be thinner than the first semiconductor layer 23.

The third semiconductor layer 25 may have an n-type impurity concentration within a range from 1×10¹³ cm⁻³ to 1×10¹⁵ cm⁻³, inclusive. In one example, the n-type impurity concentration in the third semiconductor layer 25 is within a range from 5×10¹³ cm⁻³ to 5×10¹⁴ cm⁻³, inclusive. In one example, the n-type impurity concentration in the third semiconductor layer 25 is greater than or equal to 1×10¹⁴ cm⁻³ and less than 1×10¹⁵ cm⁻³. The n-type impurity concentration in the third semiconductor layer 25 gradually decreases as the second semiconductor layer 24 becomes farther in the Z-direction. That is, the peak of the n-type impurity concentration in the third semiconductor layer 25 is at a region contacting the second semiconductor layer 24 in the Z-direction. The n-type impurity concentration in the third semiconductor layer 25 becomes the minimum in a region located toward the first surface 20S. In one example, the minimum value of the n-type impurity concentration in the third semiconductor layer 25 is 1×10¹⁴ cm⁻³. In this manner, the minimum value of the n-type impurity concentration in the third semiconductor layer 25 is less than the minimum value of the n-type impurity concentration in the second semiconductor layer 24. In one example, the n-type impurity concentration in the third semiconductor layer 25 is less than the n-type impurity concentration in the second semiconductor layer 24.

The second semiconductor layer 24 and the third semiconductor layer 25 are both formed by n-type high-resistance layers having a relatively low n-type impurity concentration.

The second semiconductor layer 24 and the third semiconductor layer 25 may both have a resistivity within a range from 50 Ω·cm to 150 Ω·cm, inclusive. In one example, the resistivity of both the second semiconductor layer 24 and the third semiconductor layer 25 is within a range from 80 Ω·cm to 120 Ω·cm, inclusive.

### Pin Junction

As shown in FIGS. 2 and 3, the semiconductor chip 20 includes a first p-intrinsic-n (pin) junction 30, a second pin junction 40, and a third pin junction 50. The first pin junction 30, the second pin junction 40, and the third pin junction 50 each include an outer portion of the semiconductor chip 20 (region located toward first surface 20S in Z-direction and including first surface 20S of semiconductor chip 20). The first pin junction 30, the second pin junction 40, and the third pin junction 50 are each a region of the semiconductor chip 20 where a pin diode for a first polarity direction is formed. The first polarity direction is the direction in which forward current flows from the second surface 20R of the semiconductor chip 20 toward the first surface 20S.

As shown in FIG. 2, the first pin junction 30 includes a first terminal high-concentration region 31, a first terminal low-concentration region 32, a first terminal contact region 33, and a first partitioning region 34.

The first terminal high-concentration region 31 is a p-type region extending across the first semiconductor layer 23, the second semiconductor layer 24, and the third semiconductor layer 25 in the Z-direction. The first terminal high-concentration region 31 includes part of the first semiconductor layer 23 in the Z-direction, all of the second semiconductor layer 24 in the Z-direction, and part of the third semiconductor layer 25 in the Z-direction. Thus, the first terminal high-concentration region 31 is separated from the first surface 20S of the semiconductor chip 20 and located toward the second surface 20R. The first terminal high-concentration region 31 is separated from the semiconductor substrate 21 in the Z-direction. The first terminal high-concentration region 31 may be divided into a first region 31A, a second region 31B, and a third region 31C in the Z-direction. In this case, the p-type is one example of “the second conductance type.”

The first region 31A is located in an outer portion of the first semiconductor layer 23 (region close to second semiconductor layer 24 and including upper surface of first semiconductor layer 23). The first region 31A acts to maintain the p-type impurity concentration in the first semiconductor layer 23. That is, the first region 31A acts to maintain a predetermined p-type impurity concentration. The p-type impurity concentration in the first region 31A may be within a range from 1×10¹⁷ cm⁻³ to 1×10¹⁹ cm⁻³, inclusive. In one example, the p-type impurity concentration in the first region 31A is 1×1018 cm⁻³.

The second region 31B is arranged on the first region 31A and includes all of the second semiconductor layer 24 in the Z-direction. In one example, the second region 31B is formed so that the p-type impurity concentration gradually decreases as the first region 31A becomes farther in the Z-direction. Thus, the p-type impurity concentration in the second region 31B is less than or equal to the minimum value of the p-type impurity concentration in the first region 31A.

The third region 31C is a region of the third semiconductor layer 25 arranged on the second region 31B and located toward the second semiconductor layer 24. In one example, the p-type impurity concentration in the third region 31C gradually decreases as the second region 31B becomes farther in the Z-direction. Thus, the p-type impurity concentration in the third region 31C is less than or equal to the p-type impurity concentration in the second region 31B.

The first terminal low-concentration region 32 is arranged closer to the first surface 20S than the first terminal high-concentration region 31 is at a position overlapping the first terminal high-concentration region 31 in plan view. In one example, the first terminal low-concentration region 32 is arranged on the third region 31C. The first terminal low-concentration region 32 is an n-type region formed in the third semiconductor layer 25. The first terminal low-concentration region 32 is exposed from the first surface 20S of the semiconductor chip 20. Thus, the n-type impurity concentration in the first terminal low-concentration region 32 is equal to the n-type impurity concentration in the third semiconductor layer 25. Accordingly, the n-type impurity concentration in the first terminal low-concentration region 32 may be within a range from 1×10¹⁴ cm⁻³ to 1×10¹⁵ cm⁻³, inclusive.

The first terminal contact region 33 is an n-type region arranged in the outer portion of the first terminal low-concentration region 32. The first terminal contact region 33 is exposed from the first surface 20S of the semiconductor chip 20. The first terminal contact region 33 is separated from the first terminal high-concentration region 31 in the Z-direction.

The n-type impurity concentration in the first terminal contact region 33 is greater than the n-type impurity concentration in the first terminal low-concentration region 32. The peak value of the n-type impurity concentration in the first terminal contact region 33 may be within a range from 1×10¹⁸ cm⁻³ to 1×10²¹ cm⁻³, inclusive. In one example, the peak value of the n-type impurity concentration in the first terminal contact region 33 is within a range from 5×10¹⁸ cm-3 to 1×10²⁰ cm⁻³, inclusive.

In the first pin junction 30, the p-type first terminal high-concentration region 31 forms a P-layer of the pin diode, the n-type first terminal low-concentration region 32 forms an I-layer of the pin diode, and the n-type first terminal contact region 33 forms an N-layer of the pin diode. That is, the first terminal high-concentration region 31, the first terminal low-concentration region 32, and the first terminal contact region 33 form a pin junction in the Z-direction. Thus, the first terminal high-concentration region 31, the first terminal low-concentration region 32, and the first terminal contact region 33 form a pin diode for the first polarity direction (diode 201) in the first pin junction 30.

The first partitioning region 34 is a p-type region surrounding the first terminal low-concentration region 32. The first partitioning region 34 partitions the first terminal low-concentration region 32 from the third semiconductor layer 25 outside the first pin junction 30. The first partitioning region 34 is arranged closer to the first surface 20S than the first terminal high-concentration region 31 is at a position overlapping the first terminal high-concentration region 31 in plan view. The first partitioning region 34 is separated from the first terminal contact region 33 in plan view. The first partitioning region 34 is arranged surrounding the first terminal contact region 33 in plan view.

The p-type impurity concentration in the first partitioning region 34 may be greater than the p-type impurity concentration in the third region 31C of the first terminal high-concentration region 31. In one example, the p-type impurity concentration in the first partitioning region 34 may be within a range from 1×10¹⁷ cm⁻³ to 1×10¹⁸ cm⁻³, inclusive. The p-type impurity concentration in the first partitioning region 34 may be varied within a range allowing the first terminal low-concentration region 32 to be partitioned from the third semiconductor layer 25.

In the first pin junction 30, the first partitioning region 34, the first terminal low-concentration region 32, and the first terminal contact region 33 form a pin diode. The first pin junction 30 includes a first current path in which forward current flows sequentially through the first terminal high-concentration region 31, the first terminal low-concentration region 32, and the first terminal contact region 33, and a second current path in which forward current flows sequentially through the first partitioning region 34, the first terminal low-concentration region 32, and the first terminal contact region 33.

As shown in FIG. 3, the second pin junction 40 includes a p-type second terminal high-concentration region 41, an n-type second terminal low-concentration region 42, an n-type second terminal contact region 43, and a p-type second partitioning region 44. The second terminal high-concentration region 41 is separated from the first surface 20S of the semiconductor chip 20 and located toward the second surface 20R. The second terminal high-concentration region 41 is separated from the first terminal high-concentration region 31 in plan view. The second terminal low-concentration region 42 is arranged closer to the first surface 20S than the second terminal high-concentration region 41 is at a position overlapping the second terminal high-concentration region 41 in plan view. The second terminal contact region 43 is arranged in an outer portion of the second terminal low-concentration region 42. The second partitioning region 44 is arranged closer to the first surface 20S than the second terminal high-concentration region 41 is at a position overlapping the second terminal high-concentration region 41 in plan view. The second partitioning region 44 surrounds the second terminal low-concentration region 42 in plan view. The second terminal high-concentration region 41, the second terminal low-concentration region 42, and the second terminal contact region 43 form a pin diode (diode 202) in the second pin junction 40. In the second pin junction 40, the second partitioning region 44, the second terminal low-concentration region 42, and the second terminal contact region 43 form a further pin diode.

The second terminal high-concentration region 41, the second terminal low-concentration region 42, the second terminal contact region 43, and the second partitioning region 44 are identical in structure to the first terminal high-concentration region 31, the first terminal low-concentration region 32, the first terminal contact region 33, and the first partitioning region 34 of the first pin junction 30 and thus will not be described in detail.

As shown in FIG. 2, the third pin junction 50 includes a p-type third terminal high-concentration region 51, an n-type third terminal low-concentration region 52, an n-type third terminal contact region 53, and a p-type third partitioning region 54. The third terminal high-concentration region 51 is separated from the first surface 20S of the semiconductor chip 20 and located toward the second surface 20R. The third terminal high-concentration region 51 is separated from both the first terminal high-concentration region 31 and the second terminal high-concentration region 41 in plan view. The third terminal low-concentration region 52 is arranged closer to the first surface 20S than the third terminal high-concentration region 51 is at a position overlapping the third terminal high-concentration region 51 in plan view. The third terminal contact region 53 is arranged in an outer portion of the third terminal low-concentration region 52. The third partitioning region 54 is arranged closer to the first surface 20S than the third terminal high-concentration region 51 is at a position overlapping the third terminal high-concentration region 51 in plan view. The third partitioning region 54 surrounds the third terminal low-concentration region 52 in plan view. The third terminal high-concentration region 51, the third terminal low-concentration region 52, and the third terminal contact region 53 forma pin diode (diode 203) in the third pin junction 50. In the third pin junction 50, the third partitioning region 54, the third terminal low-concentration region 52, and the third terminal contact region 53 form a further pin diode.

The third terminal high-concentration region 51, the third terminal low-concentration region 52, the third terminal contact region 53, and the third partitioning region 54 are identical in structure to the first terminal high-concentration region 31, the first terminal low-concentration region 32, the first terminal contact region 33, and the first partitioning region 34 and thus will not be described in detail.

### Diode-Paired Region

As shown in FIGS. 2 and 3, the semiconductor chip 20 includes a diode-paired region 60 separated from each of the first pin junction 30, the second pin junction 40, and the third pin junction 50 in plan view. The diode-paired region 60 is arranged in an outer portion of the semiconductor chip 20.

The diode-paired region 60 includes a first reverse pin junction 60A, a second reverse pin junction 60B, a third reverse pin junction 60C, and a pn junction 60E. The first reverse pin junction 60A, the second reverse pin junction 60B, and the third reverse pin junction 60C are each a region of the semiconductor chip 20 where a pin diode for a second polarity direction is formed. The second polarity direction is the direction in which forward current flows from the first surface 20S of the semiconductor chip 20 toward the second surface 20R. That is, the second polarity direction is opposite the first polarity direction.

The diode-paired region 60 includes a high-concentration region 61, a first low-concentration region 62A, a second low-concentration region 62B, a third low-concentration region 62C, a first contact region 63A, a second contact region 63B, a third contact region 63C, an internal region 64, and an isolation region 65. The high-concentration region 61, the first low-concentration region 62A, the second low-concentration region 62B, the third low-concentration region 62C, the first contact region 63A, the second contact region 63B, the third contact region 63C, the internal region 64, and the isolation region 65 form the first reverse pin junction 60A, the second reverse pin junction 60B, the third reverse pin junction 60C, and the pn junction 60E.

The high-concentration region 61 is an n-type region separated from the first surface 20S of the semiconductor chip 20 and arranged toward the second surface 20R. The high-concentration region 61 is separated from the first semiconductor layer 23 in the Z-direction toward the first surface 20S. The high-concentration region 61 extends across the second semiconductor layer 24 and the third semiconductor layer 25 in the Z-direction. The high-concentration region 61 includes part of the third semiconductor layer 25 in the Z-direction.

The n-type impurity concentration in the high-concentration region 61 is greater than the n-type impurity concentration in the second semiconductor layer 24. The n-type impurity concentration in the high-concentration region 61 is greater than the n-type impurity concentration in the third semiconductor layer 25. The n-type impurity concentration in the high-concentration region 61 may have a peak value within a range from 1×1018 cm⁻³ to 1×10²¹ cm⁻³, inclusive. In one example, the peak value of the n-type impurity concentration in the high-concentration region 61 is within a range from 5×10¹⁸ cm⁻³ to 1×10²⁰ cm⁻³, inclusive.

The first to third low-concentration regions 62A to 62C are n-type regions arranged closer to the first surface 20S than the high-concentration region 61 is. The first to third low-concentration regions 62A to 62C are separated from one another in plan view. The first to third low-concentration regions 62A to 62C are each arranged at a position overlapping the high-concentration region 61 in plan view. The first to third low-concentration regions 62A to 62C are each exposed from the first surface 20S of the semiconductor chip 20. The first to third low-concentration regions 62A to 62C are formed in the third semiconductor layer 25. Thus, the n-type impurity concentration in each of the first to third low-concentration regions 62A to 62C may be equal to the n-type impurity concentration in the third semiconductor layer 25. Accordingly, the n-type impurity concentration in each of the first to third low-concentration regions 62A to 62C may be within the range from 1×10¹⁴ cm⁻³ to 1×10¹⁵ cm⁻³, inclusive. In one example, the n-type impurity concentration in each of the first to third low-concentration regions 62A to 62C is 1×10¹⁴ cm⁻³.

The first contact region 63A is a p-type region arranged in an outer portion of the first low-concentration region 62A. The first contact region 63A is exposed from the first surface 20S of the semiconductor chip 20. The first contact region 63A is separated from the high-concentration region 61 in the Z-direction. The p-type impurity concentration in the first contact region 63A is greater than the n-type impurity concentration in the first low-concentration region 62A.

The second contact region 63B is a p-type region arranged in an outer portion of the second low-concentration region 62B. The second contact region 63B is exposed from the first surface 20S of the semiconductor chip 20. The second contact region 63B is separated from the high-concentration region 61 in the Z-direction. The p-type impurity concentration in the second contact region 63B is greater than the n-type impurity concentration in the second low-concentration region 62B. The p-type impurity concentration in the second contact region 63B is equal to the p-type impurity concentration in the first contact region 63A.

The third contact region 63C is a p-type region arranged in an outer portion of the third low-concentration region 62C. The third contact region 63C is exposed from the first surface 20S of the semiconductor chip 20. The third contact region 63C is separated from the high-concentration region 61 in the Z-direction. The p-type impurity concentration in the third contact region 63C is greater than the n-type impurity concentration in the third low-concentration region 62C. The p-type impurity concentration in the third contact region 63C is equal to the p-type impurity concentration in the first contact region 63A.

The p-type impurity concentration in each of the first to third contact regions 63A to 63C may have a peak value within a range from 1×10¹⁸ cm⁻³ to 1×10²¹ cm⁻³, inclusive. In one example, the peak value of the p-type impurity concentration in each of the first to third contact regions 63A to 63C is within a range from 5×10¹⁸ cm⁻³ to 1×10²⁰ cm⁻³, inclusive.

In the first reverse pin junction 60A, the p-type first contact region 63A forms a P-layer of the pin diode, the n-type first low-concentration region 62A forms an I-layer of the pin diode, and the n-type high-concentration region 61 forms an N-layer of the pin diode. That is, the first contact region 63A, the first low-concentration region 62A, and the high-concentration region 61 form a pin junction in the Z-direction. Thus, the high-concentration region 61, the first low-concentration region 62A, and the first contact region 63A form a pin diode for the second polarity direction (diode 204) in the first reverse pin junction 60A.

In the second reverse pin junction 60B, the p-type second contact region 63B forms a P-layer of the pin diode, the n-type second low-concentration region 62B forms an I-layer of the pin diode, and the n-type high-concentration region 61 forms an N-layer of the pin diode. That is, the second contact region 63B, the second low-concentration region 62B, and the high-concentration region 61 form a pin junction in the Z-direction. Thus, the high-concentration region 61, the second low-concentration region 62B, and the second contact region 63B form a pin diode for the second polarity direction (diode 205) in the second reverse pin junction 60B.

In the third reverse pin junction 60C, the p-type third contact region 63C forms a P-layer of the pin diode, the n-type third low-concentration region 62C forms an I-layer of the pin diode, and the n-type high-concentration region 61 forms an N-layer of the pin diode. That is, the third contact region 63C, the third low-concentration region 62C, and the high-concentration region 61 form a pin junction in the Z-direction. Thus, the high-concentration region 61, the third low-concentration region 62C, and the third contact region 63C form a pin diode for the second polarity direction (diode 206) in the third reverse pin junction 60C.

The internal region 64 is a p-type region arranged in contact with the high-concentration region 61 and is closer to the second surface 20R of the semiconductor chip 20 than the high-concentration region 61 is. The internal region 64 is arranged at a position overlapping the high-concentration region 61 in plan view. The internal region 64 extends in the Z-direction across the outer portion of the first semiconductor layer 23 and a region of the second semiconductor layer 24 located toward the first semiconductor layer 23. The internal region 64 is arranged overlapping each of the first low-concentration region 62A, the second low-concentration region 62B, and the third low-concentration region 62C in plan view.

The internal region 64 acts to maintain the p-type impurity concentration in the first semiconductor layer 23. That is, the internal region 64 acts to maintain a predetermined p-type impurity concentration. The p-type impurity concentration in the internal region 64 may be within a range from 1×10¹⁶ cm⁻³ to 1×10¹⁹ cm⁻³, inclusive. In one example, the p-type impurity concentration in the internal region 64 is 1×10¹⁸ cm⁻³. The p-type impurity concentration in the internal region 64 may be equal to the p-type impurity concentration in the first region 31A of the first terminal high-concentration region 31 in the first pin junction 30.

The pn junction 60E includes the p-type internal region 64 and the n-type high-concentration region 61. That is, the internal region 64 and the high-concentration region 61 forma pn junction in the Z-direction. Thus, the internal region 64 and the high-concentration region 61 form a pn diode for the first polarity direction (diode 207). The pn diode is connected in a reverse direction to the pin diode of the first reverse pin junction 60A, the pin diode of the second reverse pin junction 60B, and the pin diode of the third reverse pin junction 60C. Thus, the pn junction 60E is connected in a reverse direction to the first reverse pin junction 60A, the second reverse pin junction 60B, and the third reverse pin junction 60C. The p-type impurity concentration in the internal region 64 sets the breakdown voltage at the pn junction 60E. That is, the p-type impurity concentration in the internal region 64 is adjusted in accordance with the desired breakdown voltage at the pn junction 60E.

The isolation region 65 is an n-type region arranged closer to the first surface 20S than the high-concentration region 61 is. The isolation region 65 is arranged at a position continuous with the high-concentration region 61 in plan view. The isolation region 65 isolates the first low-concentration region 62A, the second low-concentration region 62B, and the third low-concentration region 62C from one another. The isolation region 65 surround each of the first low-concentration region 62A, the second low-concentration region 62B, and the third low-concentration region 62C in plan view.

The n-type impurity concentration in the isolation region 65 may have a peak value that is equal to the peak value of the n-type impurity concentration in the high-concentration region 61. In one example, the peak value of the n-type impurity concentration in the isolation region 65 may be within a range from 1×10¹⁸ cm⁻³ to 1×10²¹ cm⁻³, inclusive. In one example, the peak value of the n-type impurity concentration in the isolation region 65 may be within a range from 5×10¹⁸ cm⁻³ to 1×10²⁰ cm⁻³, inclusive.

In the first reverse pin junction 60A, among the first contact region 63A, the first low-concentration region 62A, and the isolation region 65, the part surrounding the first low-concentration region 62A forms a pin diode. The first reverse pin junction 60A includes a first current path in which forward current flows sequentially through the first contact region 63A, the first low-concentration region 62A, and the high-concentration region 61, and a second current path in which forward current flows sequentially through the first contact region 63A, the first low-concentration region 62A, and the isolation region 65.

In the second reverse pin junction 60B, among the second contact region 63B, the second low-concentration region 62B, and the isolation region 65, the part surrounding the second low-concentration region 62B forms a pin diode. The second reverse pin junction 60B includes a first current path in which forward current flows sequentially through the second contact region 63B, the second low-concentration region 62B, and the high-concentration region 61, and a second current path in which forward current flows sequentially through the second contact region 63B, the second low-concentration region 62B, and the isolation region 65.

In the third reverse pin junction 60C, among the third contact region 63C, the third low-concentration region 62C, and the isolation region 65, the part surrounding the third low-concentration region 62C forms a pin diode. The third reverse pin junction 60C includes a first current path in which forward current flows sequentially through the third contact region 63C, the third low-concentration region 62C, and the high-concentration region 61, and a second current path in which forward current flows sequentially through the third contact region 63C, the third low-concentration region 62C, and the isolation region 65.

The cathode of the pin diode in the first reverse pin junction 60A, the cathode of the pin diode in the second reverse pin junction 60B, and the cathode of the pin diode in the third reverse pin junction 60C are each connected to the cathode of the pn diode in the pn junction 60E. Thus, the first to third reverse pin junctions 60A to 60C each form a diode pair with the pn junction 60E.

### Structure on Semiconductor Chip

The TVS diode 10 includes an insulation layer 70 covering the first surface 20S of the semiconductor chip 20. The insulation layer 70 may have a laminate structure formed by laminated insulation layers or a monolayer structure formed by a single insulation layer. The insulation layer 70 may include at least one of a silicon oxide (SiO₂) layer or a silicon nitride (SiN) layer. The insulation layer 70 may have a laminate structure formed by laminating a SiO₂ and SiN layers in any order. The insulation layer 70 may have a monolayer structure formed by a SiO₂ layer or a SiN layer. The insulation layer 70 may have a thickness within a range from 1 m to 10 μm, inclusive. In one example, the thickness of the insulation layer 70 is within a range from 2 μm to 3 μm, inclusive.

In one example, the insulation layer 70 has a laminate structure including a first insulation layer 71 and a second insulation layer 72.

The first insulation layer 71 is in contact with the first surface 20S of the semiconductor chip 20. The first insulation layer 71 has a monolayer structure formed by a single SiO₂ layer.

The first insulation layer 71 is also referred to as a field oxide film. The first insulation layer 71 may have a thickness of, for example, 14000 angstroms.

The second insulation layer 72 is arranged on the first insulation layer 71. The second insulation layer 72 may include at least one of an undoped silica glass (USG) layer, a phosphor silicate glass (PSG) layer, and a boron phosphor silicate glass (BPSG) layer. In one example, the second insulation layer 72 has a laminate structure formed by a USG layer and a BPSG layer. The second insulation layer 72 may be, for example, thinner than the first insulation layer 71. The second insulation layer 72 may have a thickness of, for example, 6700 angstroms.

The insulation layer 70 includes first to sixth openings 73A to 73F and wiring openings 73G exposing the first surface 20S of the semiconductor chip 20. Each of the first to sixth openings 73A to 73F and the wiring openings 73G extends through the insulation layer 70 in the Z-direction.

The first opening 73A exposes the first terminal contact region 33 of the first pin junction 30. The second opening 73B exposes the second terminal contact region 43 of the second pin junction 40. The third opening 73C exposes the third terminal contact region 53 of the third pin junction 50. The fourth opening 73D exposes the first contact region 63A of the first reverse pin junction 60A. The fifth opening 73E exposes the second contact region 63B of the second reverse pin junction 60B. The sixth opening 73F exposes the third contact region 63C of the third reverse pin junction 60C.

The wiring openings 73G expose the isolation region 65 of the diode-paired region 60. The isolation region 65 includes an exposed surface 65S exposed from the first surface 20S of the semiconductor chip 20.

The TVS diode 10 includes a first connection electrode 81, a second connection electrode 82, and a third connection electrode 83, which are arranged on the insulation layer 70. The first to third connection electrodes 81 to 83 are each composed of a material containing, for example, at least one of copper (Cu) and aluminum (Al). In one example, the first to third connection electrodes 81 to 83 are each composed of AlCu. The first to third connection electrodes 81 to 83 may each have a thickness of, for example, 42000 angstroms.

The first connection electrode 81 electrically connects the first terminal contact region 33 of the first pin junction 30 and the first contact region 63A of the first reverse pin junction 60A. The first connection electrode 81 contacts the first terminal contact region 33 through the first opening 73A in the insulation layer 70. The first connection electrode 81 contacts the first contact region 63A through the fourth opening 73D in the insulation layer 70.

The second connection electrode 82 electrically connects the second terminal contact region 43 of the second pin junction 40 and the second contact region 63B of the second reverse pin junction 60B. The second connection electrode 82 contacts the second terminal contact region 43 through the second opening 73B in the insulation layer 70. The second connection electrode 82 contacts the second contact region 63B through the fifth opening 73E in the insulation layer 70.

The third connection electrode 83 electrically connects the third terminal contact region 53 of the third pin junction 50 and the third contact region 63C of the third reverse pin junction 60C. The third connection electrode 83 contacts the third terminal contact region 53 through the third opening 73C in the insulation layer 70. The third connection electrode 83 contacts the third contact region 63C through the sixth opening 73F in the insulation layer 70.

The TVS diode 10 includes wiring 90 connected to the exposed surface 65S in the isolation region 65 of the diode-paired region 60. The wiring 90 is composed of a material containing at least one of Cu and Al. In one example, the wiring 90 is composed of AlCu. Thus, the wiring 90 may be composed of the same material as the first to third connection electrodes 81 to 83. The structure of the wiring 90 will be described in detail later.

The TVS diode 10 includes a protection layer 74 covering the insulation layer 70, the first to third connection electrodes 81 to 83, and the wiring 90. The protection layer 74 is an insulation layer protecting the semiconductor chip 20. The protection layer 74 may have a laminate structure formed by laminated insulation layers or a monolayer structure formed by a single insulation layer.

In one example, the protection layer 74 has a laminate structure including a first protection layer 75 and a second protection layer 76. In one example, the first protection layer 75 may be a passivation layer, and the second protection layer 76 may be a resin layer.

The first protection layer 75 may have a monolayer structure formed by a SiO₂ layer or a SiN layer, or a laminate structure formed by laminating SiO₂ and SiN layers in any order. In one example, the first protection layer 75 has a monolayer structure formed by a SiN layer.

The second protection layer 76 may contain a photosensitive resin. The second protection layer 76 may contain at least one of polyimide (PI), polyamide (PA), and polybenzoxazole (PBO) as an example of the photosensitive resin. In one example, the second protection layer 76 contains PI.

The protection layer 74 includes first to third terminal openings 77A to 77C. The first to third terminal openings 77A to 77C extend through the protection layer 74 in the Z-direction. The first terminal opening 77A partially exposes the first connection electrode 81. The first terminal opening 77A is located at a position overlapping the first opening 73A of the insulation layer 70 in plan view. The second terminal opening 77B partially exposes the second connection electrode 82. The second terminal opening 77B is located at a position overlapping the second opening 73B of the insulation layer 70 in plan view. The third terminal opening 77C partially exposes the third connection electrode 83. The third terminal opening 77C is located at a position overlapping the third opening 73C of the insulation layer 70 in plan view.

### Planar Structure of the TVS Diode

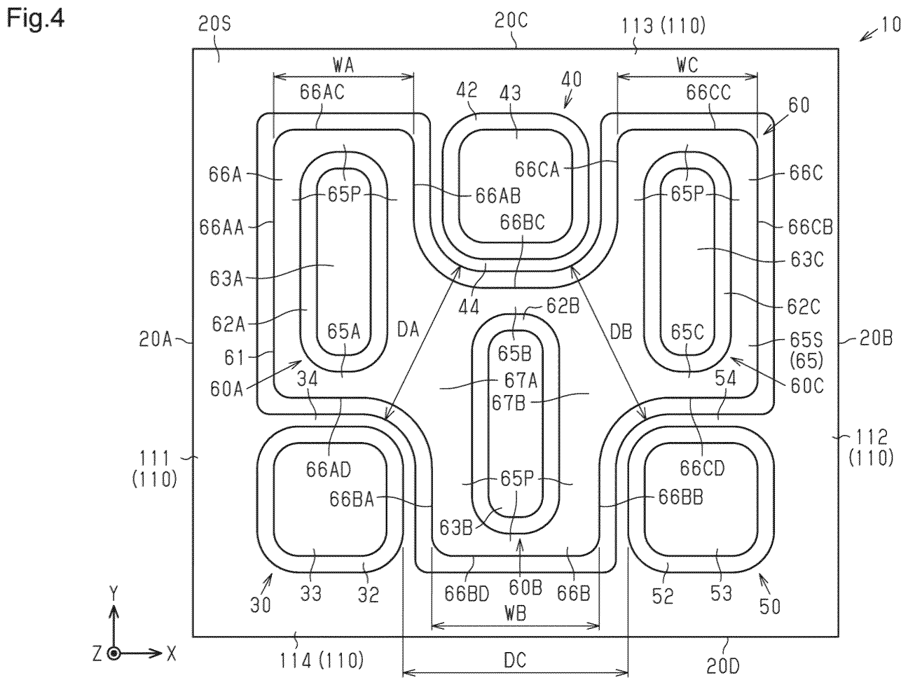

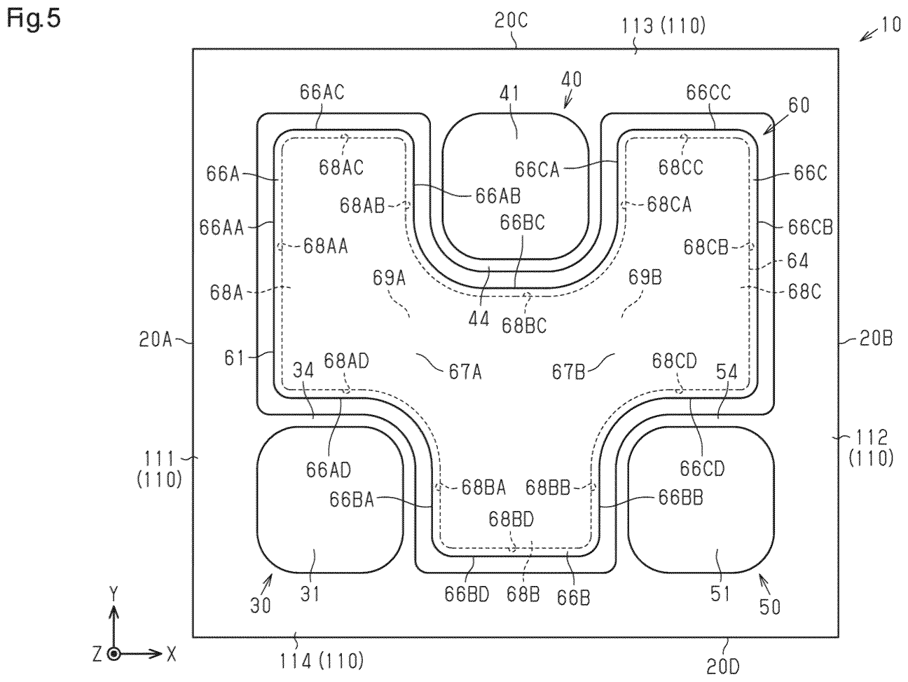

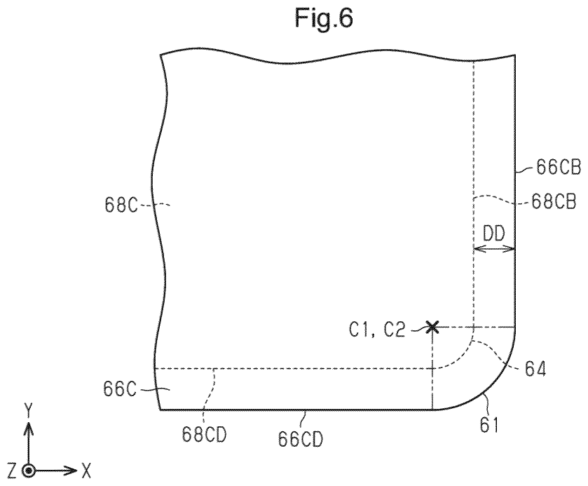

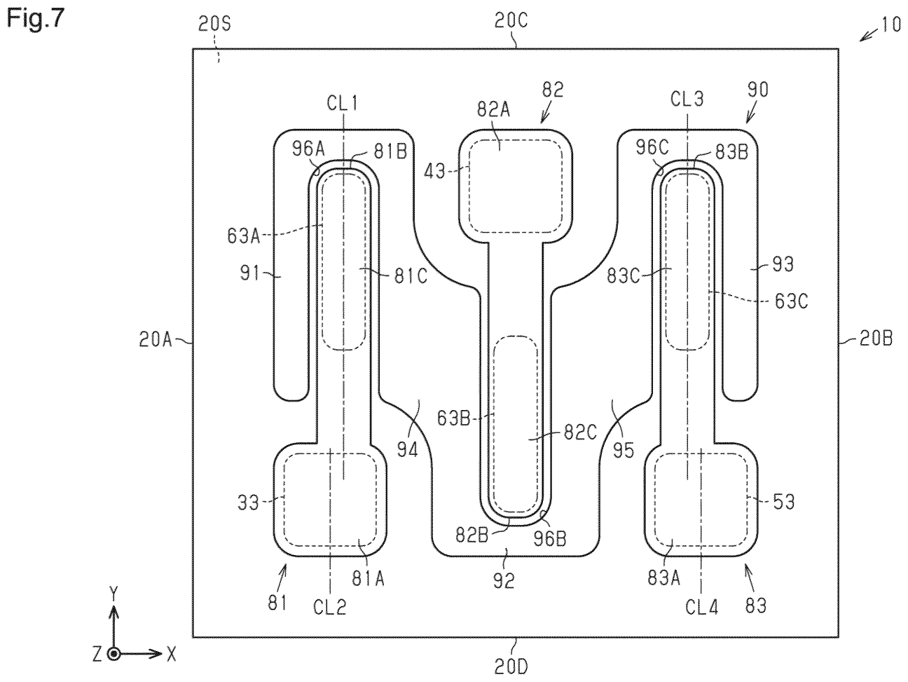

With reference to FIGS. 1 and 4 to 7, the planar structure of the TVS diode 10 will now be described. FIG. 4 is a schematic plan view showing the first surface 20S of the semiconductor chip 20. FIG. 5 is a schematic cross-sectional view of the semiconductor chip 20 taken along line F5-F5 in FIG. 3. FIG. 6 is a schematic cross-sectional view showing the high-concentration region 61 and the internal region 64 of FIG. 5 enlarged in part. Hatching lines are not shown in FIGS. 5 and 6 to aid understanding of the drawings. FIG. 7 is a schematic plan view of the first to third connection electrodes 81 to 83 and the wiring 90 of the TVS diode 10.

### Semiconductor Chip

As shown in FIG. 4, the TVS diode 10 includes a peripheral region 110 at the periphery of the first surface 20S of the semiconductor chip 20. The peripheral region 110 includes p-type impurities. The peripheral region 110 surrounds the first pin junction 30, the second pin junction 40, the third pin junction 50, and the diode-paired region 60 in plan view.

The peripheral region 110 is integrated with the first terminal high-concentration region 31 (refer to FIG. 2) and the first partitioning region 34 of the first pin junction 30, the second terminal high-concentration region 41 (refer to FIG. 3) and the second partitioning region 44 of the second pin junction 40, and the third terminal high-concentration region 51 (refer to FIG. 2) and the third partitioning region 54 of the third pin junction 50. The p-type impurity in the peripheral region 110 has a concentration gradient similar to that of the first terminal high-concentration region 31 and the first partitioning region 34.

The peripheral region 110, in plan view, includes a first region 111 extending along the first side surface 20A, a second region 112 extending along the second side surface 20B, a third region 113 extending along the third side surface 20C, and a fourth region 114 extending along the fourth side surface 20D.

The first pin junction 30, the second pin junction 40, and the third pin junction 50 are separated from one another. More specifically, the first pin junction 30 and the third pin junction 50 are located at the same position in the Y-direction and separated from each other in the X-direction. The first pin junction 30 and the third pin junction 50 are arranged close to the one of the two Y-direction ends of the first surface 20S of the semiconductor chip 20 located toward the fourth side surface 20D. The first pin junction 30 is arranged close to the one of the two X-direction ends of the first surface 20S located toward the first side surface 20A. The third pin junction 50 is arranged close to the one of the two X-direction ends of the first surface 20S located toward the second side surface 20B.

The second pin junction 40 is separated from both the first pin junction 30 and the third pin junction 50 in the X-direction and the Y-direction. The second pin junction 40 is arranged close to the one of the two Y-direction ends of the first surface 20S of the semiconductor chip 20 located toward the third side surface 20C. The second pin junction 40 is arranged at the middle of the first surface 20S with respect to the X-direction. Thus, the second pin junction 40 is located between the first pin junction 30 and the third pin junction 50 in the X-direction, as viewed in the Y-direction.

The first partitioning region 34 of the first pin junction 30 is connected to the first region 111 and the fourth region 114 of the peripheral region 110. The first terminal low-concentration region 32 of the first pin junction 30 is defined by the first region 111, the fourth region 114, and the first partitioning region 34 in plan view. The first partitioning region 34 includes a first part connected to the first region 111 and extending in the X-direction, a second part connected to the fourth region 114 and extending in the Y-direction, and a connecting part connecting the first part and the second part. The connecting part is curved in plan view.

The first terminal low-concentration region 32 is quadrilateral in plan view. The quadrilateral first terminal low-concentration region 32 has four curved corners. The first terminal contact region 33 is quadrilateral in plan view. The quadrilateral first terminal contact region 33 has four curved corners. The first terminal contact region 33 is slightly smaller than the first terminal low-concentration region 32 in plan view.

The second partitioning region 44 of the second pin junction 40 is connected to the third region 113 of the peripheral region 110. The second partitioning region 44 is U-shaped and open toward the third region 113 in plan view. The second terminal low-concentration region 42 of the second pin junction 40 is defined by the third region 113 and the second partitioning region 44 in plan view. The second partitioning region 44 includes a first part and a second part connected to the third region 113 and extending in the Y-direction, and a third part separated from the third region 113 toward the fourth side surface 20D and extending in the X-direction. The first part and the second part are separated from each other in the X-direction. The second partitioning region 44 includes a first connecting part connecting the first part and the third part, and a second connecting part connecting the second part and the third part. Each connecting part is curved in plan view.

The second terminal low-concentration region 42 is quadrilateral in plan view. The quadrilateral second terminal low-concentration region 42 has four curved corners. The second terminal low-concentration region 42 may have, for example, the same size and shape as the first terminal low-concentration region 32. The second terminal contact region 43 is quadrilateral in plan view. The quadrilateral second terminal contact region 43 has four curved corners. The second terminal contact region 43 is slightly smaller than the second terminal low-concentration region 42 in plan view. The second terminal contact region 43 may have, for example, the same size and shape as the first terminal contact region 33.

The third partitioning region 54 of the third pin junction 50 is connected to the second region 112 and the fourth region 114 of the peripheral region 110. The third terminal low-concentration region 52 of the third pin junction 50 is defined by the second region 112, the fourth region 114, and the third partitioning region 54 in plan view. The third partitioning region 54 includes a first part connected to the second region 112 and extending in the X-direction, a second part connected to the fourth region 114 and extending in the Y-direction, and a connecting part connecting the first part and the second part. The connecting part is curved in plan view.

The third terminal low-concentration region 52 is quadrilateral in plan view. The quadrilateral third terminal low-concentration region 52 has four curved corners. The third terminal low-concentration region 52 may have, for example, the same size and shape as the first terminal low-concentration region 32. The third terminal contact region 53 is quadrilateral in plan view. The quadrilateral third terminal contact region 53 has four curved corners. The third terminal contact region 53 is slightly smaller than the third terminal low-concentration region 52 in plan view. The third terminal contact region 53 may have, for example, the same size and shape as the first terminal contact region 33.

In one example, the shortest distance DA between the first partitioning region 34 and the second partitioning region 44 is equal to the shortest distance DB between the second partitioning region 44 and the third partitioning region 54. The shortest distance DC between the first partitioning region 34 and the third partitioning region 54 may be less than or equal to the shortest distance DA and the shortest distance DB.

The diode-paired region 60 is surrounded by the peripheral region 110, the first partitioning region 34, the second partitioning region 44, and the third partitioning region 54 in plan view. Thus, the diode-paired region 60 is arranged between the first pin junction 30 and the second pin junction 40, between the second pin junction 40 and the third pin junction 50, and between the first pin junction 30 and the third pin junction 50.

The diode-paired region 60 includes a first region 66A, a second region 66B, and a third region 66C.

The first region 66A is arranged next to the first pin junction 30 in the Y-direction. The first region 66A is located closer to the third side surface 20C than the first pin junction 30 is.

The first reverse pin junction 60A is arranged in the first region 66A. Thus, the first pin junction 30 and the first reverse pin junction 60A are arranged next to each other in the Y-direction in plan view. The first region 66A includes a part arranged next to the second pin junction 40 in the X-direction. The first region 66A is located closer to the first side surface 20A than the second pin junction 40 is in the X-direction. As viewed in the X-direction, part of the first reverse pin junction 60A overlaps the second pin junction 40.

The first region 66A is substantially rectangular in plan view. In one example, the first region 66A is substantially rectangular, and longer in the Y-direction and shorter in the X-direction. The first region 66A includes first to fourth sides 66AA to 66AD. The first side 66AA of the first region 66A is located toward the first side surface 20A and extends in the Y-direction in plan view. The second side 66AB of the first region 66A is located toward the second side surface 20B and extends in the Y-direction in plan view. The second side 66AB is shorter in length in the Y-direction than the first side 66AA. The third side 66AC of the first region 66A is located toward the third side surface 20C and extends in the X-direction in plan view. The fourth side 66AD of the first region 66A is located toward the fourth side surface 20D and extends in the X-direction in plan view. The fourth side 66AD is shorter in length in the X-direction than the third side 66AC.

The first region 66A includes a corner between the first side 66AA and the third side 66AC, a corner between the first side 66AA and the fourth side 66AD, and a corner between the second side 66AB and the third side 66AC. Each corner is curved in plan view.

The second region 66B is arranged next to the second pin junction 40 in the Y-direction. The second region 66B is located closer to the fourth side surface 20D than the second pin junction 40 is. The second reverse pin junction 60B is arranged in the second region 66B. Thus, the second pin junction 40 and the second reverse pin junction 60B are arranged next to each other in the Y-direction in plan view. The second region 66B includes a part located between the first pin junction 30 and the third pin junction 50 in the X-direction. That is, the second region 66B includes a part shifted from the first region 66A in the Y-direction. The second region 66B is located closer to the second side surface 20B than the first region 66A is in the X-direction. As viewed in the X-direction, part of the second reverse pin junction 60B overlaps both the first pin junction 30 and the third pin junction 50.

The second region 66B is substantially rectangular in plan view. In one example, the second region 66B is substantially rectangular, and longer in the Y-direction and shorter in the X-direction. The second region 66B includes the first to fourth sides 66BA to 66BD. The first side 66BA of the second region 66B is located toward the first side surface 20A and extends in the Y-direction in plan view. The first side 66BA is equal in length in the Y-direction to, for example, the second side 66AB of the first region 66A. The second side 66BB of the second region 66B is located toward the second side surface 20B and extends in the Y-direction in plan view. The second side 66BB is equal in length in the Y-direction to, for example, the first side 66BA. The third side 66BC of the second region 66B is located toward the third side surface 20C and extends in the X-direction in plan view. The fourth side 66BD of the second region 66B is located toward the fourth side surface 20D and extends in the X-direction in plan view. The first side 66BA, the second side 66BB, and the fourth side 66BD are each located closer to the fourth side surface 20D than the first region 66A is in the Y-direction. The fourth side 66BD is longer in length in the X-direction than the third side 66BC. The third side 66BC is shorter in length in the X-direction than the third side 66AC of the first region 66A.

The second region 66B includes a corner between the first side 66BA and the fourth side 66BD, and a corner between the second side 66BB and the fourth side 66BD. Each corner is curved in plan view.

The third region 66C is arranged next to the third pin junction 50 in the Y-direction. The third region 66C is located closer to the third side surface 20C than the third pin junction 50 is. The third region 66C and the first region 66A are located at the same position in the Y-direction. The third region 66C is separated from the first region 66A in the X-direction. The third reverse pin junction 60C is arranged in the third region 66C. Thus, the third pin junction 50 and the third reverse pin junction 60C are arranged next to each other in the Y-direction in plan view. The third region 66C includes a part arranged next to the second pin junction 40 in the X-direction. The third region 66C is located closer to the second side surface 20B than the second pin junction 40 is in the X-direction. Thus, the second pin junction 40 is located between the first region 66A and the third region 66C in the X-direction. As viewed in the X-direction, part of the third reverse pin junction 60C overlaps the second pin junction 40.

The third region 66C is substantially rectangular in plan view. In one example, the third region 66C is substantially rectangular, and longer in the Y-direction and shorter in the X-direction. The third region 66C includes first to fourth sides 66CA to 66CD. The first side 66CA of the third region 66C is located toward the first side surface 20A and extends in the Y-direction in plan view. The first side 66CA is equal in length in the Y-direction to, for example, the second side 66AB of the first region 66A. The second side 66CB of the third region 66C is located toward the second side surface 20B and extends in the Y-direction in plan view. The second side 66CB is longer in length in the Y-direction than the first side 66CA. The second side 66CB is equal in length in the Y-direction to, for example, the first side 66AA of the first region 66A. The third side 66CC of the third region 66C is located toward the third side surface 20C and extends in the X-direction in plan view. The fourth side 66CD of the third region 66C is located toward the fourth side surface 20D and extends in the X-direction in plan view. The third side 66CC is longer in length in the X-direction than the fourth side 66CD. The third side 66CC is equal in length in the X-direction to, for example, the third side 66AC of the first region 66A. The fourth side 66CD is equal in length in the X-direction to, for example, the fourth side 66AD of the first region 66A.

The third region 66C includes a corner between the first side 66CA and the third side 66CC, a corner between the second side 66CB and the fourth side 66CD, and a corner between the second side 66CB and the third side 66CC. Each corner is curved in plan view.

In the example shown in FIG. 4, the width WB (dimension in X-direction) of the second region 66B is greater than the width WA (dimension in X-direction) of the first region 66A and the width WC (dimension in X-direction) of the third region 66C. Further, the width WA of the first region 66A is equal to the width WC of the third region 66C. The width WA of the first region 66A, the width WB of the second region 66B, and the width WC of the third region 66C may each be varied. In one example, the width WA of the first region 66A may differ from the width WC of the third region 66C. In one example, the width WB of the second region 66B may be equal to the width WA of the first region 66A. In one example, the width WB of the second region 66B may be equal to the width WC of the third region 66C.

The diode-paired region 60 includes a first connecting region 67A, which connects the first region 66A and the second region 66B, and a second connecting region 67B, which connects the second region 66B and the third region 66C. The first connecting region 67A is located between the first region 66A and the second region 66B in the X-direction, and the second connecting region 67B is located between the second region 66B and the third region 66C in the X-direction. The first connecting region 67A is located between the first pin junction 30 and the second pin junction 40 in plan view in a direction intersecting both the X-direction and the Y-direction. The second connecting region 67B is located between the second pin junction 40 and the third pin junction 50 in plan view in a direction intersecting both the X-direction and the Y-direction.

The first connecting region 67A connects the second side 66AB of the first region 66A and the third side 66BC of the second region 66B, and connects the fourth side 66AD of the first region 66A and the first side 66BA of the second region 66B. The two Y-direction ends of the first connecting region 67A are curved in plan view. The two Y-direction ends of the first connecting region 67A have a greater radius of curvature than the corners of the first region 66A.

The second connecting region 67B connects the second side 66BB of the second region 66B and the fourth side 66CD of the third region 66C, and connects the third side 66BC of the second region 66B and the first side 66CA of the third region 66C. The two Y-direction ends of the second connecting region 67B are curved in plan view. The two Y-direction ends of the second connecting region 67B have a greater radius of curvature than the corners of the third region 66C.

The first low-concentration region 62A of the first reverse pin junction 60A is oblong in plan view, and longer in the Y-direction and shorter in the X-direction. In one example, the first low-concentration region 62A has a smaller X-direction dimension (width) than the first terminal low-concentration region 32 of the first pin junction 30. In one example, the width of the first low-concentration region 62A is less than the X-direction dimension of the first terminal contact region 33 of the first pin junction 30. In one example, the first low-concentration region 62A has a greater Y-direction dimension (length) than the first terminal low-concentration region 32.

The first contact region 63A of the first reverse pin junction 60A is oblong in plan view, and longer in the Y-direction and shorter in the X-direction. The first contact region 63A is slightly smaller than the first low-concentration region 62A in plan view. The first contact region 63A has a smaller X-direction dimension (width) than the first terminal contact region 33. The first contact region 63A has a greater Y-direction dimension (length) than the first terminal low-concentration region 32.

The second reverse pin junction 60B is located closer to the fourth side surface 20D than the first reverse pin junction 60A is. Further, part of the second reverse pin junction 60B overlaps the first reverse pin junction 60A in the X-direction. More specifically, the second low-concentration region 62B and the second contact region 63B of the second reverse pin junction 60B both include a part overlapping both the first low-concentration region 62A and the first contact region 63A of the first reverse pin junction 60A.

The second low-concentration region 62B is oblong in plan view, and longer in the Y-direction and shorter in the X-direction. In one example, the second low-concentration region 62B has a smaller X-direction dimension (width) than the second terminal low-concentration region 42 of the second pin junction 40. In one example, the second low-concentration region 62B has a smaller width than the second terminal contact region 43 of the second pin junction 40. In one example, the second low-concentration region 62B has a greater Y-direction dimension (length) than the second terminal low-concentration region 42. In one example, the second low-concentration region 62B is equal in width and length to the first low-concentration region 62A.

The second contact region 63B is oblong in plan view, and longer in the Y-direction and shorter in the X-direction. The second contact region 63B is slightly smaller than the second low-concentration region 62B in plan view. The second contact region 63B has a smaller X-direction dimension (width) than the second terminal contact region 43. The second contact region 63B has a greater Y-direction dimension (length) than the second terminal low-concentration region 42. In one example, the second contact region 63B is equal in width and length to the first contact region 63A.

The third reverse pin junction 60C is located closer to the third side surface 20C than the second reverse pin junction 60B is. Further, part of the third reverse pin junction 60C overlaps the second reverse pin junction 60B as viewed in the X-direction. More specifically, the third low-concentration region 62C and the third contact region 63C of the third reverse pin junction 60C both include a part overlapping both the second low-concentration region 62B and the second contact region 63B. Further, the third reverse pin junction 60C and the first reverse pin junction 60A are located at the same position in the Y-direction.

The third low-concentration region 62C is oblong in plan view, and longer in the Y-direction and shorter in the X-direction. In one example, the third low-concentration region 62C has a smaller X-direction dimension (width) than the third terminal low-concentration region 52 of the third pin junction 50. In one example, the third low-concentration region 62C has a smaller width than the third terminal contact region 53 of the third pin junction 50 in the X-direction dimension. In one example, the third low-concentration region 62C has a greater Y-direction dimension (length) than the third terminal low-concentration region 52. In one example, the third low-concentration region 62C is equal in width and length to the first low-concentration region 62A.

The third contact region 63C is oblong in plan view, and longer in the Y-direction and shorter in the X-direction. The third contact region 63C is slightly smaller than the third low-concentration region 62C in plan view. The third contact region 63C has a smaller X-direction dimension (width) than the third terminal contact region 53. The third contact region 63C has a greater Y-direction dimension (length) than the third terminal low-concentration region 52. In one example, the third contact region 63C is equal in width and length to the first contact region 63A.

The high-concentration region 61 has the same area as the diode-paired region 60 in plan view. The high-concentration region 61 has the same size and shape in plan view as the diode-paired region 60.

The isolation region 65 is the part of the high-concentration region 61 excluding the first low-concentration region 62A, the second low-concentration region 62B, the third low-concentration region 62C, the first contact region 63A, the second contact region 63B, and the third contact region 63C in plan view. Thus, the isolation region 65 includes both the first connecting region 67A and the second connecting region 67B in plan view. The isolation region 65 extends along the entire periphery of the diode-paired region 60 (high-concentration region 61). The isolation region 65 entirely surrounds the first low-concentration region 62A in the first region 66A. The isolation region 65 entirely surrounds the second low-concentration region 62B in the second region 66B. The isolation region 65 entirely surrounds the third low-concentration region 62C in the third region 66C.

The isolation region 65 has, in plan view, an area that is greater than the total area of the first low-concentration region 62A, the second low-concentration region 62B, and the third low-concentration region 62C.

As shown in FIG. 5, the internal region 64 overlaps each of the first region 66A, the second region 66B, and the third region 66C in plan view. The internal region 64 overlaps both the first connecting region 67A and the second connecting region 67B in plan view. In one example, the internal region 64 is slightly smaller than the high-concentration region 61 in plan view.

In the same manner as the diode-paired region 60, the internal region 64 includes a first region 68A, a second region 68B, a third region 68C, a first connecting region 69A, and a second connecting region 69B.

The first region 68A is located at a position overlapping the first region 66A in plan view. The first region 68A is slightly smaller than the first region 66A in plan view. The first region 68A includes the first to fourth sides 68AA to 68AD. The first to fourth sides 68AA to 68AD respectively correspond to the first to fourth sides 66AA to 66AD of the first region 66A. The first to fourth sides 68AA to 68AD are located inward from the first to fourth sides 66AA to 66AD of the first region 66A in plan view. That is, the first region 68A is arranged within the first region 66A in plan view. Further, the first region 68A entirely overlaps the first low-concentration region 62A (refer to FIG. 4) in plan view.

The second region 68B is located at a position overlapping the second region 66B in plan view. The second region 68B is slightly smaller than the second region 66B in plan view. The second region 68B includes first to fourth sides 68BA to 68BD. The first to fourth sides 68BA to 68BD respectively correspond to the first to fourth sides 66BA to 66BD of the second region 66B. The first to fourth sides 68BA to 68BD are located inward from the first to fourth sides 66BA to 66BD of the second region 66B in plan view. That is, the second region 68B is arranged within the second region 66B in plan view. Further, the second region 68B entirely overlaps the second low-concentration region 62B (refer to FIG. 4) in plan view.

The third region 68C is located at a position overlapping the third region 66C in plan view. The third region 68C is slightly smaller than the third region 66C in plan view. The third region 68C includes first to fourth sides 68CA to 68CD. The first to fourth sides 68CA to 68CD respectively correspond to the first to fourth sides 66CA to 66CD of the third region 66C. The first to fourth sides 68CA to 68CD are located inward from the first to fourth sides 66CA to 66CD of the third region 66C in plan view. That is, the third region 68C is arranged within the third region 66C in plan view. Further, the third region 68C entirely overlaps the third low-concentration region 62C (refer to FIG. 4) in plan view.

The first connecting region 69A is located at a position overlapping the first connecting region 67A in plan view. The first connecting region 69A is slightly smaller than the first connecting region 67A in plan view. The first connecting region 69A is located within the first connecting region 67A in plan view. The first connecting region 69A connects the second side 68AB of the first region 68A and the third side 68BC of the second region 68B, and connects the fourth side 68AD of the first region 68A and the first side 68BA of the second region 68B. The two Y-direction ends of the first connecting region 69A are curved in plan view. The two Y-direction ends of the first connecting region 69A have a greater radius of curvature than the corners of the first region 68A.

The second connecting region 69B is located at a position overlapping the second connecting region 67B in plan view. The second connecting region 69B is slightly smaller than the second connecting region 67B in plan view. The second connecting region 69B is located within the second connecting region 67B in plan view. The second connecting region 69B connects the second side 68BB of the second region 68B and the fourth side 68CD of the third region 68C, and connects the third side 68BC of the second region 68B and the first side 68CA of the third region 68C. The two Y-direction ends of the second connecting region 69B are curved in plan view. The two Y-direction ends of the second connecting region 69B have a greater radius of curvature than the corners of the third region 68C.

In this manner, the internal region 64 overlaps the entire first low-concentration region 62A, the entire second low-concentration region 62B, and the entire third low-concentration region 62C in plan view. Further, the internal region 64 and the high-concentration region 61 (diode-paired region 60) have similar shapes in plan view.

As shown in FIG. 6, the distance DD between the edges of the internal region 64 and the corresponding edges of the high-concentration region 61 is, for example, constant throughout the entire peripheral portion of the internal region 64. The distance DD may be, for example, approximately 5 m. Further, the center of curvature C1 of a corner of the internal region 64 may coincide with the center of curvature C2 of a corresponding corner of the high-concentration region 61. Thus, the corner of the internal region 64 has a smaller radius of curvature than the corner of the high-concentration region 61.

### Connection Electrodes and Wiring

As shown in FIG. 7, the first connection electrode 81, the second connection electrode 82, and the third connection electrode 83 are each located in the peripheral region 110 (refer to FIG. 4) in plan view. The first connection electrode 81, the second connection electrode 82, and the third connection electrode 83 are separated from one another.

The first connection electrode 81 is located closer to the first side surface 20A than the central part of the semiconductor chip 20 is in the X-direction in plan view. The first connection electrode 81 extends in the Y-direction. The first connection electrode 81 includes a pin connection portion 81A and a wiring portion 81B, which extends from the pin connection portion 81A toward the third side surface 20C in the Y-direction. In one example, the pin connection portion 81A is integrated with the wiring portion 81B.

The pin connection portion 81A is located at a position overlapping the first pin junction 30 (refer to FIG. 4) in plan view. The pin connection portion 81A is quadrilateral in plan view. The pin connection portion 81A is located within the first terminal low-concentration region 32 of the first pin junction 30 (refer to FIG. 4) in plan view. The pin connection portion 81A is slightly larger than the first terminal contact region 33 of the first pin junction 30 in plan view.

The wiring portion 81B has the form of a strip having a width in the X-direction in plan view. The width of the wiring portion 81B is less than the X-direction dimension of the pin connection portion 81A. The wiring portion 81B is shifted in the X-direction from the pin connection portion 81A. More specifically, a hypothetical line CL1 extending in the Y-direction through the width center of the wiring portion 81B is located closer to the second side surface 20B than a hypothetical line CL2, which extends in the Y-direction through the X-direction center of the pin connection portion 81A, is.

The wiring portion 81B covers the first contact region 63A of the first reverse pin junction 60A in plan view. In one example, the wiring portion 81B covers the entire first contact region 63A in plan view. The width of the wiring portion 81B is greater than that of the first contact region 63A. The width of the wiring portion 81B is less than that of the first low-concentration region 62A. The wiring portion 81B has a distal end that is curved in plan view.

A reverse pin connection portion 81C is arranged on the wiring portion 81B at a position overlapping the first contact region 63A. The reverse pin connection portion 81C is connected to the first contact region 63A.

The second connection electrode 82 extends in the Y-direction. The second connection electrode 82 is separated from the first connection electrode 81 and located toward the second side surface 20B in the X-direction. Part of the second connection electrode 82 overlaps the first connection electrode 81 as viewed in the X-direction. In one example, the second connection electrode 82 is located at the middle of the semiconductor chip 20 with respect to the X-direction in plan view.

The second connection electrode 82 includes a pin connection portion 82A and a wiring portion 82B, which extends from the pin connection portion 82A toward the fourth side surface 20D in the Y-direction. In one example, the pin connection portion 82A is integrated with the wiring portion 82B.

The pin connection portion 82A is located at a position overlapping the second pin junction 40 (refer to FIG. 4) in plan view. The pin connection portion 82A is quadrilateral in plan view. The pin connection portion 82A is located within the second terminal low-concentration region 42 of the second pin junction 40 (refer to FIG. 4) in plan view. The pin connection portion 82A is slightly larger than the second terminal contact region 43 of the second pin junction 40 in plan view. In one example, the pin connection portion 82A has the same size and shape as the pin connection portion 81A.

The wiring portion 82B has the form of a strip having a width in the X-direction in plan view. The width of the wiring portion 82B is less than the X-direction dimension of the pin connection portion 82A. The wiring portion 82B covers the second contact region 63B of the second reverse pin junction 60B in plan view. In one example, the wiring portion 82B covers the entire second contact region 63B in plan view. The width of the wiring portion 82B is greater than that of the second contact region 63B. The width of the wiring portion 82B is less than that of the second low-concentration region 62B. The wiring portion 82B has a distal end that is curved in plan view. In one example, the wiring portion 82B has the same size and shape as the wiring portion 81B. The wiring portion 82B is connected to the middle of the pin connection portion 82A with respect to the X-direction.

A reverse pin connection portion 82C is arranged on the wiring portion 82B at a position overlapping the second contact region 63B. The reverse pin connection portion 82C is connected to the second contact region 63B.

The third connection electrode 83 extends in the Y-direction. The third connection electrode 83 is separated from the second connection electrode 82 and located toward the second side surface 20B in the X-direction. Part of the third connection electrode 83 overlaps the second connection electrode 82 as viewed in the X-direction. In one example, the third connection electrode 83 and the first connection electrode 81 are located at the same position in the Y-direction.

The third connection electrode 83 includes a pin connection portion 83A and a wiring portion 83B, which extends from the pin connection portion 83A toward the third side surface 20C in the Y-direction. In one example, the pin connection portion 83A is integrated with the wiring portion 83B.

The pin connection portion 83A is located at a position overlapping the third pin junction 50 (refer to FIG. 4) in plan view. The pin connection portion 83A is quadrilateral in plan view. The pin connection portion 83A is located in the third terminal low-concentration region 52 of the third pin junction 50 (refer to FIG. 4) in plan view. The pin connection portion 83A is slightly larger than the third terminal contact region 53 of the third pin junction 50 in plan view. In one example, the pin connection portion 83A has the same size and shape as the pin connection portion 81A.

The wiring portion 83B has the form of a strip having a width in the X-direction in plan view. The width of the wiring portion 83B is less than the X-direction dimension of the pin connection portion 83A. The wiring portion 83B is shifted in the X-direction from the pin connection portion 83A. More specifically, a hypothetical line CL3 extending in the Y-direction through the width center of the wiring portion 83B is located closer to the first side surface 20A than a hypothetical line CL4, which extends in the Y-direction through the X-direction center of the pin connection portion 83A, is.

The wiring portion 83B covers the third contact region 63C of the third reverse pin junction 60C in plan view. In one example, the wiring portion 83B covers the entire third contact region 63C in plan view. The width of the wiring portion 83B is greater than that of the third contact region 63C. The width of the wiring portion 83B is less than that of the third low-concentration region 62C. The wiring portion 83B has a distal end that is curved in plan view. In one example, the wiring portion 83B has the same size and shape as the wiring portion 81B.

A reverse pin connection portion 83C is arranged on the wiring portion 83B at a position overlapping the third contact region 63C. The reverse pin connection portion 83C is connected to the third contact region 63C. The reverse pin connection portion 83C is oblong in plan view, and longer in the Y-direction and shorter in the X-direction.

The wiring 90 is located within the peripheral region 110 in plan view. The wiring 90 is arranged overlapping the diode-paired region 60 (high-concentration region 61), which is shown in FIG. 4, in plan view. The edges of the wiring 90 partially overlap the edges of the diode-paired region 60 (high-concentration region 61) in plan view. In one example, the entire wiring 90 overlaps the isolation region 65 in plan view. Thus, the wiring 90 is arranged in a manner avoiding the first pin junction 30, the second pin junction 40, and the third pin junction 50 in plan view. The wiring 90 is arranged to surround parts of the first connection electrode 81, the second connection electrode 82, and the third connection electrode 83 in plan view.

The wiring 90 includes a first region 91, a second region 92, a third region 93, a first connecting region 94, and a second connecting region 95.

The first region 91 is arranged overlapping the first region 66A of the diode-paired region 60 (refer to FIG. 4) in plan view. The edges of the first region 91 corresponding to the first to third sides 66AA to 66AC of the first region 66A (refer to FIG. 4) are arranged overlapping the first to third sides 66AA to 66AC in plan view.

The first region 91 includes a first recess 96A arranged in a manner avoiding the first connection electrode 81 in plan view. The first recess 96A is open toward the first pin junction 30. The wiring portion 81B of the first connection electrode 81 is located in the first recess 96A. Thus, the first region 91 partially surrounds the first connection electrode 81 in plan view. Further, the first recess 96A is arranged in a manner avoiding the first low-concentration region 62A of the first region 66A (refer to FIG. 4) in plan view. Thus, the first region 91 surrounds the first low-concentration region 62A in plan view.

The arrangement of the first recess 96A results in the first region 91 being partially connected to the isolation region 65 (refer to FIG. 4) in the first region 66A. More specifically, as shown in FIG. 4, the isolation region 65 in the first region 66A includes a wiring connection region 65P, which is connected to the wiring 90, and a first isolation region 65A, which overlaps the first connection electrode 81 (refer to FIG. 7) in plan view. The first isolation region 65A is arranged at the one of the two Y-direction ends of the first region 66A located toward the first pin junction 30. The first isolation region 65A is located in the first region 66A between the first low-concentration region 62A and the fourth side 66AD in plan view. The wiring connection region 65P partially surrounds the first low-concentration region 62A in plan view. That is, the wiring connection region 65P partially surrounds the first reverse pin junction 60A in plan view. Thus, the first region 91 (refer to FIG. 7), which is connected to the wiring connection region 65P, partially surrounds the first reverse pin junction 60A in plan view.

The second region 92 (refer to FIG. 7) overlaps the second region 66B of the diode-paired region 60 in plan view. The edges of the second region 92 corresponding to the first side 66BA, the second side 66BB, and the fourth side 66BD of the second region 66B are arranged overlapping the first side 66BA, the second side 66BB, and the fourth side 66BD in plan view. Thus, the second region 92 is shifted from the first region 91 in the Y-direction.

As shown in FIG. 7, the second region 92 includes a second recess 96B arranged in a manner avoiding the second connection electrode 82 in plan view. The second recess 96B is open toward the second pin junction 40 (refer to FIG. 4). The wiring portion 82B of the second connection electrode 82 is located in the second recess 96B. Thus, the second region 92 partially surrounds the second connection electrode 82 in plan view. Further, the second recess 96B is arranged in a manner avoiding the second low-concentration region 62B of the second region 66B (refer to FIG. 4) in plan view. Thus, the second region 92 surrounds the second low-concentration region 62B in plan view.

The arrangement of the second recess 96B results in the second region 92 being partially connected to the isolation region 65 in the second region 66B. More specifically, as shown in FIG. 4, the isolation region 65 in the second region 66B includes the wiring connection region 65P, which is connected to the wiring 90, and a second isolation region 65B, which overlaps the second connection electrode 82, in plan view. The second isolation region 65B is arranged at the one of the two Y-direction ends of the second region 66B located toward the second pin junction 40. The second isolation region 65B is located in the second region 66B between the second low-concentration region 62B and the third side 66BC in plan view. The wiring connection region 65P partially surrounds the second low-concentration region 62B in plan view. That is, the wiring connection region 65P partially surrounds the second reverse pin junction 60B in plan view. Thus, the second region 92 (refer to FIG. 7), which is connected to the wiring connection region 65P, partially surrounds the second reverse pin junction 60B in plan view.

The third region 93 (refer to FIG. 7) overlaps the third region 66C of the diode-paired region 60 in plan view. The edges of the third region 93 corresponding to the first to third sides 66CA to 66CC of the third region 66C are arranged overlapping the first to third sides 66CA to 66CC in plan view.

As shown in FIG. 7, the third region 93 includes a third recess 96C arranged in a manner avoiding the third connection electrode 83 in plan view. The third recess 96C is open toward the third pin junction 50. The wiring portion 83B of the third connection electrode 83 is located in the third recess 96C. Thus, the third region 93 partially surrounds the third connection electrode 83 in plan view. Further, the third recess 96C is arranged in a manner avoiding the third low-concentration region 62C of the third region 66C (refer to FIG. 4) in plan view. Thus, the third region 93 surrounds the third low-concentration region 62C in plan view.

The arrangement of the third recess 96C results in the third region 93 being partially connected to the isolation region 65 in the third region 66C. More specifically, as shown in FIG. 4, the isolation region 65 in the third region 66C includes the wiring connection region 65P, which is connected to the wiring 90, and a third isolation region 65C, which overlaps the third connection electrode 83, in plan view. The third isolation region 65C is arranged at the one of the two Y-direction ends of the third region 66C located toward the third pin junction 50. The third isolation region 65C is located in the third region 66C between the third low-concentration region 62C and the fourth side 66CD in plan view. The wiring connection region 65P partially surrounds the third low-concentration region 62C in plan view. That is, the wiring connection region 65P partially surrounds the third reverse pin junction 60C in plan view. Thus, the third region 93 (refer to FIG. 7), which is connected to the wiring connection region 65P, partially surrounds the third reverse pin junction 60C in plan view.

As shown in FIG. 7, the first connecting region 94 is arranged overlapping the first connecting region 67A of the diode-paired region 60 (refer to FIG. 4) in plan view. The first connecting region 94 has the same size and shape as the first connecting region 67A. The first connecting region 94 is connected to the entire first connecting region 67A. In other words, the first connecting region 67A is formed by the wiring connection region 65P.

The second connecting region 95 is arranged overlapping the second connecting region 67B of the diode-paired region 60 (refer to FIG. 4) in plan view. The second connecting region 95 has the same size and shape as the second connecting region 67B. The second connecting region 95 is connected to the entire second connecting region 67B. In other words, the second connecting region 67B is formed by the wiring connection region 65P.

The wiring 90 has a larger area than the first connection electrode 81 in plan view. The area of the wiring 90 in plan view is larger than that of the second connection electrode 82. The area of the wiring 90 in plan view is larger than that of the third connection electrode 83. The area of the wiring 90 in plan view is smaller than that of the high-concentration region 61. In one example, the wiring 90 is arranged within the edges of the high-concentration region 61 in plan view.

The area of the wiring 90 in plan view is smaller than that of the isolation region 65 (refer to FIG. 4). In one example, the area of the wiring 90 in plan view is within a range from 75% to 97%, inclusive, of the area of the isolation region 65 in plan view. In one example, the area of the wiring 90 in plan view may be within a range from 80% to 95%, inclusive, of the area of the isolation region 65 in plan view. In one example, the area of the wiring 90 in plan view may be within a range from 85% to 95%, inclusive, of the area of the isolation region 65 in plan view. In one example, the area of the wiring 90 in plan view may be within a range from 90% to 95%, inclusive, of the area of the isolation region 65 in plan view. In one example, the area of the wiring 90 in plan view may be within a range from 85% to 90%, inclusive, of the area of the isolation region 65 in plan view.

### Terminal Opening

As shown in FIG. 1, the first terminal opening 77A, the second terminal opening 77B, and the third terminal opening 77C are separated from one another. More specifically, the first terminal opening 77A and the third terminal opening 77C are located at the same position in the Y-direction and separated from each other in the X-direction. The first terminal opening 77A and the third terminal opening 77C are located closer to the fourth side surface 20D than the central part of the first surface 20S of the semiconductor chip 20 is in the Y-direction. The first terminal opening 77A is located closer to the first side surface 20A than the central part of the first surface 20S is in the X-direction. The third terminal opening 77C is located closer to the second side surface 20B than the central part of the first surface 20S is in the X-direction.

The second terminal opening 77B is located at a position separated from both the first terminal opening 77A and the third terminal opening 77C in the X-direction and the Y-direction. The second terminal opening 77B is located closer to the third side surface 20C than the central part of the first surface 20S of the semiconductor chip 20 is in the Y-direction. The second terminal opening 77B is located at the middle of the first surface 20S with respect to the X-direction. Thus, as viewed in the Y-direction, the second terminal opening 77B is located between the first terminal opening 77A and the third terminal opening 77C in the X-direction.

As shown in FIGS. 1 and 4, the first terminal opening 77A is arranged at a position overlapping the first pin junction 30 in plan view. The second terminal opening 77B is arranged at a position overlapping the second pin junction 40 in plan view. The third terminal opening 77C is arranged at a position overlapping the third pin junction 50 in plan view.

The first terminal opening 77A exposes the pin connection portion 81A of the first connection electrode 81 in plan view. The second terminal opening 77B exposes the pin connection portion 82A of the second connection electrode 82 in plan view. The third terminal opening 77C exposes the pin connection portion 83A of the third connection electrode 83 in plan view.

### Circuit Configuration of the TVS Diode

With reference to FIG. 8, the TVS circuit 200 of the TVS diode 10 will now be described. FIG. 8 is a schematic circuit diagram of the TVS diode 10.

As shown in FIG. 8, the TVS circuit 200 includes first to sixth diodes 201 to 206, a zener diode 207, and first to third terminals TM1 to TM3. The first terminal TM1 may be formed by, for example, the part of the first connection electrode 81 exposed from the first terminal opening 77A. The second terminal TM2 may be formed by, for example, the part of the second connection electrode 82 exposed from the second terminal opening 77B. The third terminal TM3 may be formed by, for example, the part of the third connection electrode 83 exposed from the third terminal opening 77C.

The first diode 201 is formed by the pin diode of the first pin junction 30. The second diode 202 is formed by the pin diode of the second pin junction 40. The third diode 203 is formed by the pin diode of the third pin junction 50. The fourth diode 204 is formed by the pin diode of the first reverse pin junction 60A. The fifth diode 205 is formed by the pin diode of the second reverse pin junction 60B. The sixth diode 206 is formed by the pin diode of the third reverse pin junction 60C.

The cathode of the first diode 201 is electrically connected to the anode of the fourth diode 204. The first terminal TM1 is electrically connected to a node N1 between the cathode of the first diode 201 and the anode of the fourth diode 204. The cathode of the second diode 202 is electrically connected to the anode of the fifth diode 205. The second terminal TM2 is electrically connected to a node N2 between the cathode of the second diode 202 and the anode of the fifth diode 205.

The cathode of the third diode 203 is electrically connected to the anode of the sixth diode 206. The third terminal TM3 is electrically connected to a node between the cathode of the third diode 203 and the anode of the sixth diode 206.

The zener diode 207 is connected in parallel to a series-connected body of the first diode 201 and the fourth diode 204, a series-connected body of the second diode 202 and the fifth diode 205, and a series-connected body of the third diode 203 and the sixth diode 206. The anode of the zener diode 207 is electrically connected to the anode of the first diode 201, the anode of the second diode 202, and the anode of the third diode 203. The cathode of the zener diode 207 is electrically connected to the cathode of the fourth diode 204, the cathode of the fifth diode 205, and the cathode of the sixth diode 206. In this manner, the zener diode 207 forms a diode for connection in a reverse direction shared by the fourth diode 204, the fifth diode 205, and the sixth diode 206.

In one example, the first terminal TM1 and the third terminal TM3 form input terminals, and the second terminal TM2 forms a ground terminal. Thus, when voltage is applied to the first terminal TM1, current flows from the first terminal TM1 via the fourth diode 204, the zener diode 207, and the second diode 202 to the second terminal TM2. Further, when voltage is applied to the third terminal TM3, current flows from the third terminal TM3 via the sixth diode 206, the zener diode 207, and the second diode 202 to the second terminal TM2. The first terminal TM1 and the second terminal TM2 may form the input terminals, and the third terminal TM3 may form the ground terminal. Alternatively, the second terminal TM2 and the third terminal TM3 may form the input terminals, and the first terminal TM1 may form the ground terminal.

### Method for Manufacturing the TVS Diode

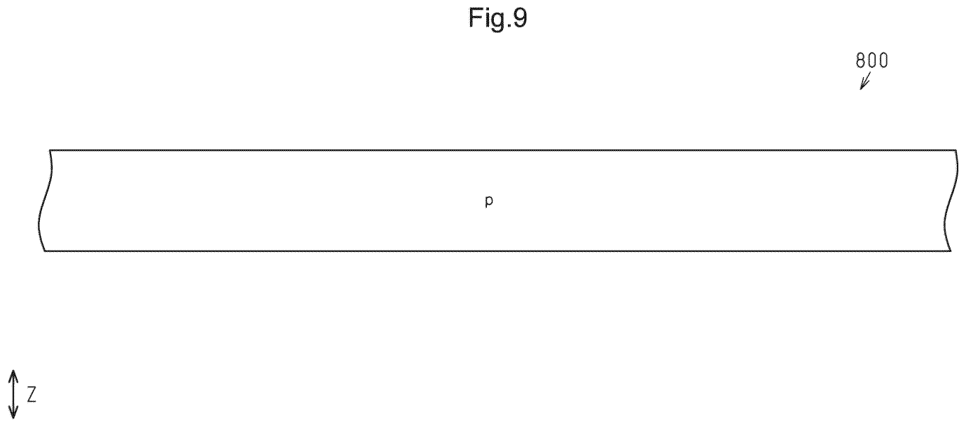

With reference to FIGS. 9 to 25, one example of a method for manufacturing the TVS diode 10 will now be described. FIGS. 9 to 25 are cross-sectional views illustrating manufacturing steps of the TVS diode 10.

As shown in FIG. 9, the method for manufacturing the TVS diode 10 includes a step of preparing a semiconductor wafer 800. The semiconductor wafer 800 is, for example, a Si wafer.

The semiconductor wafer 800 contains p-type impurities. The p-type impurities may be, for example, boron (B).

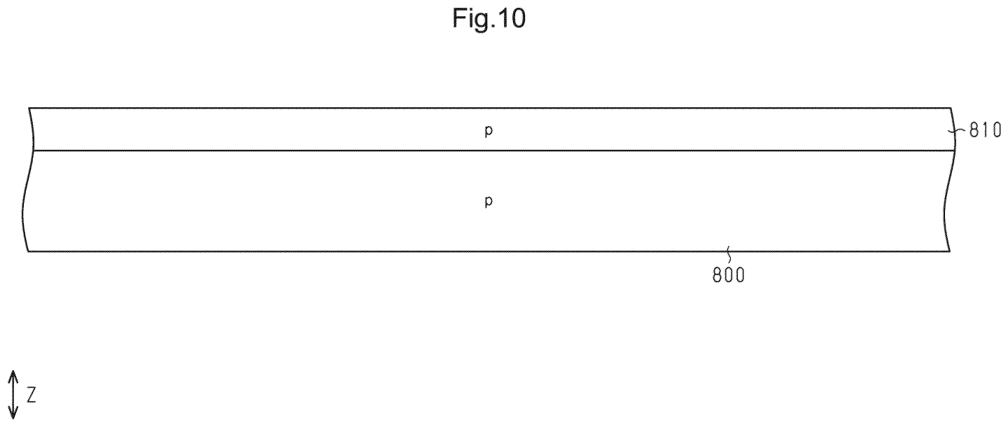

As shown in FIG. 10, the method for manufacturing the TVS diode 10 includes forming a first epitaxial layer 810. In this step, an epitaxial growing process is performed to grow Si crystals on the upper surface of the semiconductor wafer 800. The p-type impurity concentration is distributed in Si when crystals are grown on the semiconductor wafer 800. This forms the p-type first epitaxial layer 810, which becomes the first semiconductor layer 23, on the semiconductor wafer 800.

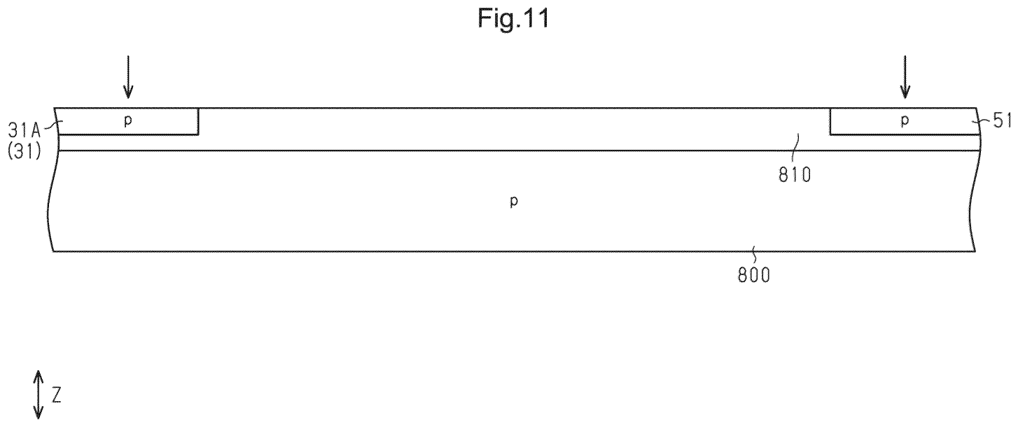

As shown in FIG. 11, the method for manufacturing the TVS diode 10 includes selectively diffusing p-type impurities (e.g., B) into the outer portion of the first epitaxial layer 810. In this step, p-type impurities are selectively diffused into the outer portion of the first epitaxial layer 810 at regions where the first terminal high-concentration region 31, the second terminal high-concentration region 41 (refer to FIG. 3), and the third terminal high-concentration region 51 are to be formed. In this step, the p-type impurities may be, for example, implanted into the outer portion of the first epitaxial layer 810 through an ion implantation process using an ion implantation mask (not shown). This forms part of the first terminal high-concentration region 31 (first region 31A), part of the second terminal high-concentration region 41, and part of the third terminal high-concentration region 51.

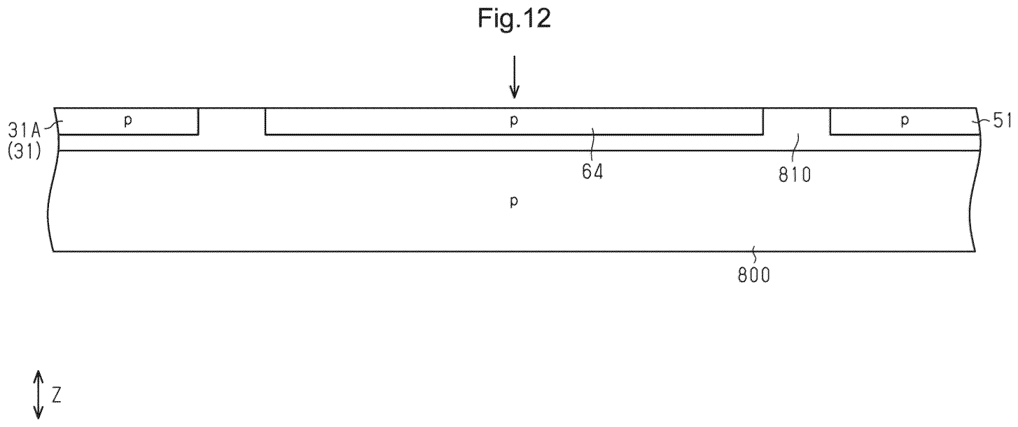

Then, as shown in FIG. 12, p-type impurities are diffused into the outer portion of the first epitaxial layer 810 at a region where the internal region 64 is to be formed. In this step, the p-type impurities may be selectively implanted into the outer portion of the first epitaxial layer 810 through the ion implantation method described above. This forms part of the internal region 64.

The drawings illustrating the method for manufacturing the TVS diode 10 in accordance with the first embodiment, including FIGS. 11 and 12, show part of the first terminal high-concentration region 31 (first region 31A), part of the third terminal high-concentration region 51, and part of the internal region 64 but do not show part of the second terminal high-concentration region 41. The step illustrated in FIG. 12 may be performed before the step illustrated in FIG. 11.

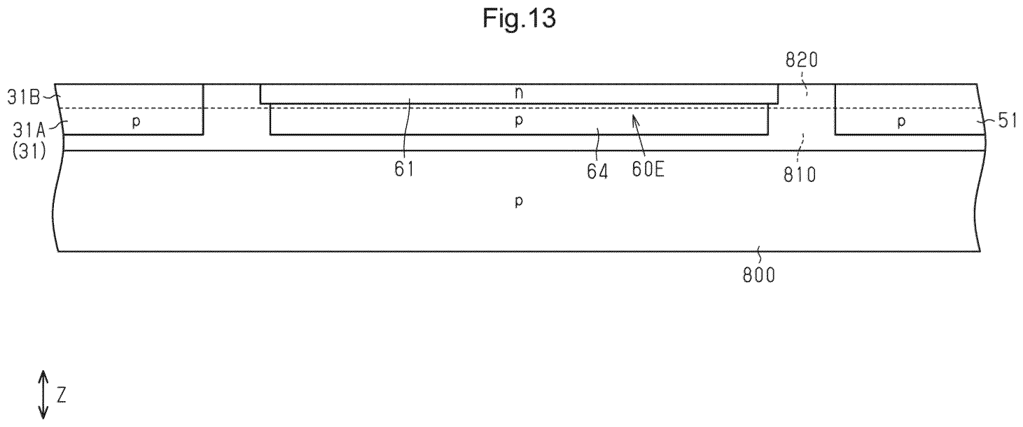

As shown in FIG. 13, the method for manufacturing the TVS diode 10 includes a step for forming a second epitaxial layer 820. In this step, an epitaxial growing process is performed to grow Si crystals from the first epitaxial layer 810. This forms the n-type second epitaxial layer 820, which becomes the second semiconductor layer 24, on the first epitaxial layer 810. The second epitaxial layer 820 may be of the p-type.

Then, the method for manufacturing the TVS diode 10 includes a step of selectively diffusing p-type impurities into the second epitaxial layer 820. In this step, the p-type impurities are, for example, selectively implanted into the second epitaxial layer 820 at regions where the first terminal high-concentration region 31, the second terminal high-concentration region 41, the third terminal high-concentration region 51, and the internal region 64 are to be formed. In the same manner as the step illustrated in FIG. 11, the step of selectively implanting the p-type impurities at regions where the first terminal high-concentration region 31, the second terminal high-concentration region 41, and the third terminal high-concentration region 51 are to be performed may be performed separately from the step of implanting the p-type impurities at a region where the internal region 64 is to be formed.

Then, the method for manufacturing the TVS diode 10 includes a step of diffusing n-type impurities into the outer portion of the second epitaxial layer 820 at a region where the diode-paired region 60 is to be formed. The n-type impurities may be, for example, at least one of arsenic (As) and phosphorus (P). The n-type impurities may be, for example, implanted into the outer portion of the second epitaxial layer 820 through an ion implantation process using an ion implantation mask (not shown). This forms part of the high-concentration region 61 in the outer portion of the second epitaxial layer 820. The high-concentration region 61 covers the entire internal region 64 in plan view. The high-concentration region 61 is formed contacting the internal region 64. This forms the pn junction 60E.

Then, the method for manufacturing the TVS diode 10 includes diffusing p-type impurities into the outer portion of the first epitaxial layer 810, and dispersing the p-type impurities and the n-type impurities diffused into the second epitaxial layer 820. In this step, for example, a drive-in process is performed to further diffuse the p-type impurities and the n-type impurities. This diffuses the p-type impurities from the outer portion of the first epitaxial layer 810 into the second epitaxial layer 820.

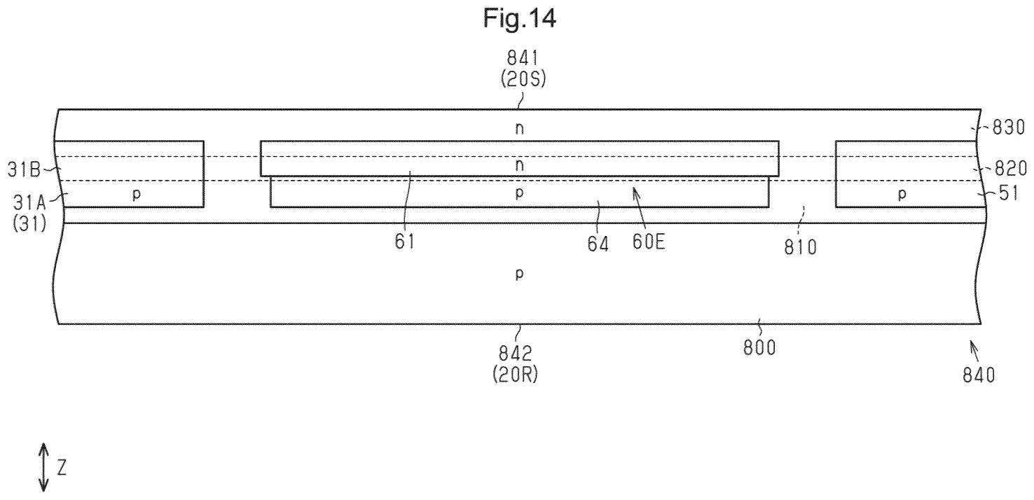

As shown in FIG. 14, the method for manufacturing the TVS diode 10 includes a process for forming a third epitaxial layer 830. In this step, an epitaxial growing process is performed to grow Si crystals from the second epitaxial layer 820 when the n-type impurities are diffused. In this step, the p-type impurities and the n-type impurities are diffused in Si when crystals are grown from the second epitaxial layer 820. This forms the third epitaxial layer 830 on the second epitaxial layer 820. Further, part of the first terminal high-concentration region 31, part of the second terminal high-concentration region 41, part of the third terminal high-concentration region 51, and the high-concentration region 61 are formed at the boundary of the second epitaxial layer 820 and the third epitaxial layer 830.

The steps described above form a semiconductor wafer structure 840 including the semiconductor wafer 800, the first epitaxial layer 810, the second epitaxial layer 820, and the third epitaxial layer 830. The semiconductor wafer structure 840 includes a first wafer surface 841 and a second wafer surface 842 opposite the first wafer surface 841. The first wafer surface 841 corresponds to the first surface 20S of the semiconductor chip 20, and the second wafer surface 842 corresponds to the second surface 20R of the semiconductor chip 20. The first wafer surface 841 is formed by the third epitaxial layer 830. The second wafer surface 842 is formed by the semiconductor wafer 800.

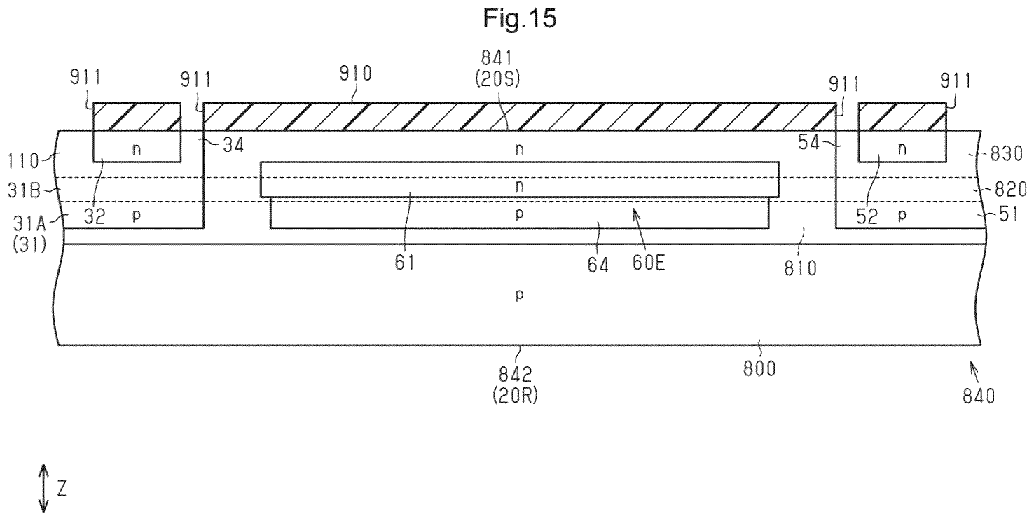

As shown in FIG. 15, the method for manufacturing the TVS diode 10 includes a step of forming the partitioning region and the peripheral region 110. In this step, for example, an ion implantation process is performed using an ion implantation mask 910 to selectively implant p-type impurities into the outer portion of the third epitaxial layer 830. The ion implantation mask 910 includes openings 911 exposing regions of the third epitaxial layer 830 where the first partitioning region 34, the second partitioning region 44 (refer to FIG. 3), the third partitioning region 54, and the peripheral region 110 are to be formed. P-type impurities are implanted through the openings 911 into the outer portion of the third epitaxial layer 830. This forms the first partitioning region 34, the second partitioning region 44, the third partitioning region 54, and the peripheral region 110, which are of the p-type. The formation of the first partitioning region 34 and the peripheral region 110 forms the first terminal low-concentration region 32, which is surrounded by the first partitioning region 34 in plan view. The formation of the second partitioning region 44 and the peripheral region 110 forms the second terminal low-concentration region 42, which is surrounded by the second partitioning region 44 in plan view. The formation of the third partitioning region 54 and the peripheral region 110 forms the third terminal low-concentration region 52, which is surrounded by the third partitioning region 54 in plan view. FIG. 15 shows the first partitioning region 34, the third partitioning region 54, and the peripheral region 110 but does not show the second partitioning region 44.

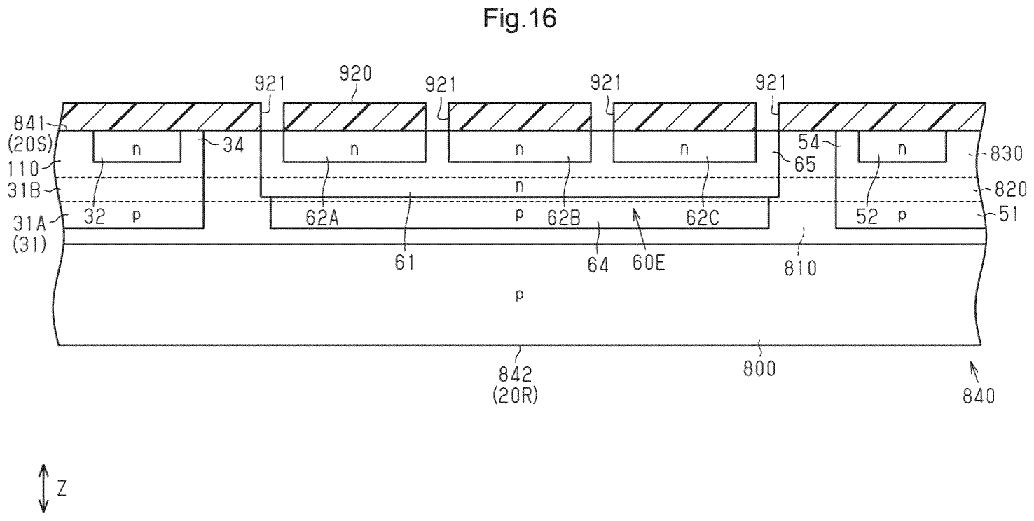

As shown in FIG. 16, the method for manufacturing the TVS diode 10 includes a step of forming the isolation region 65. In this step, for example, an ion implantation process is performed using an ion implantation mask 920 to selectively implant n-type impurities into the outer portion of the third epitaxial layer 830. The ion implantation mask 920 includes openings 921 exposing regions of the third epitaxial layer 830 where the isolation region 65 is to be formed. N-type impurities are implanted through the openings 921 into the outer portion of the third epitaxial layer 830. This forms the isolation region 65 of the n-type. The formation of the isolation region 65 forms the first low-concentration region 62A, the second low-concentration region 62B, and the third low-concentration region 62C, which are surrounded by the isolation region 65 in plan view.

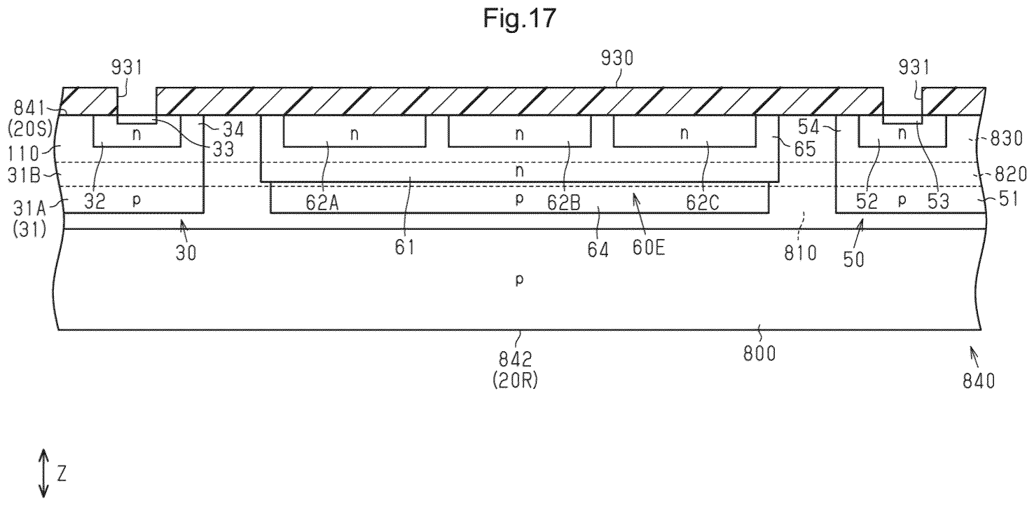

As FIG. 17, the method for manufacturing the TVS diode 10 includes a step of forming the terminal contact regions. In this step, for example, an ion implantation process is performed using an ion implantation mask 930 to selectively implant n-type impurities into the outer portion of the third epitaxial layer 830. The ion implantation mask 930 includes openings 931 exposing regions in the outer portion of the third epitaxial layer 830 where the first terminal contact region 33, the second terminal contact region 43, and the third terminal contact region 53 are to be formed. Further, the openings 931 expose parts of the outer portion of the third epitaxial layer 830 corresponding to the outer portions of the first terminal low-concentration region 32, the second terminal low-concentration region 42 (refer to FIG. 3), and the third terminal low-concentration region 52. The n-type impurities are implanted through the openings 931 into the outer portions of the first terminal low-concentration region 32, the second terminal low-concentration region 42, and the third terminal low-concentration region 52. This forms the first terminal contact region 33 of the n-type in the outer portion of the first terminal low-concentration region 32. The second terminal contact region 43 (refer to FIG. 3) of the n-type is formed in the outer portion of the second terminal low-concentration region 42. The third terminal contact region 53 of the n-type is formed in the outer portion of the third terminal low-concentration region 52. The first pin junction 30, the second pin junction 40, and the third pin junction 50 are formed through the steps described above. FIG. 17 shows the first terminal contact region 33 and the third terminal contact region 53 but does not show the second terminal contact region 43.

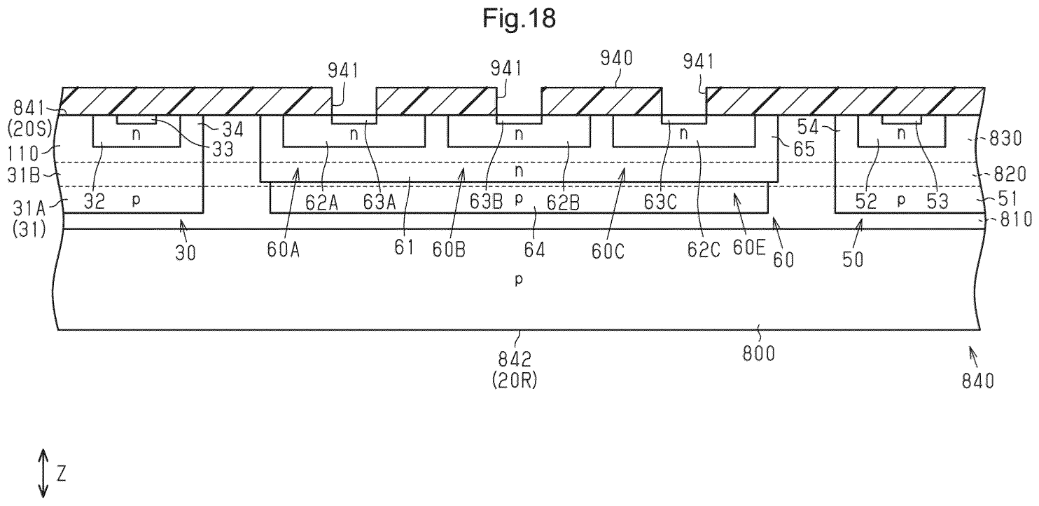

As shown in FIG. 18, the method for manufacturing the TVS diode 10 includes a step of forming the contact regions. In this step, for example, an ion implantation process is performed using an ion implantation mask 940 to selectively implant p-type impurities into the outer portion of the third epitaxial layer 830. The ion implantation mask 940 includes openings 941 exposing regions in the outer portion of the third epitaxial layer 830 where the first contact region 63A, the second contact region 63B, and the third contact region 63C are to be formed. The openings 941 expose parts of the outer portion of the third epitaxial layer 830 corresponding to the outer portion of the first low-concentration region 62A, the second low-concentration region 62B, and the third low-concentration region 62C. The p-type impurities are implanted through the openings 941 into the outer portions of the first low-concentration region 62A, the second low-concentration region 62B, and the third low-concentration region 62C. This forms the first contact region 63A of the p-type in the outer portion of the first low-concentration region 62A. The second contact region 63B of the p-type is formed in the outer portion of the second low-concentration region 62B. The third contact region 63C of the p-type is formed in the outer portion of the third low-concentration region 62C. The first reverse pin junction 60A, the second reverse pin junction 60B, and the third reverse pin junction 60C are formed through the steps described above.

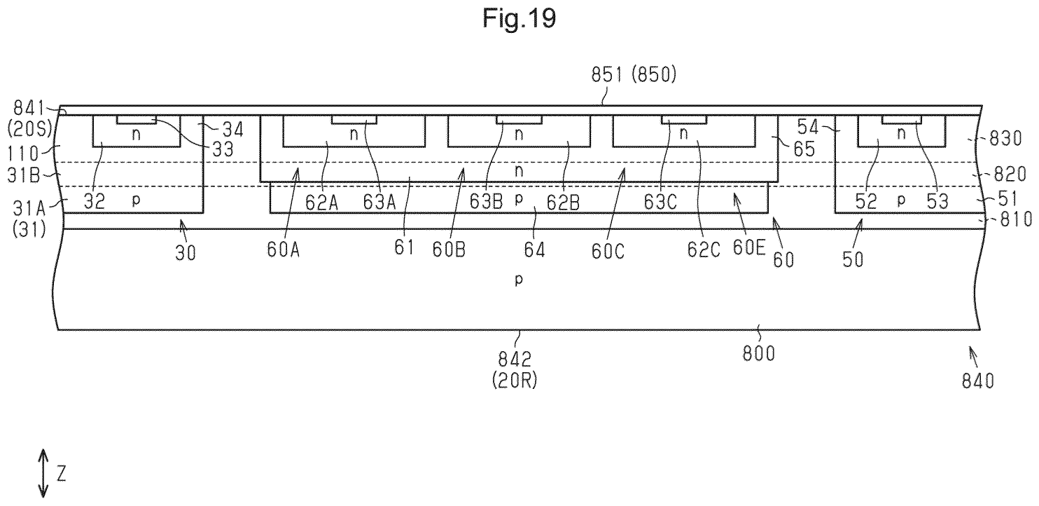

As shown in FIGS. 19 to 21, the method for manufacturing the TVS diode 10 includes a step of forming an insulation layer 850.

As shown in FIG. 19, the step of forming the insulation layer 850 includes a step of forming a first insulation layer 851. The first insulation layer 851 is formed on the first wafer surface 841 of the semiconductor wafer structure 840. The first insulation layer 851 defines the first insulation layer 71 of the insulation layer 70. The first insulation layer 851 may be formed through a chemical vapor deposition (CVD) process or an oxidation process (e.g., thermal oxidation process).

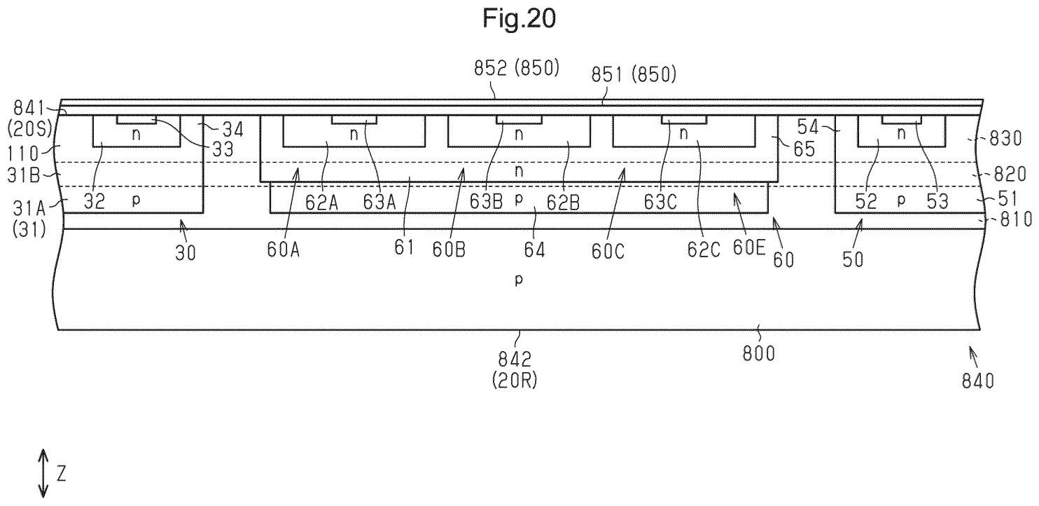

Then, as shown in FIG. 20, the step of forming the insulation layer 850 includes a step of forming a second insulation layer 852. The second insulation layer 852 is formed on the first insulation layer 851. The second insulation layer 852 defines the second insulation layer 72 of the insulation layer 70. The second insulation layer 852 may be formed through at least one of a CVD process and an oxidation process.

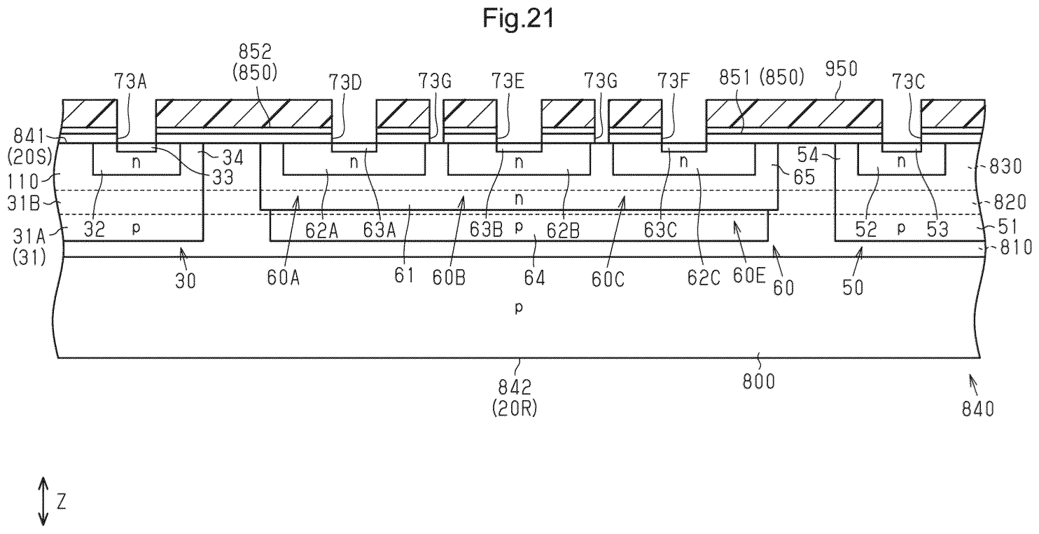

Then, as shown in FIG. 21, the step of forming the insulation layer 850 includes a step of forming the first to sixth openings 73A to 73F and the wiring openings 73G, which partially expose the first wafer surface 841. In this step, a resist mask 950 having a predetermined pattern is formed on the second insulation layer 852. The resist mask 950 exposes the insulation layer 850 at regions where the first to sixth openings 73A to 73F and the wiring openings 73G of the insulation layer 70 are to be formed and covers the other regions. Etching is performed using the resist mask 950 to remove the portions exposed from the resist mask 950. This forms the first to sixth openings 73A to 73F and the wiring openings 73G.

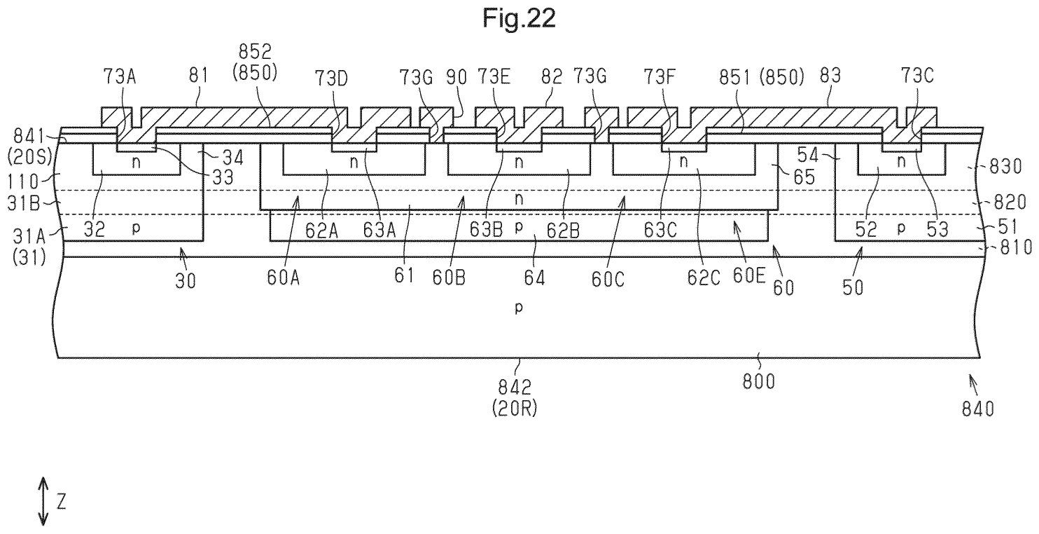

As shown in FIG. 22, the method for manufacturing the TVS diode 10 includes a step of forming the connection electrodes and a step of forming the wiring 90. In one example, the formation of the connection electrodes and the formation of the wiring 90 are performed in the same step.

A metal layer is first formed on the insulation layer 850. The metal layer covers the insulation layer 850 and fills the first to sixth openings 73A to 73F. Thus, the metal layer contacts the first terminal contact region 33, the second terminal contact region 43, the third terminal contact region 53, the first to third contact regions 63A to 63C, and the isolation region 65. The metal layer forms the first to third connection electrodes 81 to 83 and the wiring 90.

Then, an etching process is performed using a resist mask (not shown) having a predetermined pattern to remove unnecessary parts from the metal layer. The resist mask covers regions of the metal layer where the first to third connection electrodes 81 to 83 and the wiring 90 are to be formed and exposes other regions. The parts exposed from the resist layer are removed from the metal layer. This forms the first to third connection electrodes 81 to 83 and the wiring 90. FIG. 22 shows the first connection electrode 81, the third connection electrode 83, and the wiring 90 but does not show the second connection electrode 82.

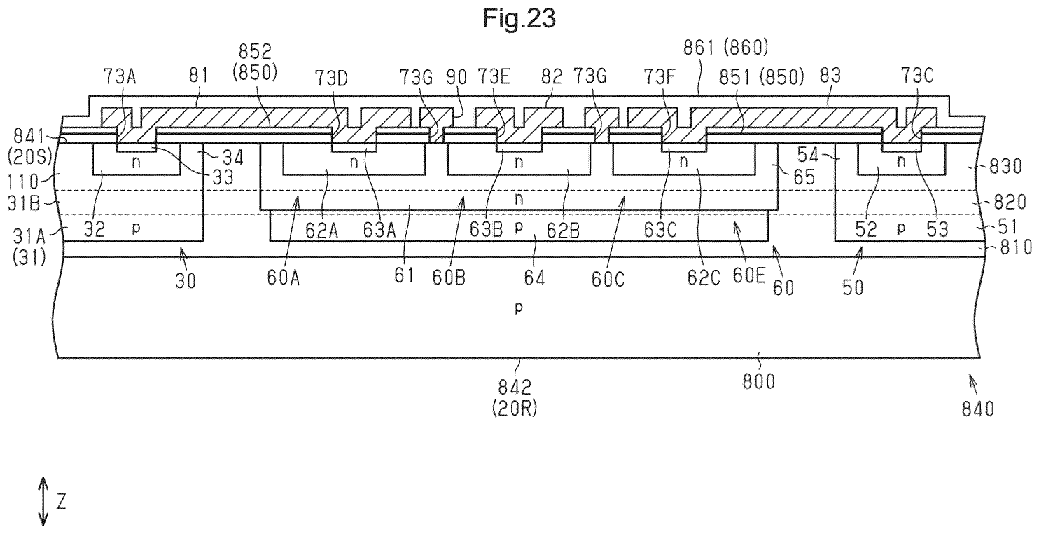

As shown in FIGS. 23 to 25, the method for manufacturing the TVS diode 10 includes a step of forming a protection layer 860.

As shown in FIG. 23, the step of forming the protection layer 860 includes a step of forming a first protection layer 861. The first protection layer 861 is an insulation layer forming the first protection layer 75 of the protection layer 74. The first protection layer 861 may be formed through a CVD process.

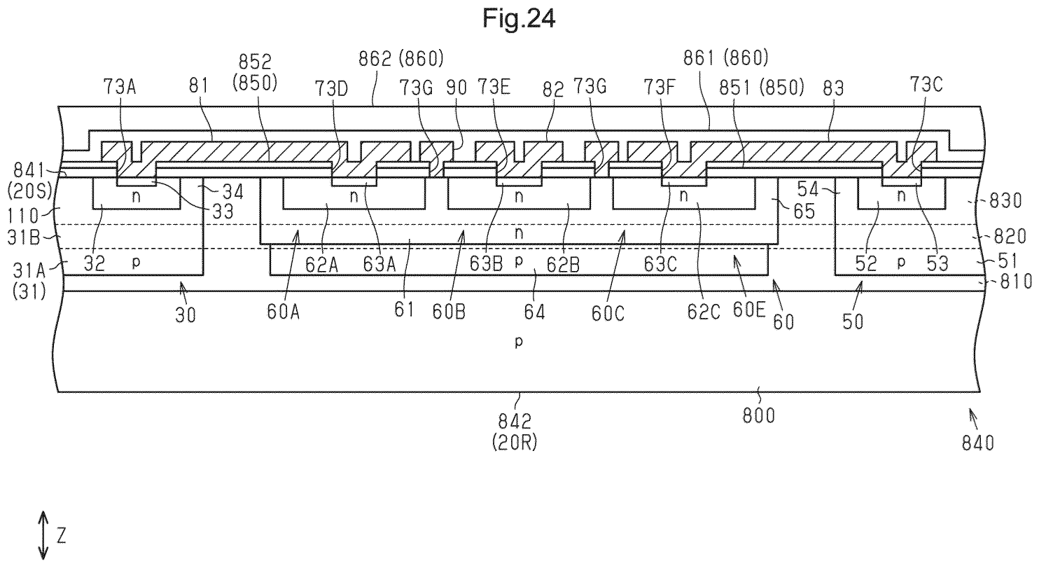

As shown in FIG. 24, the step of forming the protection layer 860 includes a step of forming a second protection layer 862. The second protection layer 862 is a resin layer forming the second protection layer 76 of the protection layer 74. In one example, the second protection layer 862 is formed by applying a photosensitive resin (e.g., PI) to the first protection layer 861.

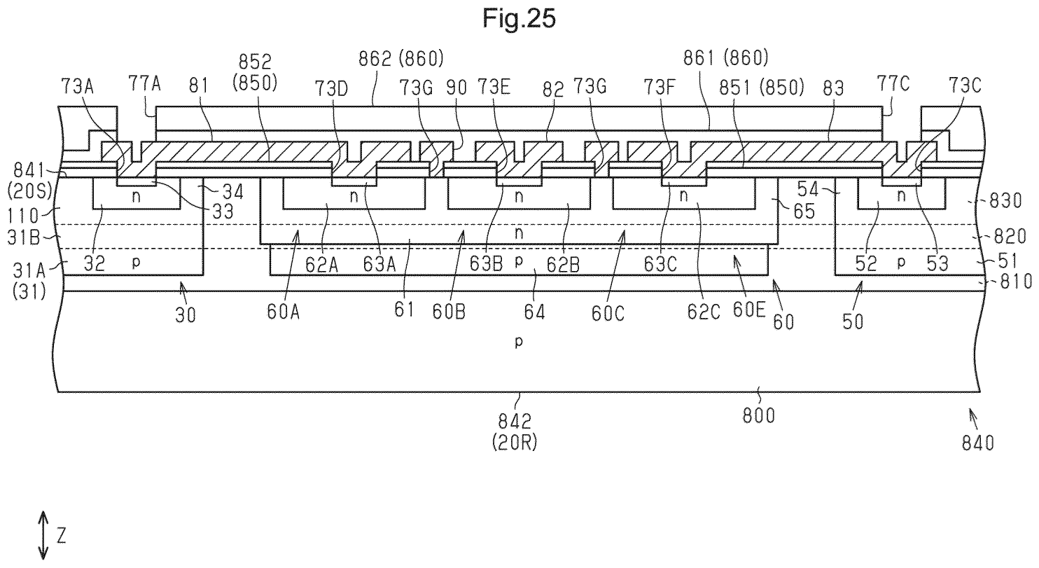

As shown in FIG. 25, the step of forming the protection layer 860 includes a step of forming the first to third terminal openings 77A to 77C. The first to third terminal openings 77A to 77C are formed through exposure and development of the first protection layer 861 and the second protection layer 862. More specifically, a photoresist is formed on the second protection layer 862. Then, for example, the photoresist undergoes exposure to form openings in the photoresist exposing regions of the second protection layer 862 where the first to third terminal openings 77A to 77C are to be formed. Then, development is performed to remove the second protection layer 862 and the first protection layer 861 exposed from the openings. This forms the first to third terminal openings 77A to 77C. FIG. 25 shows the first terminal opening 77A and the third terminal opening 77C but does not show the second terminal opening 77B (refer to FIG. 3).

Although not shown in the drawings, the method for manufacturing the TVS diode 10 includes a fragmenting step. In this step, for example, a dicing blade is used to cut the semiconductor wafer structure 840, the insulation layer 850, and the protection layer 860. This forms the semiconductor chip 20, the insulation layer 70, and the protection layer 74 (refer to FIG. 2). The TVS diode 10 is manufactured through the steps described above.

### Operation

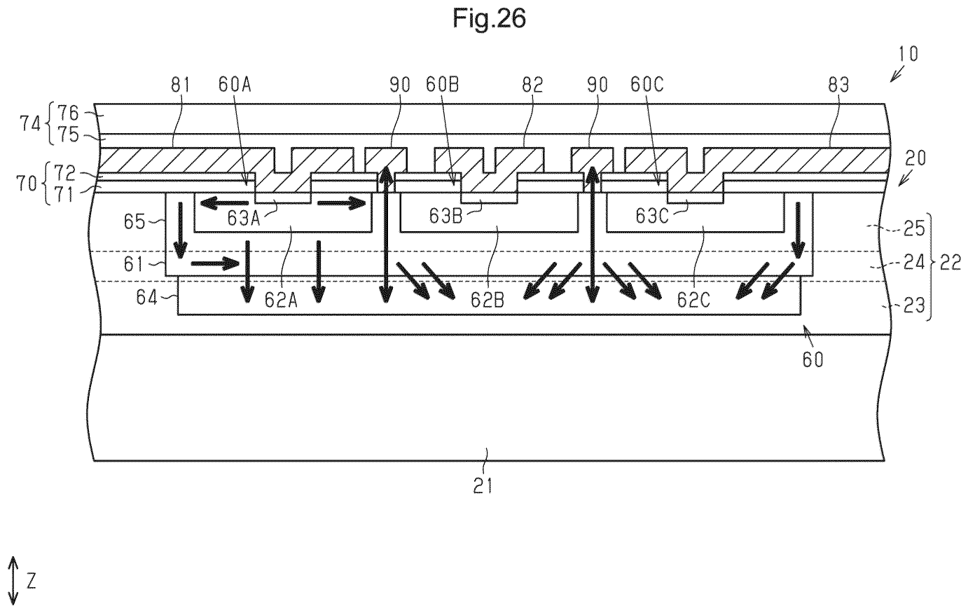

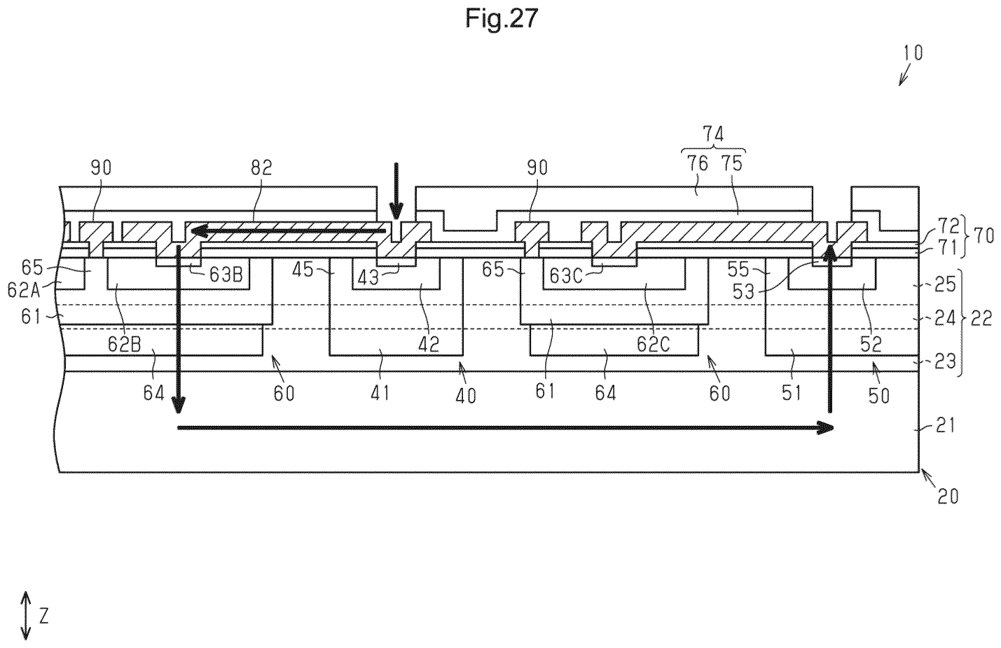

With reference to FIGS. 26 and 27, the operation of the TVS diode 10 in accordance with the first embodiment will now be described. FIG. 26 is an enlarged, schematic cross-sectional view showing the diode-paired region 60 of the TVS diode 10. FIG. 27 is a schematic cross-sectional view showing the second pin junction 40, the second reverse pin junction 60B, the third reverse pin junction 60C, and the third pin junction 50.

As shown in FIG. 26, the diode-paired region 60 includes the first to third reverse pin junctions 60A to 60C. The high-concentration region 61 forms an N-layer shared by the first to third reverse pin junctions 60A to 60C. The internal region 64 is arranged overlapping the first low-concentration region 62A, the second low-concentration region 62B, and the third low-concentration region 62C in plan view. That is, the pn junction 60E, which is formed by the high-concentration region 61 and the internal region 64, acts as a pn junction used commonly as a pn junction connected in a reverse direction to the first reverse pin junction 60A, a pn junction connected in a reverse direction to the second reverse pin junction 60B, and a pn junction connected in a reverse direction to the third pin junction 60C. Thus, as long as the chip size is the same, the high-concentration region 61 and the internal region 64 may be joined over a greater area in comparison with a structure in which a pn junction connected in a reverse direction to the first reverse pin junction 60A, a pn junction connected in a reverse direction to the second reverse pin junction 60B, and a pn junction connected in a reverse direction to the third pin junction 60C are separate from one another. Further, when maintaining the joined area of the high-concentration region 61 and the internal region 64, the TVS diode 10 may be reduced in size.

As shown by the thick arrows in FIG. 26, current flows through the first reverse pin junction 60A in order of the first contact region 63A, the first low-concentration region 62A, and the isolation region 65. The current flowing through the isolation region 65 flows to the wiring 90, which is in contact with the isolation region 65. The wiring 90 surrounds the first to third reverse pin junctions 60A to 60C and entirely covers the high-concentration region 61 in plan view. This allows current to smoothly flow from the wiring 90 via the isolation region 65 to the entire internal region 64. Current flows in the same manner through the second reverse pin junction 60B and the third reverse pin junction 60C. Thus, when current flows through the second reverse pin junction 60B and when current flows through the third reverse pin junction 60C, current smoothly flows to the entire internal region 64.

As shown in FIG. 27, part of the diode-paired region 60 is arranged between the second pin junction 40 and the third pin junction 50 to decrease the amplification factor of a parasitic NPN transistor between the second pin junction 40 and the third pin junction 50. Thus, activation of the parasitic NPN limits the direct flow of current from the second pin junction 40 to the third pin junction 50. For example, when electrostatic discharge (ESD) is applied to a second terminal 102, current flows from the second terminal 102 through the second connection electrode 82, the second reverse pin junction 60B, and the pn junction 60E to the first semiconductor layer 23. Then, the current flows from the first semiconductor layer 23 through the third pin junction 50 and the third connection electrode 83 to a third terminal 103. In this manner, when the second pin junction 40 and the third pin junction 50 sandwich the diode-paired region 60, current flows through the diode-paired region 60 and the first semiconductor layer 23.

### Advantages

The TVS diode 10 in accordance with the first embodiment has the advantages described below.
(1-1) The TVS diode 10 includes the first surface 20S, the second surface 20R at the opposite side of the first surface 20S, and the semiconductor chip 20. The semiconductor chip 20 includes the first pin junction 30 for the first polarity direction arranged toward the first surface 20S of the semiconductor chip 20, the second pin junction 40 for the first polarity direction arranged toward the first surface 20S of the semiconductor chip 20 in a region separated from the first pin junction 30 in a plan view taken in a thickness direction of the semiconductor chip 20, and the diode-paired region 60 separated from both the first pin junction 30 and the second pin junction 40. The diode-paired region 60 includes the high-concentration region 61 of the n-type separated from the first surface 20S of the semiconductor chip 20 and arranged toward the second surface 20R, the first low-concentration region 62A and the second low-concentration region 62B of the n-type that have a lower impurity concentration than the high-concentration region 61 and are separated from each other and closer to the first surface 20S than the high-concentration region 61 is at positions overlapping the high-concentration region 61 in plan view, the isolation region 65 isolating the first low-concentration region 62A and the second low-concentration region 62B and arranged closer to the first surface 20S than the high-concentration region 61 is at a position overlapping the high-concentration region 61 in plan view, the first contact region 63A of the p-type arranged in an outer portion of the first low-concentration region 62A, the second contact region 63B of the p-type arranged in the outer portion of the second low-concentration region 62B, and the internal region 64 of the p-type contacting the high-concentration region 61 and being arranged closer to the second surface 20R than the high-concentration region 61 is at a position overlapping the high-concentration region 61 in plan view. The high-concentration region 61, the first low-concentration region 62A, and the first contact region 63A form the first reverse pin junction 60A for the second polarity direction. The high-concentration region 61, the second low-concentration region 62B, and the second contact region 63B form the second reverse pin junction 60B for the second polarity direction. The high-concentration region 61 and the internal region 64 form the pn junction 60E for the first polarity direction connected in a reverse direction to the first reverse pin junction 60A and the second reverse pin junction 60B. The internal region 64 is arranged overlapping both the first low-concentration region 62A and the second low-concentration region 62B in plan view.

With this structure, the high-concentration region 61 forms an N-layer shared by the first reverse pin junction 60A and the second reverse pin junction 60B. The pn junction 60E, which is formed by the high-concentration region 61 and the internal region 64, acts as a pn junction connected in a reverse direction to the first reverse pin junction 60A, and a pn junction connected in a reverse direction to the second reverse pin junction 60B. Thus, as long as the chip size is the same, the high-concentration region 61 and the internal region 64 may be joined over a greater area in comparison with a structure in which a pn junction connected in a reverse direction to the first reverse pin junction 60A is separate from a pn junction connected in a reverse direction to the second reverse pin junction 60B. The joined area increases the capability for absorbing surges. Accordingly, the electrical characteristics of the TVS diode 10 are improved.
(1-2) The isolation region 65 includes the exposed surface 65S exposed from the first surface 20S of the semiconductor chip 20. The TVS diode 10 includes the wiring 90 contacting the exposed surface 65S.

With this structure, current flows from the first pin junction 30 and the second pin junction 40 through the isolation region 65 to the wiring 90. The current flows from the wiring 90 through the isolation region 65 to the entire internal region 64. In comparison with a structure in which current flows through the high-concentration region 61, instead of the wiring 90, to the entire internal region 64, current flows with a lower resistance to the entire internal region 64. This increases the capability for absorbing surges and decreases the clamp voltage.
(1-3) The isolation region 65 includes the first isolation region 65A overlapping the first connection electrode 81 in plan view, the second isolation region 65B overlapping the second connection electrode 82 in plan view, and the wiring connection region 65P connected to the wiring 90. The wiring connection region 65P is arranged partially surrounding each of the first reverse pin junction 60A and the second reverse pin junction 60B in plan view.

With this structure, current flows smoothly from each of the first reverse pin junction 60A and the second reverse pin junction 60B through the wiring connection region 65P to the wiring 90. Thus, current flows with a low resistance through the entire internal region 64. This increases the surge absorption capability and decreases the clamp voltage.
(1-4) The wiring 90 is arranged individually and partially surrounding both the first connection electrode 81 and the second connection electrode 82 in plan view.

With this structure, the wiring 90 insulates the first connection electrode 81 and the second connection electrode 82 and increases the area of contact with the isolation region 65. Accordingly, current flows through the entire wiring 90 from the high-concentration region 61 to the internal region 64. Thus, current smoothly flows with a low resistance to the entire internal region 64.
(1-5) The wiring 90 has a larger area than the first connection electrode 81 in plan view.

This structure increases the area of the wiring 90 contacting the isolation region 65. Accordingly, current flows through the entire wiring 90 from the high-concentration region 61 to the internal region 64. Thus, current smoothly flows with a low resistance to the entire internal region 64.
(1-6) The wiring 90 has a smaller area than the isolation region 65 in plan view.

With this structure, the area of the wiring 90 extending out of the isolation region 65 in plan view becomes less or null. This shortens the path of the current flowing from the wiring 90 to the isolation region 65, and current of a low resistance flows through the entire internal region 64.
(1-7) The area of the wiring 90 is within a range from 75% to 97%, inclusive, of the area of the isolation region 65 in plan view.

This structure increases the area of the wiring 90 contacting the isolation region 65. Thus, in comparison with when the area of the wiring 90 is less than 75% of the isolation region 65 in plan view, current flows more smoothly in the first pin junction 30 and the second pin junction 40 from the isolation region 65 to the wiring 90. Accordingly, current flows through the entire wiring 90 from the high-concentration region 61 to the internal region 64. Thus, current smoothly flows with a low resistance to the entire internal region 64.
(1-8) The edge of the internal region 64 is located inward from the edge of the high-concentration region 61 in plan view.

With this structure, in comparison with a structure in which the edge of the internal region 64 is located at the same position as the edge of the high-concentration region 61 in plan view, electric field concentration is more limited at the edge of the internal region 64. This improves the ESD tolerance.
(1-9) The edges of the internal region 64 form corners in plan view. The corners are each curved in plan view.

This structure limits electric field concentration at each corner of the internal region 64. This improves the ESD tolerance.
(1-10) The TVS diode 10 includes the semiconductor chip 20 including the first surface 20S and the second surface 20R at a side opposite the first surface 20S. The semiconductor chip 20 includes the first pin junction 30 and the second pin junction 40 that are for the first polarity direction and are arranged in a region located toward the first surface 20S of the semiconductor chip 20. The semiconductor chip 20 also includes the diode-paired region 60 including the first reverse pin junction 60A and the second reverse pin junction 60B, which are for the second polarity direction and arranged toward the first surface 20S of the semiconductor chip 20, and the pn junction 60E, which is for the first polarity direction arranged at a position overlapping the first reverse pin junction 60A and the second reverse pin junction 60B in a plan view taken in the thickness direction of the semiconductor chip 20. The diode-paired region 60 forms a diode pair with the first reverse pin junction 60A and the second reverse pin junction 60B, in which the diode-paired region 60 is separated from both the first pin junction 30 and the second pin junction 40. The diode-paired region 60 is located between the first pin junction 30 and the second pin junction 40 in plan view.

With this structure, the arrangement of the diode-paired region 60 between the first pin junction 30 and the second pin junction 40 decreases the amplification factor of the parasitic NPN transistor between the first pin junction 30 and the second pin junction 40. Activation of the parasitic NPN transistor limits the direct flow of current from the first pin junction 30 to the second pin junction 40, and limits the direct flow of current from the second pin junction 40 to the first pin junction 30. This improves the ESD tolerance.
(1-11) The diode-paired region 60 includes the first region 66A in which the first reverse pin junction 60A is arranged, and the second region 66B in which the second reverse pin junction 60B is arranged. The second region 66B includes a part shifted from the first region 66A in the Y-direction. The first region 66A is adjacent to the second pin junction 40 in the X-direction in plan view. The second region 66B is adjacent to the first pin junction 30 in the X-direction in plan view.

With this structure, the distance between the first pin junction 30 and the second pin junction 40 may be increased, and the diode-paired region 60 may have a large area. This increases the surge absorption capability and improves the ESD tolerance.
(1-12) The first connection electrode 81 and the second connection electrode 82 are separated from each other in the X-direction in plan view. The first connection electrode 81 and the second connection electrode 82 each extend in the Y-direction in plan view.

This structure allows the first connection electrode 81 and the second connection electrode 82 to have a simple shape in plan view. Additionally, the parts of the first connection electrode 81 and the second connection electrode 82 overlapping the isolation region 65 may be decreased in plan view. This allows the area of the wiring 90 contacting the isolation region 65 to be increased.
(1-13) The semiconductor chip 20 includes the third pin junction 50 for the first polarity arranged toward the first surface 20S of the semiconductor chip 20, and the third reverse pin junction 60C for the second polarity direction arranged toward the first surface 20S of the semiconductor chip 20 and forming a diode pair with the pn junction 60E. The third pin junction 50 and the third reverse pin junction 60C are electrically connected and arranged next to each other in the Y-direction in plan view. The third pin junction 50 and the third reverse pin junction 60C are arranged adjacent to each other at a side of the second pin junction 40 and the second reverse pin junction 60B opposite the first pin junction 30 and the first reverse pin junction 60A in the X-direction in plan view. The third pin junction 50 and the second reverse pin junction 60B are adjacent to each other in the X-direction in plan view. The third reverse pin junction 60C and the second pin junction 40 are adjacent to each other in the X-direction in plan view. The diode-paired region 60 includes a region located between the second pin junction 40 and the third pin junction 50 in a direction intersecting both the X-direction and the Y-direction in plan view.

With this structure, the arrangement of the diode-paired region 60 between the second pin junction 40 and the third pin junction 50 decreases the amplification factor of the parasitic NPN transistor between the second pin junction 40 and the third pin junction 50. Activation of the parasitic NPN transistor limits the direct flow of current from the second pin junction 40 to the third pin junction 50, and limits the direct flow of current from the third pin junction 50 to the second pin junction 40. This improves the ESD tolerance.
(1-14) The high-concentration region 61 includes the first region 66A in which the first reverse pin junction 60A is arranged, the second region 66B in which the second reverse pin junction 60B is arranged, and the third region 66C in which the third reverse pin junction 60C is arranged. The second region 66B includes a part shifted from both the first region 66A and the third region 66C in the Y-direction. The second region 66B includes a part located between the first pin junction 30 and the third pin junction 50 in the X-direction. The first region 66A and the third region 66C each include a part adjacent to the second pin junction 40 in the X-direction.

With this structure, the distance between the first pin junction 30 and the second pin junction 40 may be increased, the distance between the second pin junction 40 and the third pin junction 50 may be increased, and the diode-paired region 60 may have a large area. This increases the surge absorption capability and improves the ESD tolerance.
(1-15) The first connection electrode 81, the second connection electrode 82, and the third connection electrode 83 are separated from one another in the X-direction in plan view. The first connection electrode 81, the second connection electrode 82, and the third connection electrode 83 each extend in the Y-direction in plan view.

This structure allows each of the first connection electrode 81, the second connection electrode 82, and the third connection electrode 83 to have a simple shape in plan view. Additionally, the parts of the first connection electrode 81, the second connection electrode 82, and the third connection electrode 83 overlapping the isolation region 65 may be decreased in plan view. This allows the area of the wiring 90 contacting the isolation region 65 to be increased.

### Second Embodiment

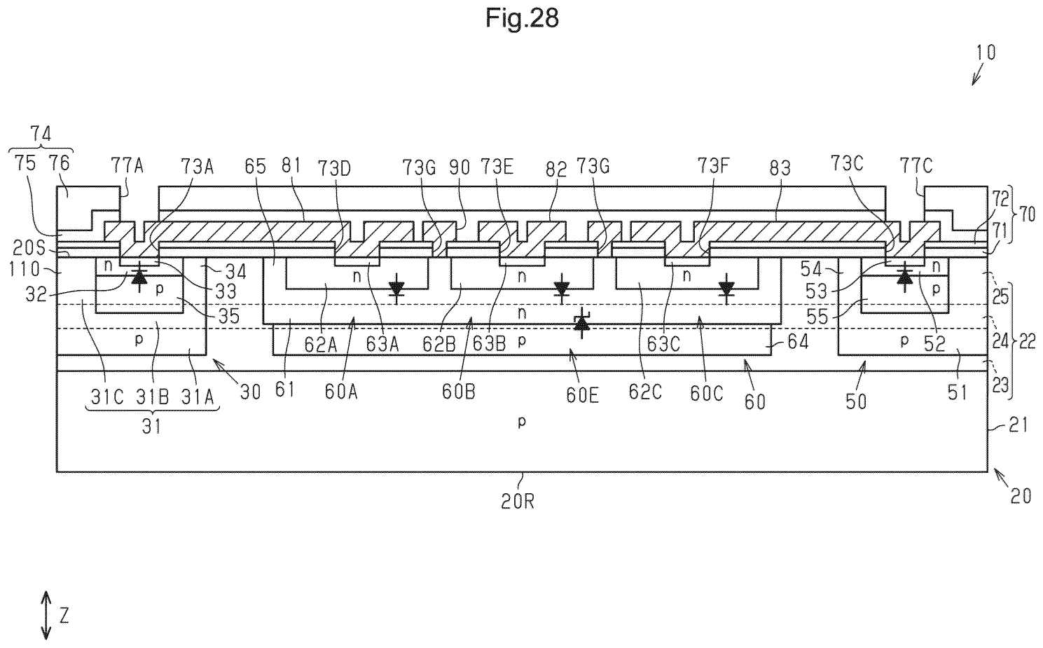

With reference to FIGS. 28 to 33, the TVS diode 10 in accordance with a second embodiment will now be described. The TVS diode 10 in accordance with the second embodiment differs from the TVS diode 10 in accordance with the first embodiment mainly in the structures of the first pin junction 30, the second pin junction 40, and the third pin junction 50. The same reference characters are given to those components that are the same as the corresponding components of the first embodiment. Such components will not be described in detail.

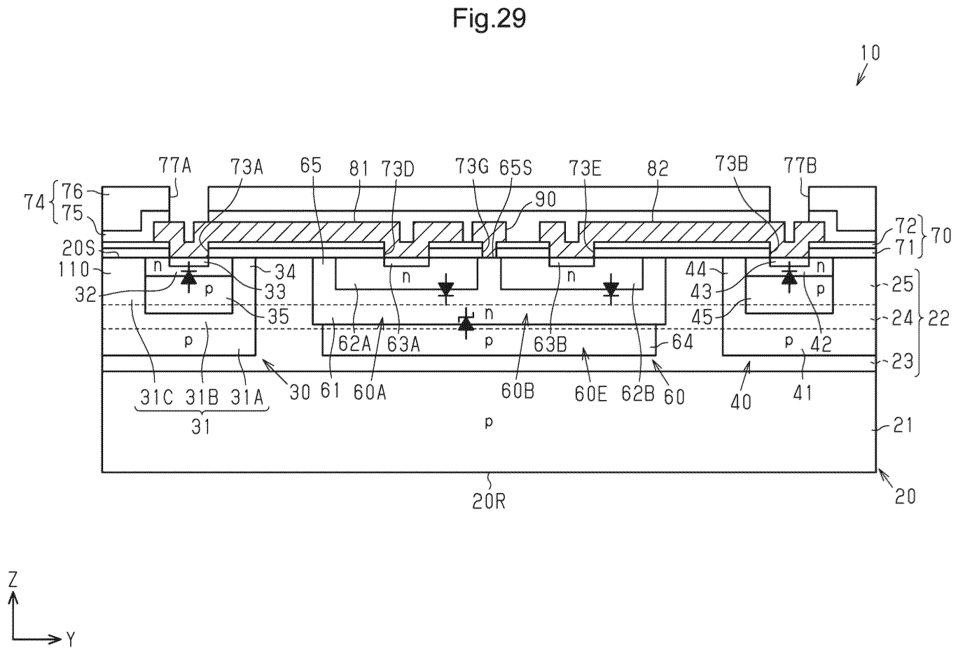

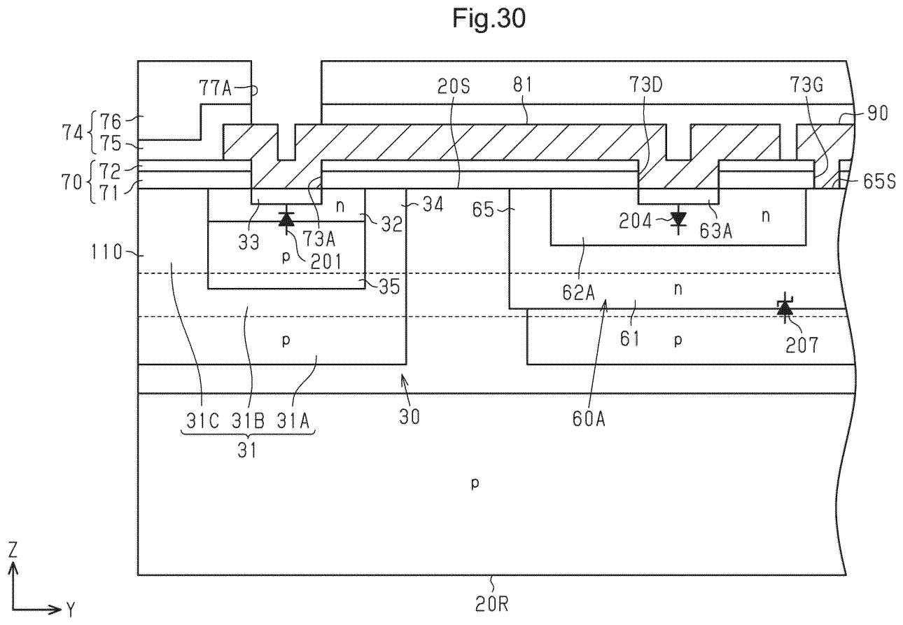

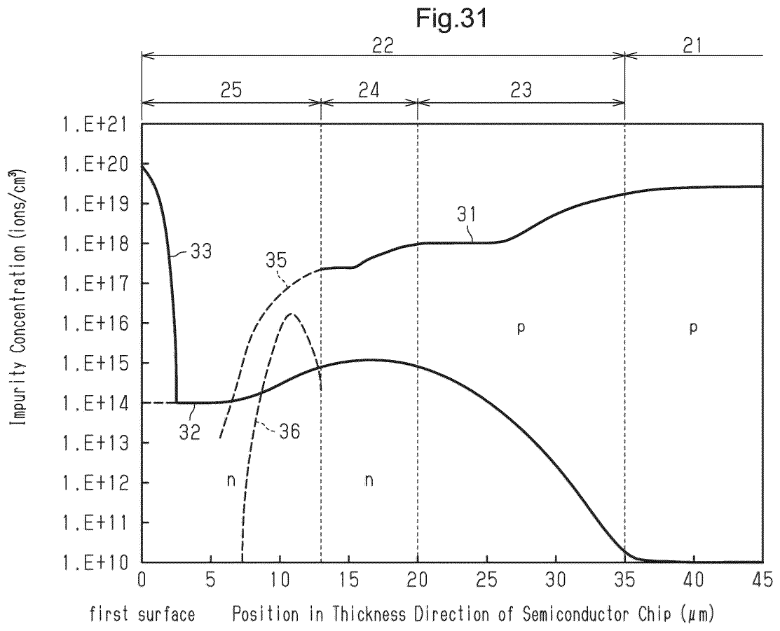

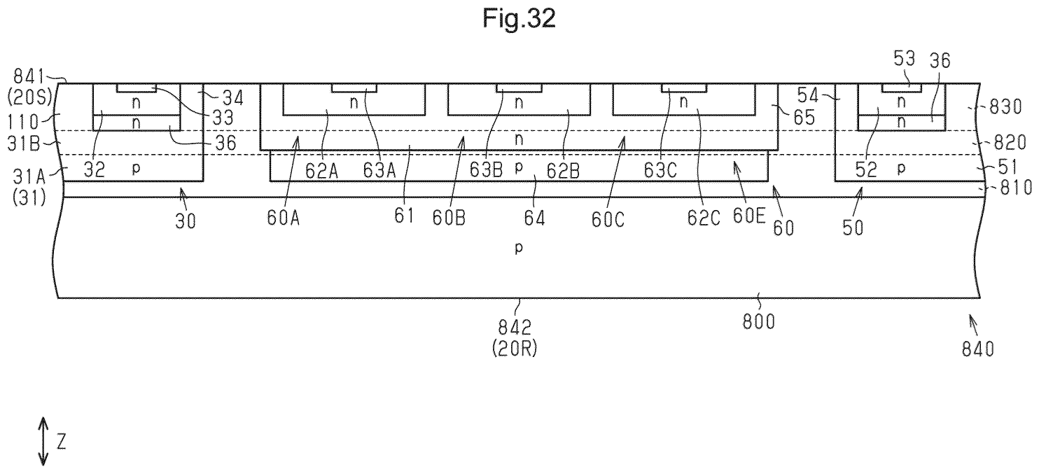

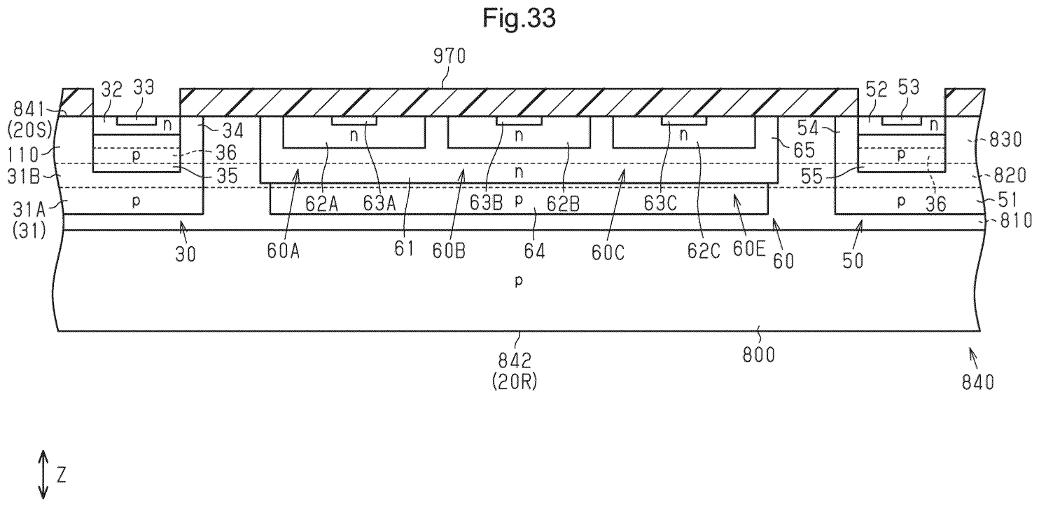

FIGS. 28 and 29 are schematic cross-sectional views of the TVS diode 10 in accordance with the second embodiment. FIG. 28 mainly shows the first pin junction 30, the third pin junction 50, and the diode-paired region 60. FIG. 29 mainly shows the first pin junction 30, the second pin junction 40, and the diode-paired region 60. FIG. 30 is an enlarged, cross-sectional view showing the first pin junction 30 of FIG. 28. FIG. 31 is a graph showing the position of the first pin junction 30 in the Z-direction in relation to the impurity concentration. FIG. 32 and FIG. 33 are schematic cross-sectional views illustrating exemplary manufacturing steps of the TVS diode 10 in accordance with the second embodiment.

As shown in FIG. 28, the first pin junction 30 includes a first buffer region 35 of the p-type. The first buffer region 35 is located between the first terminal high-concentration region 31 and the first terminal low-concentration region 32 in the Z-direction. The first buffer region 35 is in contact with the first terminal high-concentration region 31. The first buffer region 35 is in contact with the first terminal low-concentration region 32. The first partitioning region 34 is arranged surrounding the first buffer region 35 in plan view. In the second embodiment, the first pin junction 30 is formed by the first terminal contact region 33, the first terminal low-concentration region 32, and the first buffer region 35. The first terminal contact region 33 forms an N-layer, the first terminal low-concentration region 32 forms an I-layer, and the first buffer region 35 forms a P-layer.

As shown in FIG. 29, the second pin junction 40 includes a second buffer region 45 of the p-type. The second buffer region 45 is located between the second terminal high-concentration region 41 and the second terminal low-concentration region 42 in the Z-direction. The second buffer region 45 is in contact with the second terminal high-concentration region 41. The second buffer region 45 is in contact with the second terminal low-concentration region 42. The second partitioning region 44 surrounds the second buffer region 45 in plan view. In the second embodiment, the second pin junction 40 is formed by the second terminal contact region 43, the second terminal low-concentration region 42, and the second buffer region 45. The second terminal contact region 43 forms an N-layer, the second terminal low-concentration region 42 forms an I-layer, and the second buffer region 45 forms a P-layer.

As shown in FIG. 28, the third pin junction 50 includes a third buffer region 55 of the p-type. The third buffer region 55 is located between the third terminal high-concentration region 51 and the third terminal low-concentration region 52 in the Z-direction. The third buffer region 55 is in contact with the third terminal high-concentration region 51. The third buffer region 55 is in contact with the third terminal low-concentration region 52. The third partitioning region 54 is arranged surrounding the third buffer region 55 in plan view. In the second embodiment, the third pin junction 50 is formed by the third terminal contact region 53, the third terminal low-concentration region 52, and the third buffer region 55. The third terminal contact region 53 forms an N-layer, the third terminal low-concentration region 52 forms an I-layer, and the third buffer region 55 forms a P-layer.

The first pin junction 30, the second pin junction 40, and the third pin junction 50 are identical in structure. Thus, only the first pin junction 30 will be described in detail hereafter. The second pin junction 40 and the third pin junction 50 will not be described in detail.

As shown in FIG. 30, the first buffer region 35 is arranged at the boundary of the second semiconductor layer 24 and the third semiconductor layer 25. That is, the boundary of the first buffer region 35 and the first terminal high-concentration region 31 in the Z-direction is located in the second semiconductor layer 24. Thus, the first terminal high-concentration region 31 is thinner than the first terminal high-concentration region 31 of the first embodiment (refer to FIG. 2).

The boundary of the first buffer region 35 and the first terminal low-concentration region 32 is located closer to the first surface 20S of the semiconductor chip 20 than the boundary of the high-concentration region 61 and the first low-concentration region 62A is in the diode-paired region 60. Thus, the first terminal low-concentration region 32 is thinner than the first terminal low-concentration region 32 of the first embodiment (refer to FIG. 2). In one example, the first terminal low-concentration region 32 is thinner than the first low-concentration region 62A. The first terminal low-concentration region 32 is thinner than the first buffer region 35.

As shown in FIG. 31, the p-type impurity concentration in the first buffer region 35 may be within a range of 1×10¹⁴ cm⁻³ to 5×10¹⁷ cm⁻³, inclusive. The first buffer region 35 has a concentration gradient, where the p-type impurity concentration decreases in the Z-direction from the first terminal high-concentration region 31 toward the first terminal low-concentration region 32. Thus, the p-type impurity concentration in the first buffer region 35 is the maximum at the boundary of the first buffer region 35 and the first terminal high-concentration region 31, and is the minimum at the boundary of the first buffer region 35 and the first terminal low-concentration region 32. Thus, the first buffer region 35 has a lower p-type impurity concentration than the first terminal high-concentration region 31. Further, the p-type impurity concentration in the first buffer region 35 may be equal to the n-type impurity concentration in the first terminal low-concentration region 32 at the boundary of the first buffer region 35 and the first terminal low-concentration region 32. In one example, the p-type impurity concentration at the boundary of the first buffer region 35 and the first terminal low-concentration region 32 may be 1×10¹⁴ cm⁻³. As shown in FIG. 31, the p-type impurity concentration in the first buffer region 35 is greater than or equal to the n-type impurity concentration in the first terminal low-concentration region 32.

The p-type impurity concentration in the second buffer region 45 and the p-type impurity concentration in the third buffer region 55 have the same concentration gradient as the p-type impurity concentration in the first buffer region 35. Thus, the second buffer region 45 has a lower p-type impurity concentration than the second terminal high-concentration region 41. The second buffer region 45 has a concentration gradient, where the p-type impurity concentration decreases in the Z-direction from the second terminal high-concentration region 41 toward the second terminal low-concentration region 42. The p-type impurity concentration in the second buffer region 45 is greater than or equal to the n-type impurity concentration in the second terminal low-concentration region 42. The third buffer region 55 has a lower p-type impurity concentration than the third terminal high-concentration region 51. The third buffer region 55 has a concentration gradient, where the p-type impurity concentration decreases in the Z-direction from the third terminal high-concentration region 51 toward the third terminal low-concentration region 52. The p-type impurity concentration in the third buffer region 55 is greater than or equal to the n-type impurity concentration in the third terminal low-concentration region 52.

### Method for Manufacturing TVS Diode

One example of a method for manufacturing the TVS diode 10 in accordance with the second embodiment will now be described. The second embodiment differs from the first embodiment in that steps of forming the first buffer region 35, the second buffer region 45, and the third buffer region 55 are added. These steps will now be described.

The steps of forming the first buffer region 35, the second buffer region 45, and the third buffer region 55 are performed after the steps of forming the isolation region 65, the first terminal contact region 33, the second terminal contact region 43, and the third terminal contact region 53. The step of forming the first buffer region 35 will be described below.

FIGS. 32 and 33 show the cross-sectional structure subsequent to the step of forming the first terminal contact region 33, the second terminal contact region 43, and the third terminal contact region 53. FIGS. 32 and 33 do not show the second pin junction 40. The second pin junction 40 is shown in FIG. 29.

As shown in FIG. 32, the n-type impurities in the isolation region 65, the first terminal contact region 33, the second terminal contact region 43, and the third terminal contact region 53 form an autodoping layer 36 at the end of the first terminal low-concentration region 32 close to the first terminal high-concentration region 31. As shown in FIG. 31, the n-type impurity concentration in the autodoping layer 36 is greater than the n-type impurity concentration in the first terminal low-concentration region 32. In one example, the n-type impurity concentration in the autodoping layer 36 has a peak value of approximately 1×10¹⁶ cm³.

As shown in FIG. 33, in the step of forming the first buffer region 35, for example, an ion implantation process is performed using an ion implantation mask 970 to implant p-type impurities into the first terminal high-concentration region 31. The implantation energy (ion accelerating voltage) is adjusted to implant p-type impurities into the autodoping layer 36. The first buffer region 35 is formed in the autodoping layer 36. The steps of forming the second buffer region 45 and the third buffer region 55 are similar to the step of forming the first buffer region 35 and thus will not be described.

### Operation

With reference to FIGS. 31 and 32, the operation of the TVS diode 10 in accordance with the second embodiment will now be described. The first pin junction 30 will be described below. The same applies to the second pin junction 40 and the third pin junction 50.

As shown in FIGS. 31 and 32, the autodoping layer 36 formed in the manufacturing process of the TVS diode 10 has a greater n-type impurity concentration than the first terminal low-concentration region 32. Thus, the junction capacitance of the autodoping layer 36 and the first terminal high-concentration region 31 in the first pin junction 30 is greater than the junction capacitance of the first terminal low-concentration region 32 and the first terminal high-concentration region 31.

In this respect, the TVS diode 10 in accordance with the second embodiment includes the first buffer region 35 of the p-type between the first terminal high-concentration region 31 and the first terminal low-concentration region 32. This allows the n-type impurities in the autodoping layer 36 to be offset by the p-type impurities in the first buffer region 35. Thus, in the first pin junction 30, the junction of the autodoping layer 36 and the first terminal high-concentration region 31 is replaced by the junction of the first buffer region 35 and the first terminal low-concentration region 32. This eliminates parts where the n-type impurity concentration is high from the first terminal low-concentration region 32 and thus limits increases in the junction capacitance of the first pin junction 30.

### Advantages

The TVS diode 10 in accordance with the second embodiment has the advantages described below.
(2-1) The TVS diode 10 includes the semiconductor chip 20 including the first surface 20S and the first surface 20S at a side opposite to the second surface 20R. The semiconductor chip 20 includes the first pin junction 30 for the first polarity direction arranged toward the first surface 20S of the semiconductor chip 20, the diode-paired region 60 including the first reverse pin junction 60A for the second polarity direction separated from the first pin junction 30 in a plan view taken in a thickness direction of the semiconductor chip 20 and the pn junction 60E for the first polarity direction forming a diode pair with the first reverse pin junction 60A, the first terminal high-concentration region 31 of the p-type separated from the first surface 20S of the semiconductor chip 20 and arranged toward the second surface 20R, the first terminal low-concentration region 32 of the n-type arranged closer to the first surface 20S than the first terminal high-concentration region 31 is at a position overlapping the first terminal high-concentration region 31 in plan view, and the first terminal contact region 33 of the n-type arranged in the outer portion of the first terminal low-concentration region 32, the first buffer region 35 of the p-type contacting the first terminal high-concentration region 31 between the first terminal high-concentration region 31 and the first terminal low-concentration region 32 in the thickness direction of the semiconductor chip 20. The first terminal contact region 33, the first terminal low-concentration region 32, and the first buffer region 35 form a pin diode.

With this structure, even if a part located toward the first terminal high-concentration region 31 is formed with a high n-type impurity concentration in the first terminal low-concentration region 32 during the manufacturing process of the TVS diode 10, the first buffer region 35 will eliminate the part where the n-type impurity concentration is high. This limits increases in the junction capacitance at the first pin junction 30.
(2-2) The first buffer region 35 has a lower p-type impurity concentration than the first terminal high-concentration region 31.

This structure decreases the junction capacitance of the first buffer region 35 and the first terminal low-concentration region 32, thereby decreasing the junction capacitance of the first pin junction 30.
(2-3) The p-type impurity concentration in the first buffer region 35 decreases in the thickness direction of the semiconductor chip 20 from the first terminal high-concentration region 31 toward the first terminal low-concentration region 32.

With this structure, the p-type impurity concentration in the first buffer region 35 becomes the minimum at the boundary of the first buffer region 35 and the first terminal low-concentration region 32. This decreases the junction capacitance of the first buffer region 35 and the first terminal low-concentration region 32, thereby decreasing the junction capacitance of the first pin junction 30.
(2-4) The semiconductor chip 20 includes the second pin junction 40 for the first polarity direction arranged toward the first surface 20S of the semiconductor chip 20 in a region separated from the first pin junction 30 in plan view, the second terminal high-concentration region 41 of the p-type separated from the first surface 20S of the semiconductor chip 20 and arranged toward the second surface 20R, the second terminal high-concentration region 41 being separated from the first terminal high-concentration region 31 in plan view, the second terminal low-concentration region 42 of the n-type arranged closer to the first surface 20S than the second terminal high-concentration region 41 is at a position overlapping the second terminal high-concentration region 41 in plan view, the second terminal contact region 43 of the n-type arranged in the outer portion of the second terminal low-concentration region 42, and the second buffer region 45 of the p-type contacting the second terminal high-concentration region 41 between the second terminal high-concentration region 41 and the second terminal low-concentration region 42 in the thickness direction of the semiconductor chip 20. The second buffer region 45, the second terminal low-concentration region 42, and the second terminal contact region 43 form the second pin junction 40.

With this structure, even if a part located toward the second terminal high-concentration region 41 is formed with a high n-type impurity concentration in the second terminal low-concentration region 42 during the manufacturing process of the TVS diode 10, the second buffer region 45 will eliminate the part where the n-type impurity concentration is high. This limits increases in the junction capacitance at the second pin junction 40.
(2-5) The second buffer region 45 has a lower p-type impurity concentration than the second terminal high-concentration region 41.

This structure decreases the junction capacitance of the second buffer region 45 and the second terminal low-concentration region 42, thereby decreasing the junction capacitance of the second pin junction 40.
(2-6) The p-type impurity concentration in the second buffer region 45 decreases in the semiconductor chip 20 from the second terminal high-concentration region 41 toward the second terminal low-concentration region 42.

With this structure, the p-type impurity concentration in the second buffer region 45 becomes the minimum at the boundary of the second buffer region 45 and the second terminal low-concentration region 42. This decreases the junction capacitance of the second buffer region 45 and the second terminal low-concentration region 42, thereby decreasing the junction capacitance of the second pin junction 40.
(2-7) The semiconductor chip 20 includes the third pin junction 50 for the first polarity direction arranged toward the first surface 20S of the semiconductor chip 20 in a region separated from both the first pin junction 30 and the second pin junction 40 in plan view, the third terminal high-concentration region 51 of the p-type separated from the first surface 20S of the semiconductor chip 20 and arranged toward the second surface 20R, the third terminal high-concentration region 51 being separated from both the first terminal high-concentration region 31 and the second terminal high-concentration region 41 in plan view, the third terminal low-concentration region 52 of the n-type arranged closer to the first surface 20S than the third terminal high-concentration region 51 is at a position overlapping the third terminal high-concentration region 51 in plan view, the third terminal contact region 53 of the n-type arranged in the outer portion of the third terminal low-concentration region 52, and the third buffer region 55 of the p-type contacting the third terminal high-concentration region 51 between the third terminal high-concentration region 51 and the third terminal low-concentration region 52 in the thickness direction of the semiconductor chip 20. The third buffer region 55, the third terminal low-concentration region 52, and the third terminal contact region 53 form the third pin junction 50.

With this structure, even if a part located toward the third terminal high-concentration region 51 is formed with a high n-type impurity concentration in the third terminal low-concentration region 52 during the manufacturing process of the TVS diode 10, the third buffer region 55 will eliminate the part where the n-type impurity concentration is high. This limits increases in the junction capacitance at the third pin junction 50.
(2-8) The third buffer region 55 has a lower p-type impurity concentration than the third terminal high-concentration region 51.

This structure decreases the junction capacitance of the third buffer region 55 and the third terminal low-concentration region 52, thereby decreasing the junction capacitance of the third pin junction 50.
(2-9) The p-type impurity concentration in the third buffer region 55 decreases in the thickness direction of the semiconductor chip 20 from the third terminal high-concentration region 51 toward the third terminal low-concentration region 52.

With this structure, the p-type impurity concentration in the third buffer region 55 becomes the minimum at the boundary of the third buffer region 55 and the third terminal low-concentration region 52. This decreases the junction capacitance of the third buffer region 55 and the third terminal low-concentration region 52, thereby decreasing the junction capacitance of the third pin junction 50.

### Third Embodiment

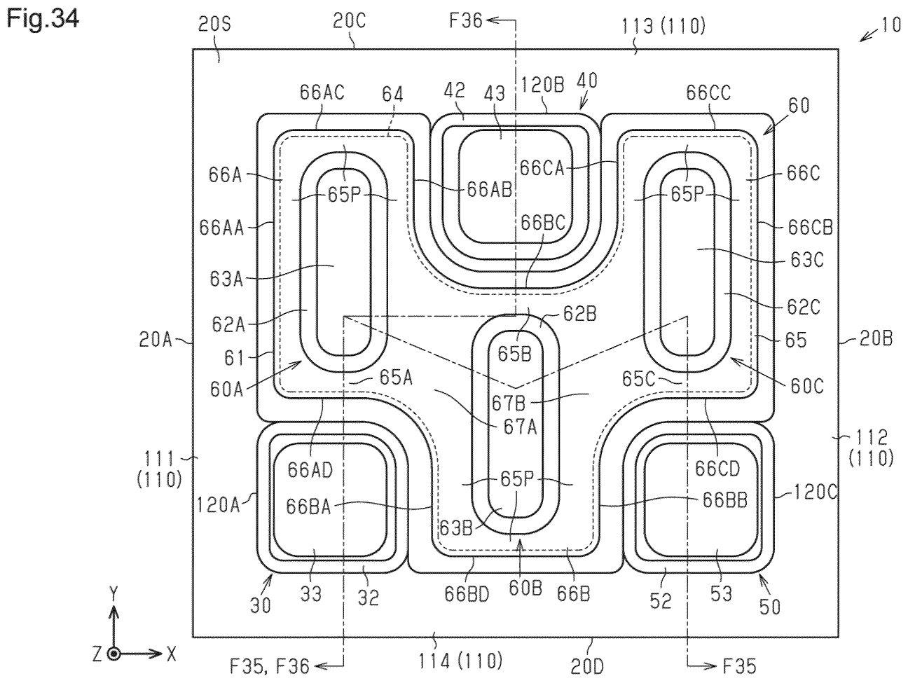

With reference to FIGS. 34 to 39, the TVS diode 10 in accordance with a third embodiment will now be described. The TVS diode 10 in accordance with the third embodiment differs from the TVS diode 10 in accordance with the first embodiment mainly in the structures of the first pin junction 30, the second pin junction 40, and the third pin junction 50. The same reference characters are given to those components that are the same as the corresponding components of the first embodiment. Such components will not be described in detail.

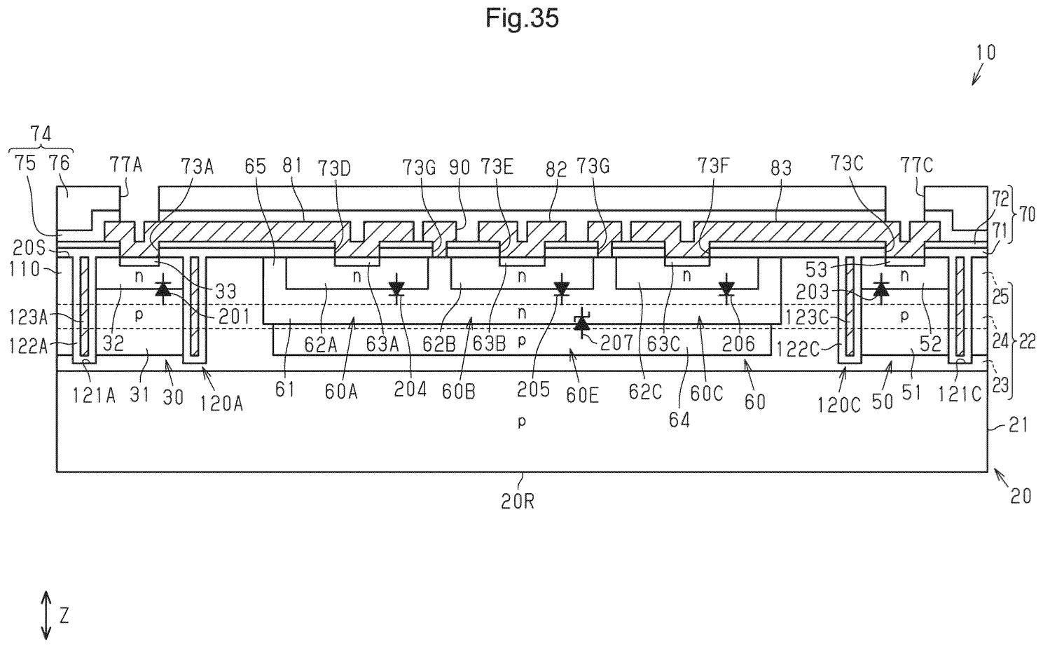

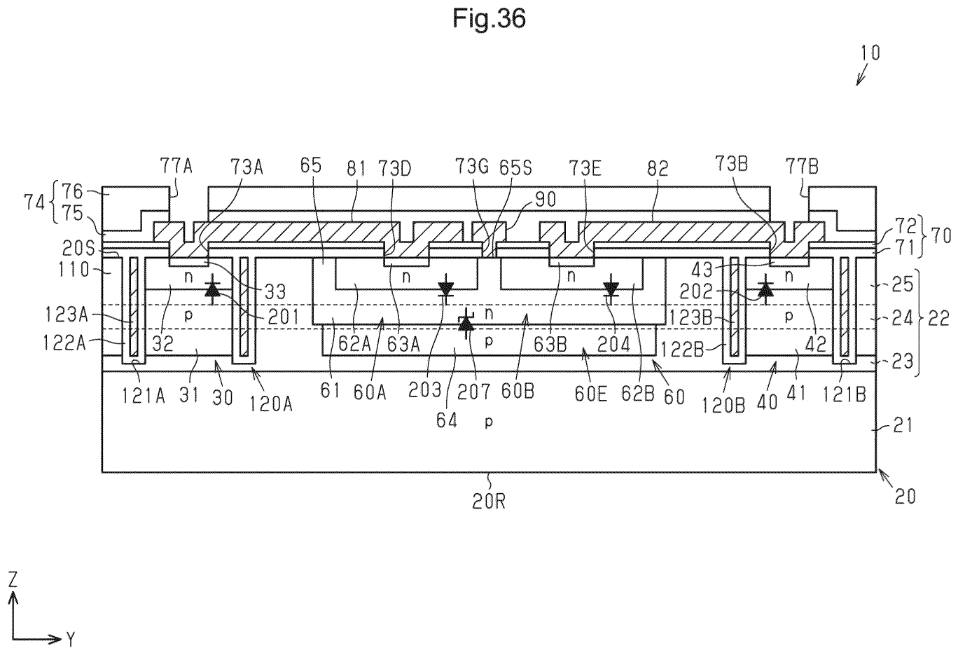

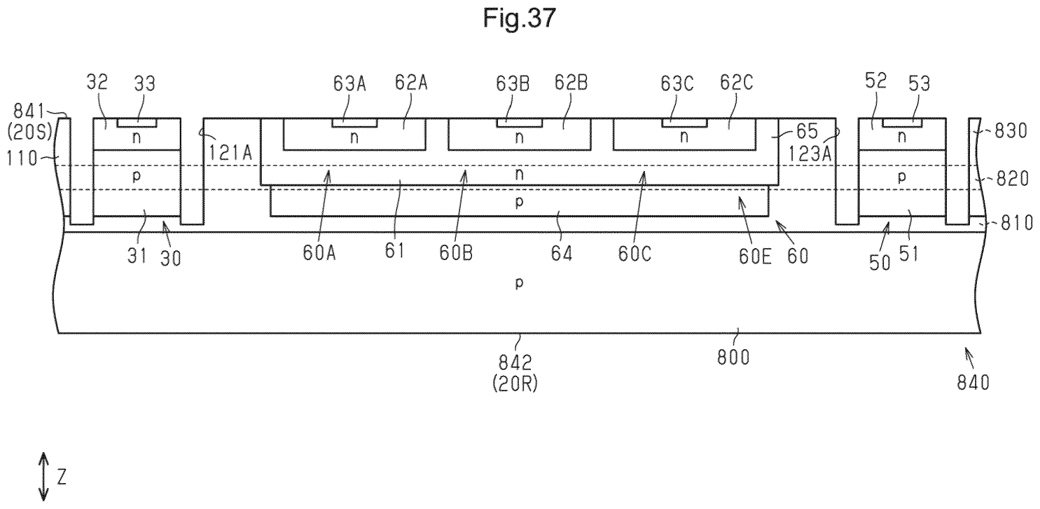

FIG. 34 is a schematic plan view of the semiconductor chip 20 in the TVS diode 10 in accordance with the third embodiment. FIG. 35 is a schematic cross-sectional view of the TVS diode 10 taken along line F35-F35 in FIG. 34. FIG. 36 is a schematic cross-sectional view of the TVS diode 10 taken along line F36-F36 in FIG. 34. FIGS. 37 to 39 are schematic cross-sectional views showing exemplary manufacturing steps of the TVS diode 10 in accordance with the third embodiment.

As shown in FIGS. 34 and 35, the first pin junction 30 includes a first isolation trench structure 120A instead of the first partitioning region 34 (refer to FIG. 2). The first isolation trench structure 120A, for example, partitions the first pin junction 30 from the diode-paired region 60.

The first isolation trench structure 120A includes a first isolation trench 121A, a first isolation-insulation layer 122A, and a first isolation electrode 123A.

The first isolation trench 121A surrounds the first terminal high-concentration region 31 in plan view. In one example, the first isolation trench 121A has the form of a quadrilateral frame in plan view. The first isolation trench 121A is formed by etching the first surface 20S of the semiconductor chip 20 toward the second surface 20R. The first isolation trench 121A extends through the third semiconductor layer 25 and the second semiconductor layer 24 to the first semiconductor layer 23. In one example, the first isolation trench 121A has a bottom wall that is located closer to the second surface 20R of the semiconductor chip 20 in the Z-direction than the boundary of the first terminal high-concentration region 31 and the first semiconductor layer 23 is. Thus, the bottom wall of the first isolation trench 121A exposes the first semiconductor layer 23.

The first isolation trench 121A includes an inner wall and an outer wall. The inner wall of the first isolation trench 121A exposes the first terminal low-concentration region 32 and the first terminal high-concentration region 31. The outer wall of the first isolation trench 121A exposes the first to third semiconductor layers 23 to 25. Thus, the first isolation trench 121A isolates the first terminal low-concentration region 32 and the first terminal high-concentration region 31 from the second semiconductor layer 24 and the third semiconductor layer 25.

The inner and outer walls of the first isolation trench 121A are both orthogonal to the first surface 20S of the semiconductor chip 20. Further, the inner and outer walls of the first isolation trench 121A may both be inclined to become closer to each other as the bottom wall of the first surface 20S becomes closer.

The width of the first isolation trench 121A may be in a range from 0.1 μm to 3 μm, inclusive. In one example, the width of the first isolation trench 121A is in a range from 1.5 m to 2.5 μm, inclusive. The width of the first isolation trench 121A may be defined as the distance between the inner wall and the outer wall in plan view in a direction orthogonal to the direction in which the first isolation trench 121A extends.

The depth of the first isolation trench 121A may be in a range from 1 μm to 50 μm, inclusive. In one example, the depth of the first isolation trench 121A is in a range from 15 μm to m, inclusive. The depth of the first isolation trench 121A may be defined as the distance in the Z-direction between the first surface 20S of the semiconductor chip 20 and the bottom surface of the first isolation trench 121A.

The first isolation-insulation layer 122A is arranged in the first isolation trench 121A. More specifically, the first isolation-insulation layer 122A has the form of a film extending along the walls of the first isolation trench 121A. Thus, the first isolation-insulation layer 122A defines a recessed space in the first isolation trench 121A.

The first isolation-insulation layer 122A may include at least one of a SiO₂ layer and a SiN layer. The first isolation-insulation layer 122A may have a laminate structure formed by laminating a SiO₂ layer and a SiN layer in any order. The first isolation-insulation layer 122A may have a monolayer structure formed by a SiO₂ layer or a SiN layer. The first isolation-insulation layer 122A may be composed of the same insulative material as the first insulation layer 71. In one example, the first isolation-insulation layer 122A has a monolayer structure formed by a SiO₂ layer.

The first isolation electrode 123A is embedded in the first isolation trench 121A with the first isolation-insulation layer 122A interposed. The first isolation electrode 123A has the form of a frame surrounding the first terminal high-concentration region 31 in plan view. In one example, the first isolation electrode 123A has the form of a quadrilateral frame in plan view. The first isolation electrode 123A may be composed of, for example, polysilicon. The first isolation electrode 123A is in an electrically floating state.

As shown in FIGS. 34 and 36, the second pin junction 40 includes a second isolation trench structure 120B instead of the second partitioning region 44 (refer to FIG. 3). The second isolation trench structure 120B, for example, partitions the second pin junction 40 from the diode-paired region 60. The second isolation trench structure 120B includes a second isolation trench 121B, a second isolation-insulation layer 122B, and a second isolation electrode 123B. The second isolation trench 121B is arranged in the first surface 20S of the semiconductor chip 20 to partition the second pin junction 40 from the diode-paired region 60. The second isolation-insulation layer 122B is arranged in the second isolation trench 121B. The second isolation electrode 123B is embedded in the second isolation trench 121B with the second isolation-insulation layer 122B interposed. The second isolation electrode 123B is in an electrically floating state. The structures of the second isolation trench 121B, the second isolation-insulation layer 122B, and the second isolation electrode 123B are respectively the same as the first isolation trench 121A, the first isolation-insulation layer 122A, and the first isolation electrode 123A and thus will not be described in detail.

As shown in FIGS. 34 and 35, the third pin junction 50 includes a third isolation trench structure 120C instead of the third partitioning region 54 (refer to FIG. 2). The third isolation trench structure 120C, for example, partitions the third pin junction 50 from the diode-paired region 60. The third isolation trench structure 120C includes a third isolation trench 121C, a third isolation-insulation layer 122C, and a third isolation electrode 123C. The third isolation trench 121C is arranged in the first surface 20S of the semiconductor chip 20 to partition the third pin junction 50 from the diode-paired region 60. The third isolation-insulation layer 122C is arranged in the third isolation trench 121C. The third isolation electrode 123C is embedded in the third isolation trench 121C with the third isolation-insulation layer 122C interposed. The third isolation electrode 123C is in an electrically floating state. The structures of the third isolation trench 121C, the third isolation-insulation layer 122C, and the third isolation electrode 123C are respectively the same as the first isolation trench 121A, the first isolation-insulation layer 122A, and the first isolation electrode 123A and thus will not be described in detail.

### Method for Manufacturing TVS Diode

One example of a method for manufacturing the TVS diode 10 in accordance with the third embodiment will now be described. The method for manufacturing the TVS diode 10 in accordance with the third embodiment differs from the first embodiment mainly in that steps of forming the first isolation trench structure 120A, the second isolation trench structure 120B, and the third isolation trench structure 120C are performed instead of the steps of forming the first partitioning region 34, the second partitioning region 44, and the third partitioning region 54. These steps will now be described.

FIGS. 37 to 39 show steps of forming the first isolation trench structure 120A and the third isolation trench structure 120C. Although not shown in the drawings, the second isolation trench structure 120B is formed in the same manner as the first isolation trench structure 120A and the third isolation trench structure 120C.

In the step shown in FIG. 37, the first isolation trench 121A and the third isolation trench 121C are formed. More specifically, a hard mask having a predetermined pattern (not shown) is formed on the first surface 20S of the semiconductor chip 20. The hard mask exposes regions of the first surface 20S where the isolation trenches 121A, 121B, and 121C are to be formed and covers the remaining regions. The hard mask may be formed through a CVD process or an oxidation process. The hard mask may be patterned through an etching process using an etching mask. Then, an etching process using the hard mask is performed to remove regions of the first surface 20S of the semiconductor chip 20 exposed from the hard mask. The etching process may be a dry etching process. One example of a dry etching process is reactive ion etching (RIE). This forms the first isolation trench 121A, the second isolation trench 121B, and the third isolation trench 121C. Then, the hard mask is removed.

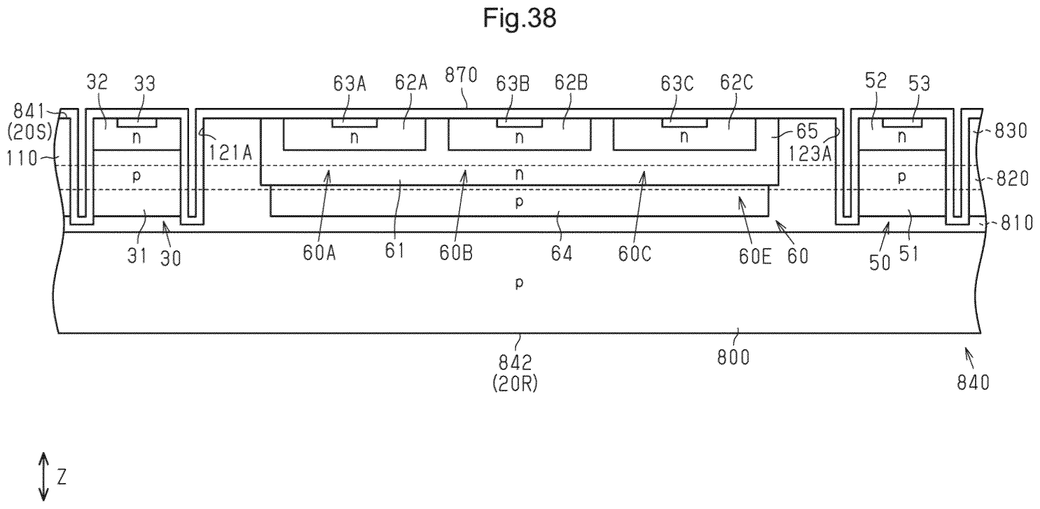

As shown in FIG. 38, the step of forming the first isolation trench structure 120A and the third isolation trench structure 120C includes forming an insulation layer 870. The insulation layer 870 is formed on the first surface 20S of the semiconductor chip 20 and the walls of each of the isolation trenches 121A, 121B, and 121C. The insulation layer 870 forms the first isolation-insulation layer 122A and the third isolation-insulation layer 122C. Although not shown in the drawings, the insulation layer 870 forms the second isolation-insulation layer 122B. The insulation layer 870 may be formed through a CVD process or an oxidation process (e.g., thermal oxidation process). In one example, the insulation layer 870 is formed through a thermal oxidation process.

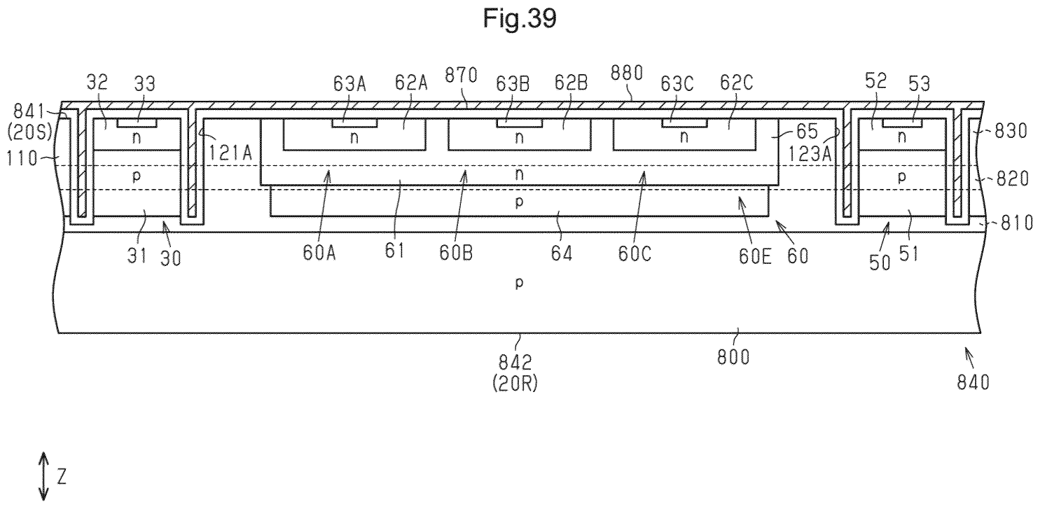

As shown in FIG. 39, the step of forming the first isolation trench structure 120A and the third isolation trench structure 120C includes forming the first isolation electrode 123A and the third isolation electrode 123C. In this step, an electrode layer 880 is formed on the insulation layer 870. The electrode layer 880 forms the first isolation electrode 123A and the third isolation electrode 123C. Although not shown in the drawings, the electrode layer 880 forms the second isolation electrode 123B. The electrode layer 880 may be composed of, for example, polysilicon. The electrode layer 880 is embedded in each of the isolation trenches 121A, 121B, and 121C with the insulation layer 870 interposed. The electrode layer 880 may be formed through, for example, a CVD process.

Although not shown in the drawings, an etching process is performed to remove unnecessary parts from the electrode layer 880. Parts of the electrode layer 880 that are not embedded in the isolation trenches 121A and 121C are removed. The electrode layer 880 is removed until the insulation layer 870 is exposed. This forms the first isolation electrode 123A and the third isolation electrode 123C. The steps described above form the first isolation trench structure 120A and the third isolation trench structure 120C. Parts of the electrode layer 880 that are not embedded in the second isolation trench 121B are removed form the second isolation electrode 123B. This forms the second isolation trench structure 120B.

Then, a step of forming the insulation layer 850 (not shown) is performed. The first insulation layer 851 of the insulation layer 850 covers the first isolation trench structure 120A, the second isolation trench structure 120B, and the third isolation trench structure 120C. Thus, each of the isolation electrodes 123A, 123B, and 123C is covered by the insulation layer 870 and the first insulation layer 851.

### Advantages

The TVS diode 10 in accordance with the third embodiment has the advantages described below.
(3-1) The semiconductor chip 20 includes the first isolation trench 121A arranged in the first surface 20S and partitioning the first pin junction 30 from the diode-paired region 60, and the second isolation trench 121B arranged in the first surface 20S and partitioning the second pin junction 40 from the diode-paired region 60. The TVS diode 10 includes the first isolation-insulation layer 122A arranged in the first isolation trench 121A, and the second isolation-insulation layer 122B arranged in the second isolation trench 121B.

With this structure, the insulation between the first pin junction 30 and the diode-paired region 60 is improved, and the insulation between the second pin junction 40 and the diode-paired region 60 is improved. This allows the gap to be decreased from the first pin junction 30 and the second pin junction 40 to the diode-paired region 60. Thus, as long as the chip size is the same, the area of the diode-paired region 60 in plan view may be increased, thereby improving the surge absorption capability. As long as the area of the diode-paired region 60 in plan view is the same, the gap is decreased from the first pin junction 30 and the second pin junction 40 to the diode-paired region 60. This allows the TVS diode 10 to be reduced in size.

### Fourth Embodiment

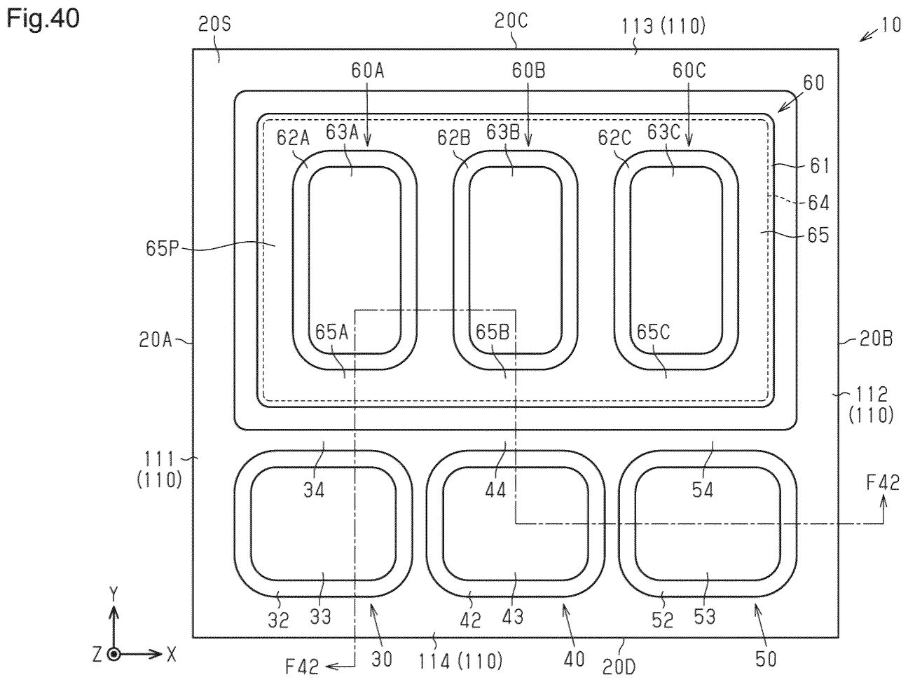

With reference to FIGS. 40 to 43, the TVS diode 10 in accordance with a fourth embodiment will now be described. The TVS diode 10 in accordance with the fourth embodiment differs from the TVS diode 10 in accordance with the first embodiment mainly in the planar structure of the TVS diode 10. The same reference characters are given to those components that are the same as the corresponding components of the first embodiment. Such components will not be described in detail.

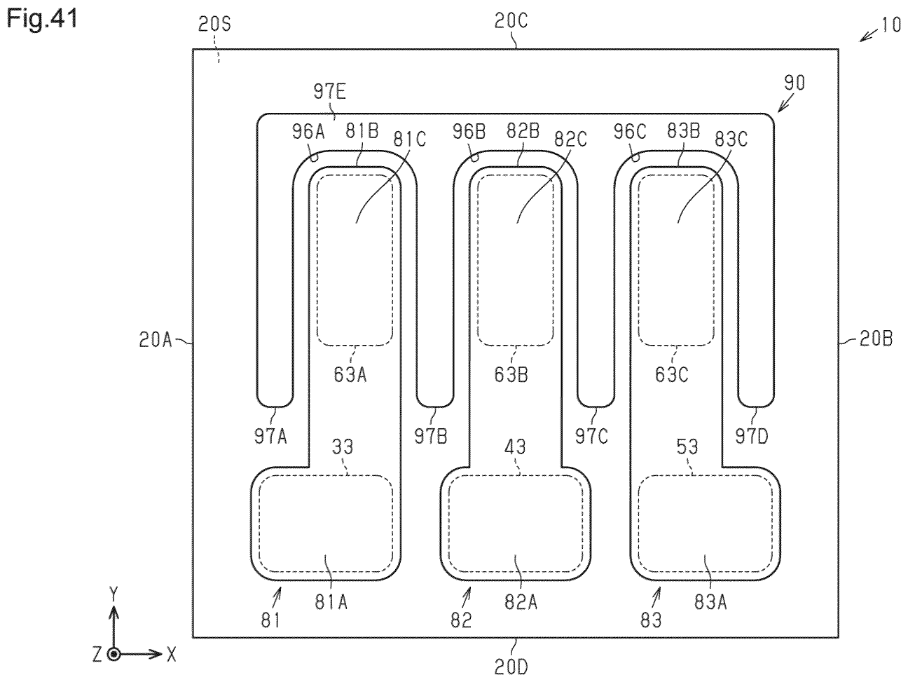

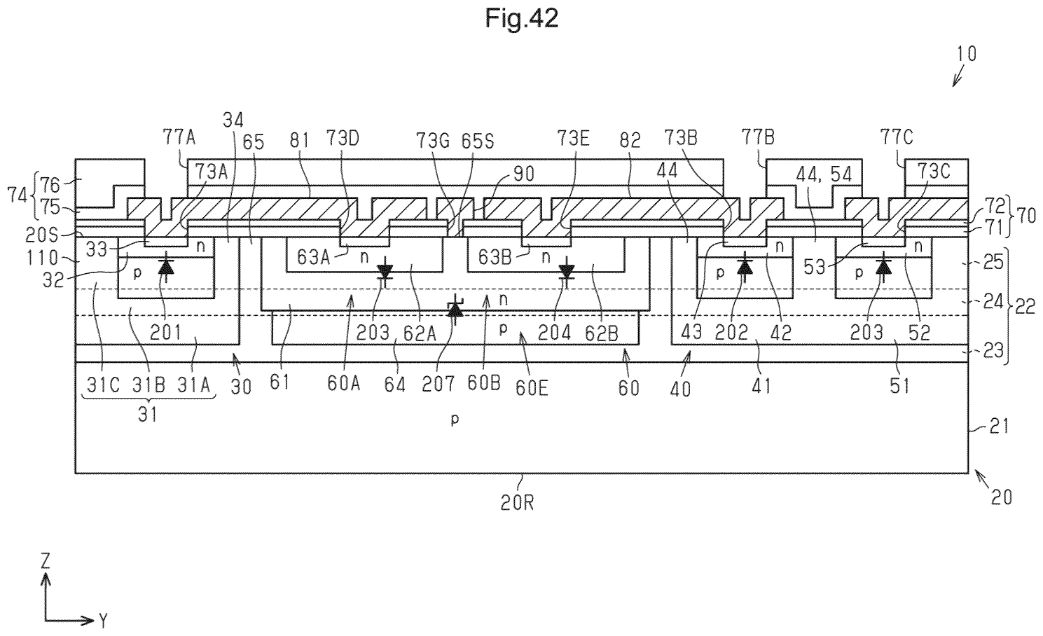

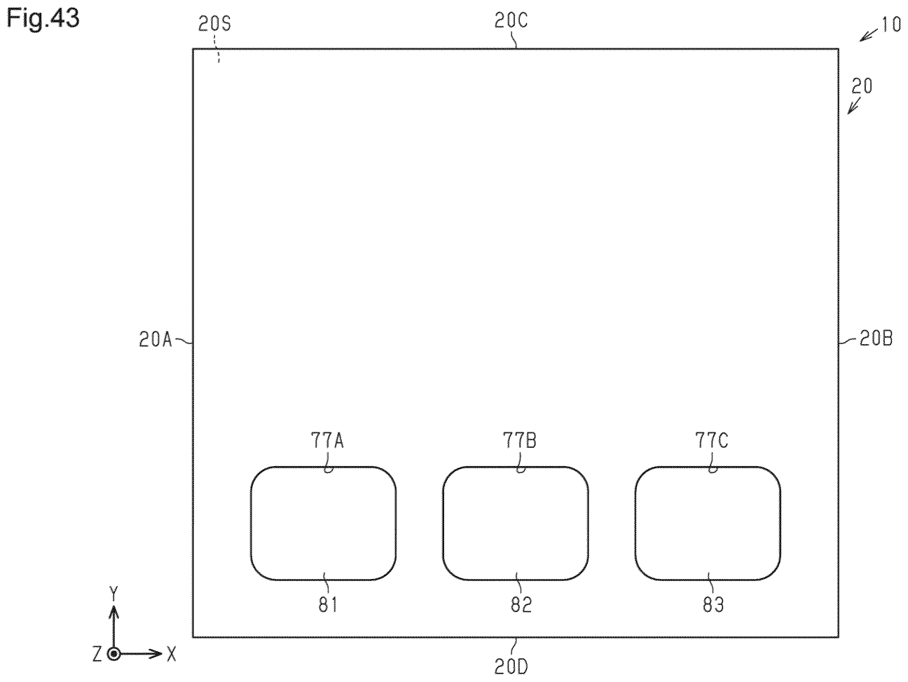

FIG. 40 is a schematic plan view of the semiconductor chip 20 in the TVS diode 10 in accordance with the fourth embodiment. FIG. 41 is a schematic plan view of the first to third connection electrodes 81 to 83 and the wiring 90 of the TVS diode 10. FIG. 42 is a schematic cross-sectional view of the TVS diode 10 taken along line F42-F42 in FIG. 40. FIG. 43 is a schematic plan view of the TVS diode 10.

As shown in FIG. 40, in the TVS diode 10 in accordance with the fourth embodiment, the first pin junction 30, the second pin junction 40, and the third pin junction 50 are arranged next to the diode-paired region 60 in the Y-direction. The first pin junction 30, the second pin junction 40, and the third pin junction 50 are located closer to the fourth side surface 20D than the diode-paired region 60 is in plan view. In other words, the diode-paired region 60 is located closer to the third side surface 20C than the first pin junction 30, the second pin junction 40, and the third pin junction 50 are in plan view.

The first pin junction 30, the second pin junction 40, and the third pin junction 50 are arranged next to one another in the X-direction. More specifically, the first pin junction 30, the second pin junction 40, and the third pin junction 50 are located at the same position in the Y-direction and separated from one another in the X-direction. As shown in FIG. 42, the first pin junction 30, the second pin junction 40, and the third pin junction 50 each have the same cross-sectional structure in the same manner as the first embodiment. The regions partitioning the first terminal low-concentration region 32 and the second terminal low-concentration region 42 form the first partitioning region 34 and the second partitioning region 44. The regions partitioning the second terminal low-concentration region 42 and the third terminal low-concentration region 52 form the second partitioning region 44 and the third partitioning region 54.

As shown in FIG. 40, the diode-paired region 60 is rectangular in plan view. In one example, the diode-paired region 60 is longer in the X-direction (arrangement direction of first pin junction 30, second pin junction 40, and third pin junction 50) and shorter in the Y-direction. The first reverse pin junction 60A, the second reverse pin junction 60B, and the third reverse pin junction 60C are arranged in the diode-paired region 60. Each of the reverse pin junctions 60A, 60B, and 60C is located at a position overlapping the high-concentration region 61 in plan view.

The first reverse pin junction 60A, the second reverse pin junction 60B, and the third reverse pin junction 60C are separated from one another in the X-direction. The first reverse pin junction 60A is located at a position overlapping the first pin junction 30 as viewed in the Y-direction. The second reverse pin junction 60B is located at a position overlapping the second pin junction 40 as viewed in the Y-direction. The third pin junction 50 is located at a position overlapping the third pin junction 50 as viewed in the Y-direction. As shown in FIG. 42, the cross-sectional structure of the reverse pin junctions 60A, 60B, and 60C is similar to that of the first embodiment.

As shown in FIG. 40, the isolation region 65 surrounds each of the first low-concentration region 62A, the second low-concentration region 62B, and the third low-concentration region 62C. In the same manner as the first embodiment, the isolation region 65 includes the first to third isolation regions 65A to 65C and the wiring connection region 65P. The first isolation region 65A is arranged in the isolation region 65 between the first contact region 63A and the first terminal contact region 33 in the Y-direction. The second isolation region 65B is arranged in the isolation region 65 between the second contact region 63B and the second terminal contact region 43 in the Y-direction. The third isolation region 65C is arranged in the isolation region 65 between the third contact region 63C and the third terminal contact region 53 in the Y-direction. The wiring connection region 65P partially surrounds each of the reverse pin junctions 60A, 60B, and 60C in plan view.

As shown by the broken lines in FIG. 40, the edges of the internal region 64 are located inward from the edges of the high-concentration region 61 in plan view. In one example, the internal region 64 is rectangular and slightly smaller than the high-concentration region 61 (diode-paired region 60) in plan view. Thus, the internal region 64 overlaps each of the reverse pin junctions 60A, 60B, and 60C in plan view. More specifically, the internal region 64 overlaps each of the first low-concentration region 62A, the second low-concentration region 62B, and the third low-concentration region 62C in plan view. As shown in FIG. 42, the cross-sectional structure of the pn junction 60E is similar to that of the first embodiment.

As shown in FIG. 41, in the same manner as the first embodiment, the first connection electrode 81 includes the pin connection portion 81A, the wiring portion 81B, and the reverse pin connection portion 81C. In one example, the pin connection portion 81A is rectangular and entirely covers the first terminal contact region 33 in plan view. The wiring portion 81B extends in the Y-direction from the pin connection portion 81A toward the third side surface 20C in plan view. The wiring portion 81B is connected to the pin connection portion 81A so that the central part of the wiring portion 81B in the X-direction is closer than that of the pin connection portion 81A to the second side surface 20B. In one example, the reverse pin connection portion 81C entirely covers the first contact region 63A in plan view.

In the same manner as the first embodiment, the second connection electrode 82 includes the pin connection portion 82A, the wiring portion 82B, and the reverse pin connection portion 82C. The wiring portion 82B extends from the pin connection portion 82A toward the third side surface 20C in the Y-direction. In one example, the central part of the wiring portion 82B in the X-direction is located at the same position as the central part of the pin connection portion 82A. In one example, the reverse pin connection portion 82C entirely covers the second contact region 63B in plan view.

In the same manner as the first embodiment, the third connection electrode 83 includes the pin connection portion 83A, the wiring portion 83B, and the reverse pin connection portion 83C. The wiring portion 83B extends from the pin connection portion 83A toward the third side surface 20C in the Y-direction. In one example, the wiring portion 83B is connected to the pin connection portion 83A so that the central part of the wiring portion 83B in the X-direction is closer than that of the pin connection portion 83A to the first side surface 20A. In one example, the reverse pin connection portion 83C entirely covers the third contact region 63C in plan view.

The wiring 90 has the form of comb teeth in plan view. In the same manner as the first embodiment, the wiring 90 includes the first recess 96A, the second recess 96B, and the third recess 96C. Each of the recesses 96A to 96C is open toward the fourth side surface 20D in the Y-direction. Further, the wiring 90 includes first to fourth teeth 97A to 97D and a connecting portion 97E. The first to fourth teeth 97A to 97D are separated from one another in the X-direction in plan view. The connecting portion 97E is located closer to the third side surface 20C than the first to fourth teeth 97A to 97D are. The connecting portion 97E connects the first to fourth teeth 97A to 97D. The first to fourth teeth 97A to 97D are arranged in this order from the first side surface 20A toward the second side surface 20B. The first to fourth teeth 97A to 97D extends from the connecting portion 97E toward the fourth side surface 20D in the Y-direction. The first recess 96A is formed by the first tooth 97A, the second tooth 97B, and the connecting portion 97E. The second recess 96B is formed by the second tooth 97B, the third tooth 97C, and the connecting portion 97E. The third recess 96C is formed by the third tooth 97C, the fourth tooth 97D, and the connecting portion 97E.

The wiring portion 81B of the first connection electrode 81 is located in the first recess 96A. The wiring portion 82B of the second connection electrode 82 is located in the second recess 96B. The wiring portion 83B of the third connection electrode 83 is located in the third recess 96C. In this manner, the wiring 90 is arranged to partially surround the first connection electrode 81, the second connection electrode 82, and the third connection electrode 83 in plan view.

As shown in FIG. 43, the first to third terminal openings 77A to 77C in the TVS diode 10 in accordance with the fourth embodiment are located at the same position in the Y-direction and separated from one another in the X-direction. The first to third terminal openings 77A to 77C are located closer to the fourth side surface 20D than the third side surface 20C is in plan view. The first terminal opening 77A is located at a position overlapping the first terminal contact region 33 (refer to FIG. 40) in plan view. The second terminal opening 77B is located at a position overlapping the second terminal contact region 43 (refer to FIG. 40) in plan view. The third terminal opening 77C is located at a position overlapping the third terminal contact region 53 in plan view. The TVS diode 10 in accordance with the fourth embodiment has the same advantages as the first embodiment.

### Fifth Embodiment

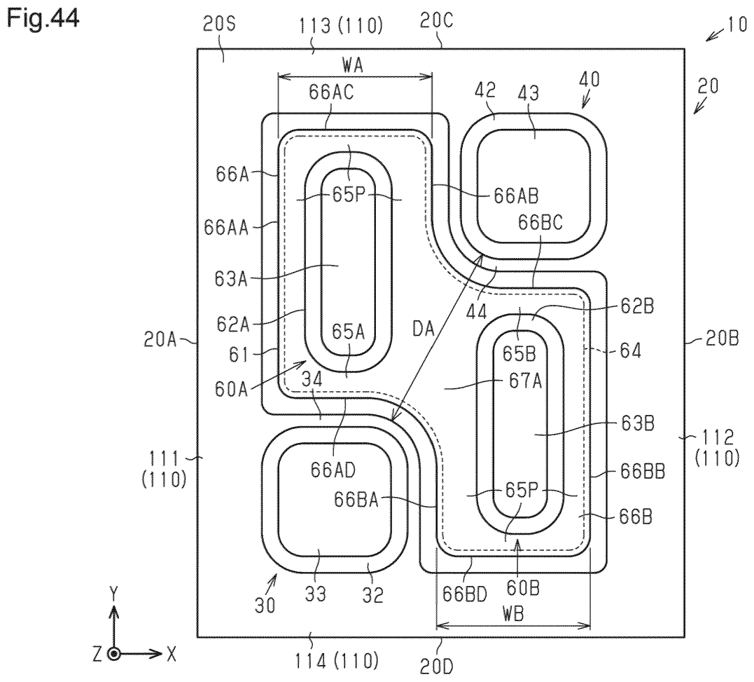

With reference to FIGS. 44 to 46, the TVS diode 10 in accordance with a fifth embodiment will now be described. The TVS diode 10 in accordance with the fifth embodiment differs from the TVS diode 10 in accordance with the first embodiment mainly in the planar structure of the TVS diode 10. The same reference characters are given to those components that are the same as the corresponding components of the first embodiment. Such components will not be described in detail.

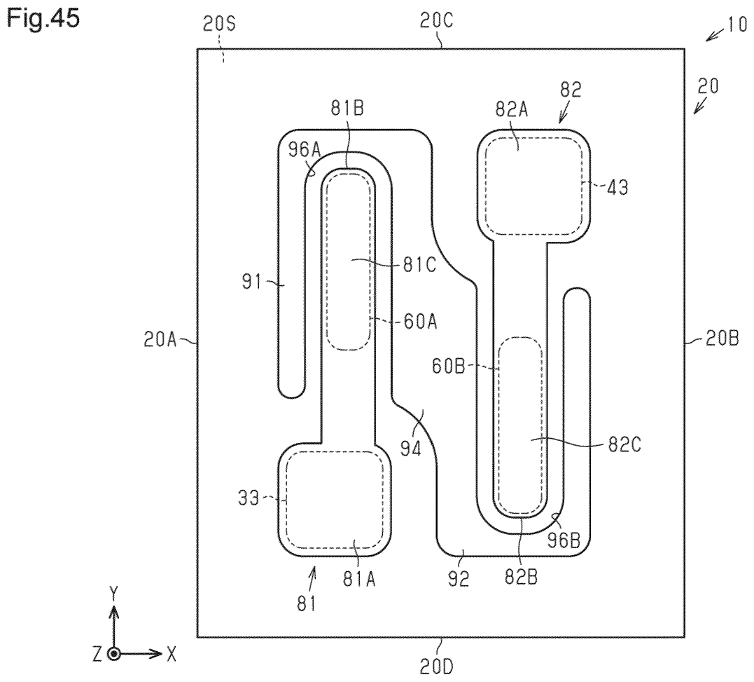

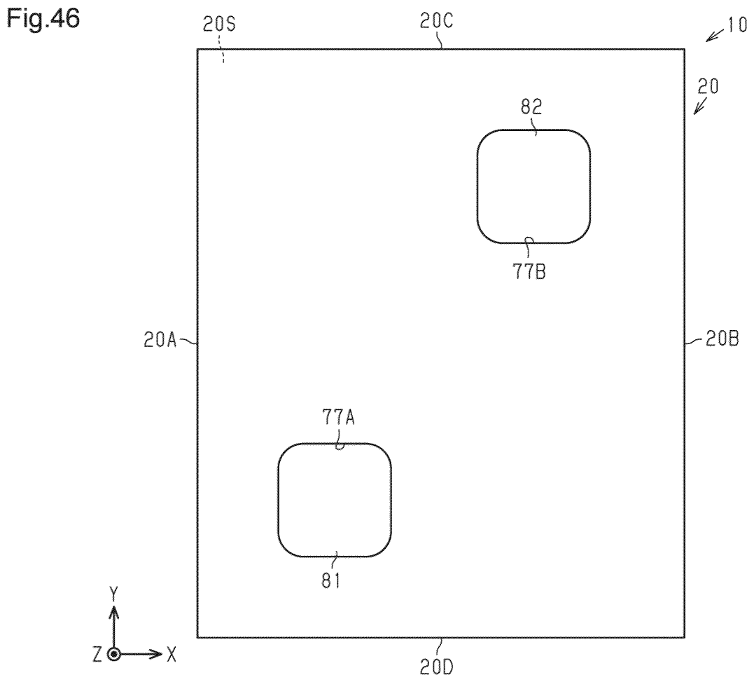

FIG. 44 is a schematic plan view of the semiconductor chip 20 in the TVS diode 10 in accordance with the fifth embodiment. FIG. 45 is a schematic plan view of the first to third connection electrodes 81 to 83 and the wiring 90 of the TVS diode 10. FIG. 46 is a schematic plan view of the TVS diode 10.

As shown in FIG. 44, the TVS diode 10 in accordance with the fifth embodiment includes the first pin junction 30, the second pin junction 40, the first reverse pin junction 60A, the second reverse pin junction 60B, and the pn junction 60E. In the TVS diode 10 in accordance with the fifth embodiment, the third pin junction 50 and the third reverse pin junction 60C (refer to FIG. 2) of the first embodiment are omitted. Although not shown in the drawings, the first pin junction 30 and the second pin junction 40 have the same cross-sectional structures as the first embodiment.

The diode-paired region 60 (high-concentration region 61) includes the first region 66A, the second region 66B, and the first connecting region 67A. In the diode-paired region 60 (high-concentration region 61), the third region 66C and the second connecting region 67B of the first embodiment are omitted. As shown by the broken lines in FIG. 44, the edges of the internal region 64 are located inward from the edges of the high-concentration region 61 in plan view. In one example, the internal region 64 is slightly smaller than the high-concentration region 61 (diode-paired region 60) in plan view. Thus, the internal region 64 overlaps each of the reverse pin junctions 60A and 60B in plan view. More specifically, the internal region 64 overlaps each of the first low-concentration region 62A and the second low-concentration region 62B in plan view. The cross-sectional structure of the reverse pin junctions 60A and 60B is similar to that of the first embodiment.

As shown in FIG. 45, the TVS diode 10 includes the first connection electrode 81, the second connection electrode 82, and the wiring 90. In the TVS diode 10 in accordance with the fifth embodiment, the third connection electrode 83 of the first embodiment is omitted. The planar structure of the wiring 90 differs from the first embodiment. The structure of the first connection electrode 81 and the second connection electrode 82 is the same as the first embodiment.

The wiring 90 includes the first region 91, the second region 92, and the first connecting region 94. Further, the wiring 90 includes the first recess 96A and the second recess 96B. In the wiring 90 of the fifth embodiment, the third region 93, the second connecting region 95, and the third recess 96C of the first embodiment are omitted.

As shown in FIG. 46, the TVS diode 10 in accordance with the fifth embodiment includes the first terminal opening 77A, which exposes part of the first connection electrode 81, and the second terminal opening 77B, which exposes part of the second connection electrode 82. The first terminal opening 77A is located near the corner between the first side surface 20A and the fourth side surface 20D of the semiconductor chip 20 in plan view. The second terminal opening 77B is located near the corner between the second side surface 20B and the fourth side surface 20D of the semiconductor chip 20 in plan view. The first terminal opening 77A is located at a position overlapping the first terminal contact region 33 (refer to FIG. 44) in plan view. The second terminal opening 77B is located at a position overlapping the second terminal contact region 43 (refer to FIG. 44) in plan view. The TVS diode 10 in accordance with the fifth embodiment has the same advantages as the first embodiment.

### Sixth Embodiment

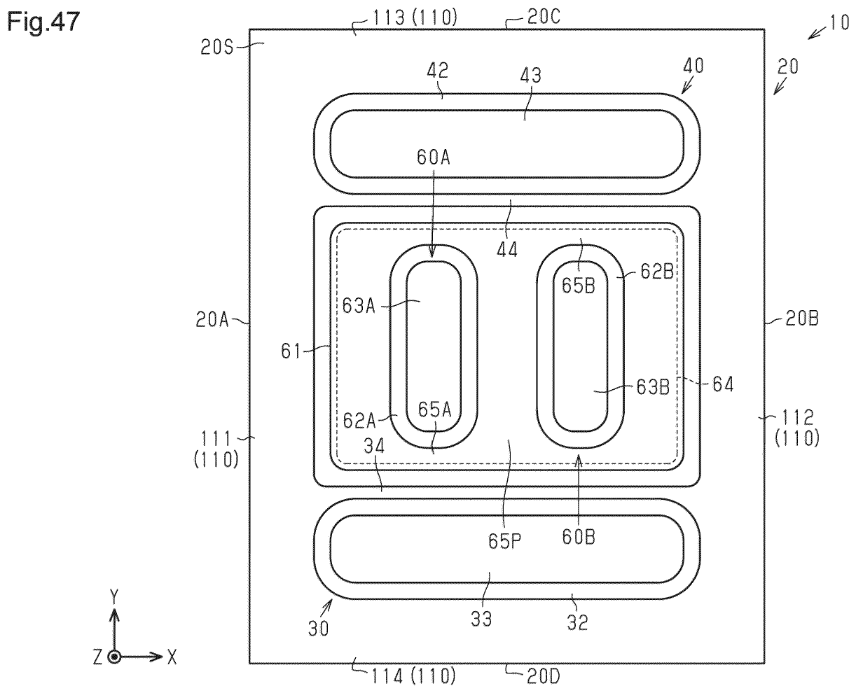

With reference to FIGS. 47 to 49, the TVS diode 10 in accordance with a sixth embodiment will now be described. The TVS diode 10 in accordance with the sixth embodiment differs from the TVS diode 10 in accordance with the first embodiment mainly in the planar structure of the TVS diode 10. The same reference characters are given to those components that are the same as the corresponding components of the first embodiment. Such components will not be described in detail.

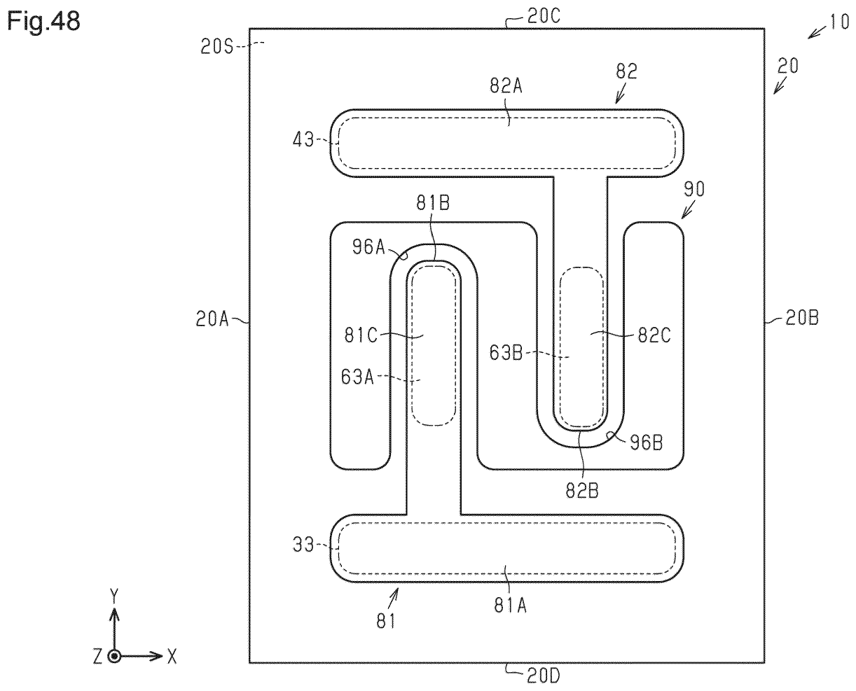

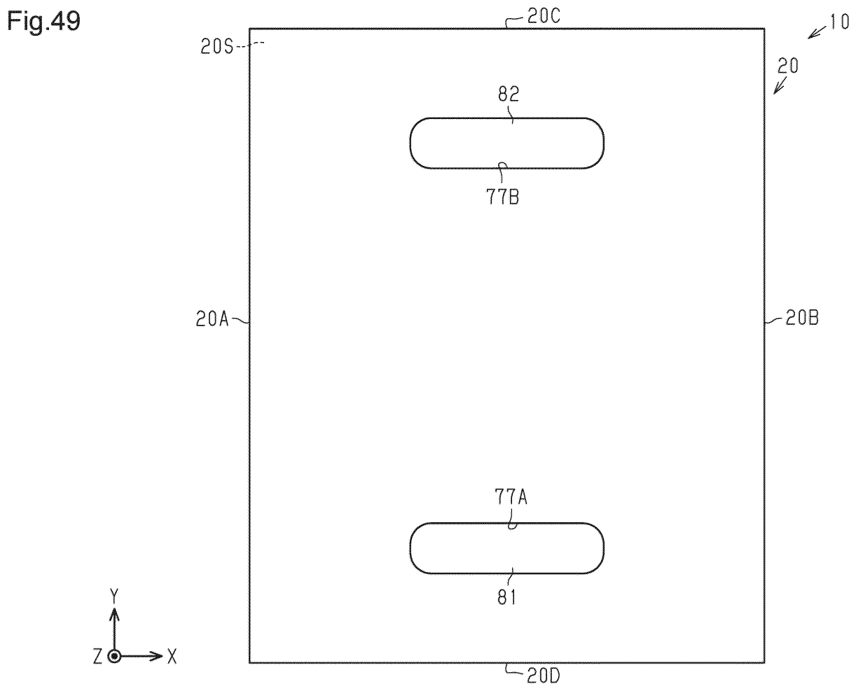

FIG. 47 is a schematic plan view of the semiconductor chip 20 in the TVS diode 10 in accordance with the sixth embodiment. FIG. 48 is a schematic plan view of the first to third connection electrodes 81 to 83 and the wiring 90 of the TVS diode 10. FIG. 49 is a schematic plan view of the TVS diode 10.

As shown in FIG. 47, the TVS diode 10 in accordance with the sixth embodiment includes the first pin junction 30, the second pin junction 40, the first reverse pin junction 60A, the second reverse pin junction 60B, and the pn junction 60E. In the TVS diode 10 in accordance with the sixth embodiment, the third pin junction 50 and the third reverse pin junction 60C (refer to FIG. 2) of the first embodiment are omitted.

The first pin junction 30 and the second pin junction 40 are separated from each other in the Y-direction. The diode-paired region 60 is arranged between the first pin junction 30 and the second pin junction 40 in the Y-direction and separated from the first pin junction 30 and the second pin junction 40.

The first pin junction 30 and the second pin junction 40 are rectangular and longer in the X-direction and shorter in the Y-direction (arrangement direction of first pin junction 30 and second pin junction 40). Thus, the first terminal low-concentration region 32 and the second terminal low-concentration region 42 are both rectangular in plan view, and longer in the X-direction and shorter in the Y-direction. The first terminal contact region 33 and the second terminal contact region 43 are both rectangular in plan view, and longer in the X-direction and shorter in the Y-direction. Each of the terminal low-concentration regions 32 and 42 and the terminal contact regions 33 and 43 has four curved corners. The first pin junction 30 and the second pin junction 40 have the same cross-sectional structure as the first embodiment.

The diode-paired region 60 (high-concentration region 61) is rectangular in plan view. In one example, the diode-paired region 60 (high-concentration region 61) is longer in the X-direction and shorter in the Y-direction in plan view. The first reverse pin junction 60A and the second reverse pin junction 60B are arranged in the diode-paired region 60. In one example, the first reverse pin junction 60A and the second reverse pin junction 60B are located at the same position in the Y-direction and separated from each other in the X-direction. The first low-concentration region 62A and the second low-concentration region 62B are located at the same position in the Y-direction and separated from each other in the X-direction. The first contact region 63A and the second contact region 63B are located at the same position in the Y-direction and separated from each other in the X-direction. Each of the low-concentration regions 62A and 62B is oblong and shorter in the X-direction (arrangement direction of first low-concentration region 62A and second low-concentration region 62B) and longer in the Y-direction. Each of the contact regions 63A and 63B is oblong and shorter in the X-direction (arrangement direction of first contact region 63A and second contact region 63B) and longer in the Y-direction.

As shown by the broken lines in FIG. 47, the edges of the internal region 64 are located inward from the edges of the high-concentration region 61 in plan view. In one example, the internal region 64 is rectangular and slightly smaller than the high-concentration region 61 (diode-paired region 60) in plan view. Thus, the internal region 64 overlaps each of the reverse pin junctions 60A and 60B in plan view. More specifically, the internal region 64 overlaps each of the first low-concentration region 62A and the second low-concentration region 62B in plan view. The cross-sectional structure of the pn junction 60E is the same as the first embodiment.

As shown in FIG. 48, the TVS diode 10 includes the first connection electrode 81, the second connection electrode 82, and the wiring 90. In the TVS diode 10 in accordance with the sixth embodiment, the third connection electrode 83 of the first embodiment is omitted. The planar structure of the wiring 90 differs from the first embodiment.

The first connection electrode 81 includes the pin connection portion 81A, the wiring portion 81B, and the reverse pin connection portion 81C. The wiring portion 81B and the reverse pin connection portion 81C are similar to the first connection electrode 81 of the first embodiment. The pin connection portion 81A is rectangular in plan view, and longer in the X-direction and shorter in the Y-direction. The pin connection portion 81A entirely covers the first terminal contact region 33 in plan view.

The second connection electrode 82 includes the pin connection portion 82A, the wiring portion 82B, and the reverse pin connection portion 82C. The wiring portion 82B and the reverse pin connection portion 82C are similar to the second connection electrode 82 of the first embodiment. The pin connection portion 82A is rectangular in plan view, and longer in the X-direction and shorter in the Y-direction. The pin connection portion 82A entirely covers the second terminal contact region 43 in plan view.

The wiring 90 is arranged partially surrounding both the first connection electrode 81 and the second connection electrode 82 in plan view. The wiring 90 includes the first recess 96A and the second recess 96B. The first recess 96A surrounds the first connection electrode 81 in plan view. The second recess 96B surrounds the second connection electrode 82 in plan view.

As shown in FIG. 49, the first terminal opening 77A and the second terminal opening 77B in the TVS diode 10 in accordance with the sixth embodiment are located at the same position in the X-direction and separated from each other in the Y-direction. The first terminal opening 77A is arranged at the one of the two Y-direction ends of the semiconductor chip 20 located toward the fourth side surface 20D in plan view. The second terminal opening 77B is arranged at the one of the two Y-direction ends of the semiconductor chip 20 located toward the third side surface 20C in plan view. Each of the first terminal opening 77A and the second terminal opening 77B is oblong in plan view, and longer in the X-direction and shorter in the Y-direction. The first terminal opening 77A is located at a position overlapping the first terminal contact region 33 (refer to FIG. 47). The second terminal opening 77B is located at a position overlapping the second terminal contact region 43 (refer to FIG. 47). The TVS diode 10 in accordance with the sixth embodiment has the same advantages as the first embodiment.

### Seventh Embodiment

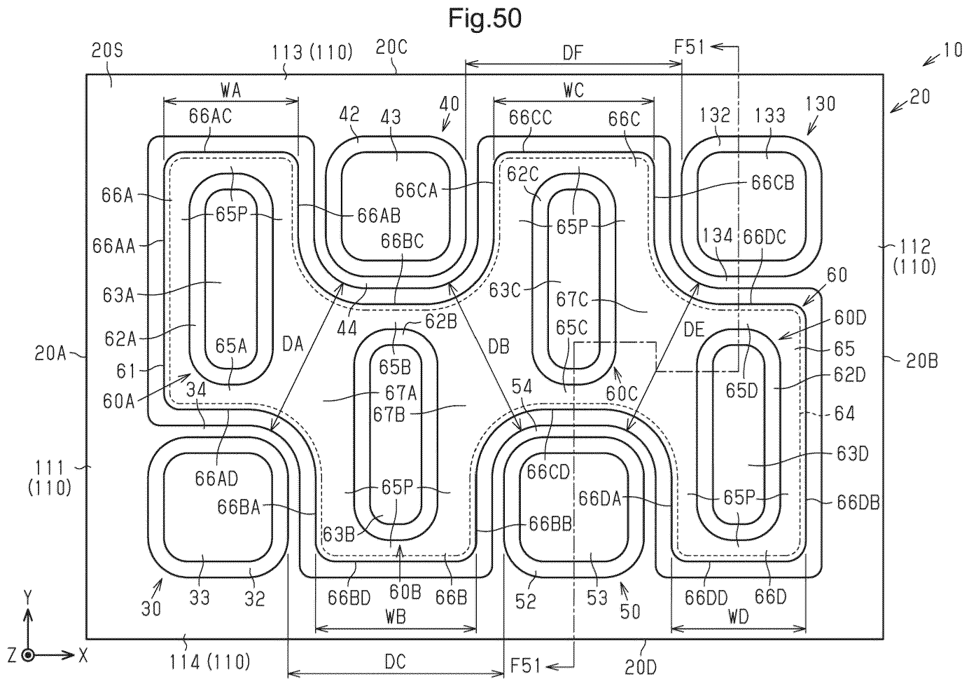

With reference to FIGS. 50 to 53, the TVS diode 10 in accordance with a seventh embodiment will now be described. The TVS diode 10 in accordance with the seventh embodiment differs from the TVS diode 10 in accordance with the first embodiment mainly in the planar structure of the TVS diode 10. The same reference characters are given to those components that are the same as the corresponding components of the first embodiment. Such components will not be described in detail.

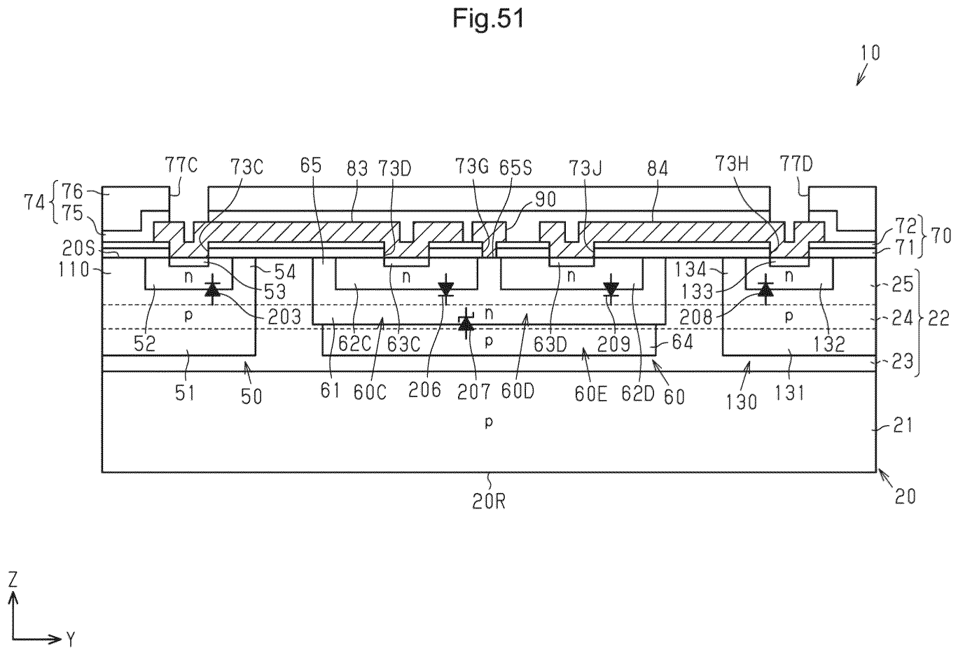

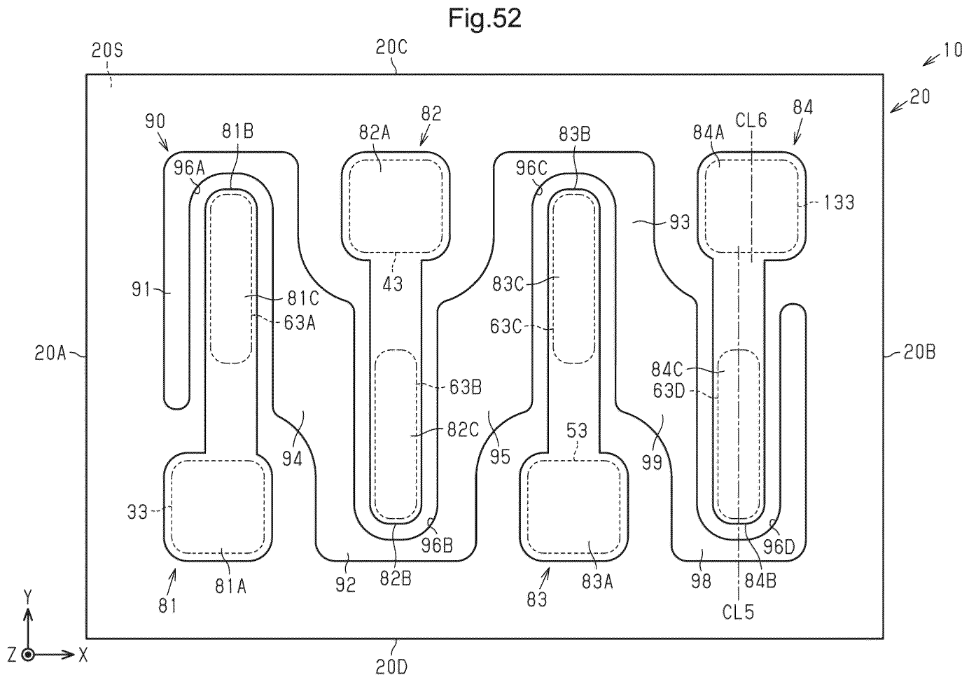

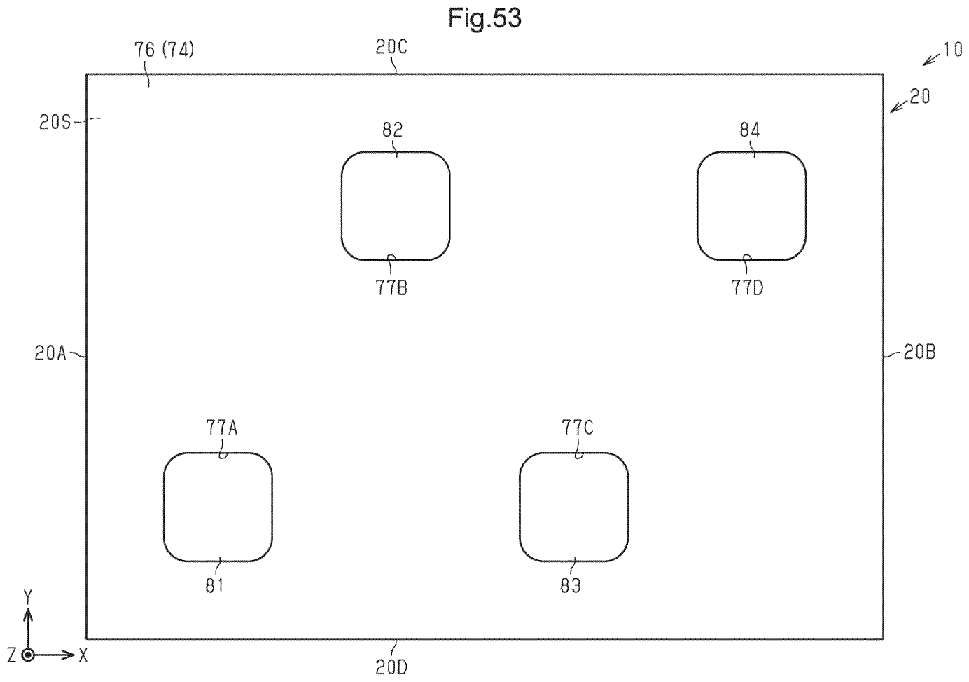

FIG. 50 is a schematic plan view of the semiconductor chip 20 in the TVS diode 10 in accordance with the seventh embodiment. FIG. 51 is a schematic cross-sectional view of the TVS diode 10 taken along line F51-F51 in FIG. 50. FIG. 52 is a schematic plan view of the first to third connection electrodes 81 to 83 and the wiring 90 of the TVS diode 10. FIG. 53 is a schematic plan view of the TVS diode 10.

As shown in FIG. 50, the TVS diode 10 in accordance with the seventh embodiment is formed by adding a fourth pin junction 130 and a fourth reverse pin junction 60D to the TVS diode 10 in accordance with the first embodiment.

The fourth pin junction 130 is located toward the second side surface 20B and the third side surface 20C from the third pin junction 50 in plan view. The fourth pin junction 130 and the second pin junction 40 are located at the same position in the Y-direction. The third region 66C of the diode-paired region 60 is located between the second pin junction 40 and the fourth pin junction 130 in plan view. Thus, the second pin junction 40 and the fourth pin junction 130 sandwich the diode-paired region 60 in plan view.

As shown in FIG. 51, the fourth pin junction 130 includes a fourth terminal high-concentration region 131, a fourth terminal low-concentration region 132, a fourth terminal contact region 133, and a fourth partitioning region 134. The fourth terminal high-concentration region 131, the fourth terminal low-concentration region 132, and the fourth terminal contact region 133 form the fourth pin junction 130. As shown in FIGS. 50 and 51, the fourth pin junction 130 and the third pin junction 50 have the same structure. Further, in the seventh embodiment, the first pin junction 30, the second pin junction 40, and the third pin junction 50 each have the same structure as the first embodiment. Thus, the first pin junction 30, the second pin junction 40, the third pin junction 50, and the fourth pin junction 130 are identical in structure. For this reason, the fourth terminal high-concentration region 131, the fourth terminal low-concentration region 132, the fourth terminal contact region 133, and the fourth partitioning region 134 will not be described in detail. In the fourth pin junction 130, the p-type fourth terminal high-concentration region 131 forms a P-layer of the pin diode, the n-type fourth terminal low-concentration region 132 forms an I-layer of the pin diode, and the n-type fourth terminal contact region 133 forms an N-layer of the pin diode. That is, the fourth terminal high-concentration region 131, the fourth terminal low-concentration region 132, and the fourth terminal contact region 133 form a pin junction in the Z-direction. Thus, the fourth terminal high-concentration region 131, the fourth terminal low-concentration region 132, and the fourth terminal contact region 133 form a pin diode (diode 208) for the first polarity direction in the fourth pin junction 130.

In the example shown in FIG. 51, the shortest distance DE between the fourth partitioning region 134 of the fourth pin junction 130 and the third partitioning region 54 of the third pin junction 50 is equal to the shortest distance DB between the second partitioning region 44 of the second pin junction 40 and the third partitioning region 54. Further, the shortest distance DE is equal to the shortest distance DA between the first partitioning region 34 of the first pin junction 30 and the second partitioning region 44. The shortest distance DF between the fourth partitioning region 134 and the second partitioning region 44 is equal to the shortest distance DC between the first partitioning region 34 and the third partitioning region 54. The shortest distances DE and DF may each be varied. In one example, the shortest distance DE may differ from at least one of the shortest distance DA and the shortest distance DB. The shortest distance DF may differ from the shortest distance DC.

As shown in FIG. 50, the diode-paired region 60 (high-concentration region 61) includes a fourth region 66D and a third connecting region 67C. The fourth region 66D is shifted from the third region 66C in the Y-direction. More specifically, the fourth region 66D is located closer to the second side surface 20B and the fourth side surface 20D than the third region 66C is. The fourth region 66D is located at the same position as the second region 66B in the Y-direction.

The fourth region 66D includes first to fourth sides 66DA to 66DD. The first side 66DA of the fourth region 66D is located toward the first side surface 20A and extends in the Y-direction in plan view. The second side 66DB of the fourth region 66D is located toward the second side surface 20B and extends in the Y-direction in plan view. The third side 66DC of the fourth region 66D is located toward the third side surface 20C and extends in the X-direction in plan view. The fourth side 66DD of the fourth region 66D is located toward the fourth side surface 20D and extends in the X-direction in plan view. The first side 66DA and the fourth side 66DD are located closer to the fourth side surface 20D than the third region 66C is in the Y-direction.

The fourth region 66D includes a corner between the first side 66DA and the fourth side 66DD, a corner between the second side 66DB and the fourth side 66DD, and a corner between the second side 66DB and the third side 66DC. Each corner is curved in plan view.

The third connecting region 67C is located between the third region 66C and the fourth region 66D. The third connecting region 67C connects the third region 66C and the fourth region 66D. The third region 66C and the third connecting region 67C are located between the third pin junction 50 and the fourth pin junction 130 in a direction intersecting both the X-direction and the Y-direction in plan view.

The fourth region 66D and the third connecting region 67C results in the third region 66C being shaped differently in plan view from the first embodiment. More specifically, the corner between the second side 66CB and the fourth side 66CD are omitted from the third region 66C.

In the example shown in FIG. 50, the width WD (dimension in X-direction) of the fourth region 66D is equal to the width WA of the first region 66A. The width WB of the second region 66B is greater than the width WD of the fourth region 66D. The width WC of the third region 66C is greater than the width WD of the fourth region 66D. The width WB of the second region 66B is equal to the width WC of the third region 66C.

Each of the width WA of the first region 66A, the width WB of the second region 66B, the width WC of the third region 66C, and the width WD of the fourth region 66D may be varied. In one example, the width WA of the first region 66A may be equal to the width WC of the third region 66C. In one example, the width WD of the fourth region 66D may be equal to the width WB of the second region 66B. The width WD of the fourth region 66D may differ from the width WA of the first region 66A.

The fourth reverse pin junction 60D is arranged in the fourth region 66D. The fourth reverse pin junction 60D is arranged next to the fourth pin junction 130 in the Y-direction. The fourth reverse pin junction 60D is separated from the third reverse pin junction 60C in the Y-direction. Part of the fourth reverse pin junction 60D overlaps the third reverse pin junction 60C as viewed in the X-direction.

As shown in FIG. 51, the fourth reverse pin junction 60D includes a fourth low-concentration region 62D and a fourth contact region 63D. The fourth low-concentration region 62D and the fourth contact region 63D respectively have the same structure as, for example, the third low-concentration region 62C and the third contact region 63C. In the fourth reverse pin junction 60D, the p-type fourth contact region 63D forms a P-layer of the pin diode, the n-type fourth low-concentration region 62D forms an I-layer of the pin diode, and the n-type high-concentration region 61 forms an N-layer of the pin diode. That is, the fourth contact region 63D, the fourth low-concentration region 62D, and the high-concentration region 61 form a pin junction in the Z-direction. The high-concentration region 61, the fourth low-concentration region 62D, and the fourth contact region 63D form a pin diode (diode 209) for the second polarity direction in the fourth reverse pin junction 60D.

As shown by the broken lines in FIG. 50, the edges of the internal region 64 are located inward from the edges of the high-concentration region 61 in plan view. In one example, the internal region 64 is rectangular and slightly smaller than the high-concentration region 61 (diode-paired region 60) in plan view. Thus, the internal region 64 overlaps each of the reverse pin junctions 60A, 60B, 60C, and 60D in plan view. More specifically, the internal region 64 overlaps each of the first low-concentration region 62A, the second low-concentration region 62B, the third low-concentration region 62C, and the fourth low-concentration region 62D in plan view. The cross-sectional structure of the pn junction 60E is the same as the first embodiment.

As shown in FIG. 52, the TVS diode 10 in accordance with the seventh embodiment is formed by adding a fourth connection electrode 84 to the TVS diode 10 in accordance with the first embodiment.

The fourth connection electrode 84 is located closer to the second side surface 20B than the central part of the semiconductor chip 20 is in the X-direction in plan view. The fourth connection electrode 84 extends in the Y-direction. The fourth connection electrode 84 includes a pin connection portion 84A and a wiring portion 84B, which extends from the pin connection portion 84A toward the fourth side surface 20D in the Y-direction. In one example, the pin connection portion 84A is integrated with the wiring portion 84B.

The pin connection portion 84A is located at a position overlapping the fourth pin junction 130 (refer to FIG. 50) in plan view. The pin connection portion 84A is quadrilateral in plan view. The pin connection portion 84A is located in the fourth terminal low-concentration region 132 of the fourth pin junction 130 in plan view. The pin connection portion 84A is slightly larger than the fourth terminal contact region 133 of the fourth pin junction 130 in plan view.

The wiring portion 84B has the form of a strip having a width in the X-direction in plan view. The width of the wiring portion 84B is less than the X-direction dimension of the pin connection portion 84A. The wiring portion 84B is shifted in the X-direction from the pin connection portion 84A. More specifically, a hypothetical line CL5 extending in the Y-direction through the width center of the wiring portion 84B is located closer to the first side surface 20A than a hypothetical line CL6, which extends in the Y-direction through the X-direction center of the pin connection portion 84A, is.

The wiring portion 84B covers the fourth contact region 63D of the fourth reverse pin junction 60D in plan view. In one example, the wiring portion 84B entirely covers the fourth contact region 63D in plan view. The width of the wiring portion 84B is greater than the width of the fourth contact region 63D. The width of the wiring portion 84B is less than the width of the fourth low-concentration region 62D. The wiring portion 84B has a distal end that is curved in plan view.

A reverse pin connection portion 84C is arranged on the wiring portion 84B at a position overlapping the fourth contact region 63D. The reverse pin connection portion 84C is connected to the fourth contact region 63D. In one example, the fourth connection electrode 84 has the same structure as the first connection electrode 81.

As shown in FIG. 51, the fourth connection electrode 84 electrically connects the fourth terminal contact region 133 of the fourth pin junction 130 and the fourth contact region 63D of the fourth reverse pin junction 60D. The fourth connection electrode 84 contacts the fourth terminal contact region 133 through a seventh opening 73H in the insulation layer 70. The fourth connection electrode 84 contacts the fourth contact region 63D through an eighth opening 73J in the insulation layer 70.

As shown in FIG. 52, the fourth connection electrode 84 results in the third connection electrode 83 being shaped differently from the first embodiment. In the seventh embodiment, the third connection electrode 83 has the same structure as the second connection electrode 82. The central part of the wiring portion 83B of the third connection electrode 83 in the X-direction is located at the same position as the central part of the pin connection portion 83A in the X-direction.

The wiring 90 includes a fourth region 98, a third connecting region 99, and a fourth recess 96D.

The fourth region 98 is arranged overlapping the fourth region 66D of the diode-paired region 60 (refer to FIG. 50) in plan view. The edges of the fourth region 98 corresponding to the first side 66DA, the second side 66DB, and the fourth side 66DD of the fourth region 66D (refer to FIG. 50) are arranged overlapping the first side 66DA, the second side 66DB, and the fourth side 66DD in plan view.

The fourth recess 96D is arranged in a manner avoiding the fourth connection electrode 84 in plan view. The fourth recess 96D is open toward the third side surface 20C. Thus, the fourth region 98 partially surrounds the fourth connection electrode 84 in plan view. Further, the fourth recess 96D is arranged in a manner avoiding the fourth low-concentration region 62D of the fourth region 66D (refer to FIG. 50) of the diode-paired region 60 (high-concentration region 61) in plan view. Thus, the fourth region 98 surrounds the fourth low-concentration region 62D in plan view.

The arrangement of the fourth recess 96D results in the fourth region 98 being partially connected to the isolation region 65 in the fourth region 66D. More specifically, as shown in FIG. 50, the isolation region 65 in the fourth region 66D includes the wiring connection region 65P, which is connected to the wiring 90, and a fourth isolation region 65D, which overlaps the fourth connection electrode 84 in plan view. The fourth isolation region 65D is arranged at the one of the two Y-direction ends of the fourth region 66D located toward the fourth pin junction 130. The fourth isolation region 65D is located in the fourth region 66D between the fourth low-concentration region 62D and the third side 66DC in plan view. The wiring connection region 65P partially surrounds the fourth low-concentration region 62D in plan view. That is, the wiring connection region 65P partially surrounds the fourth reverse pin junction 60D in plan view. Thus, the fourth region 98 (refer to FIG. 51), which is connected to the wiring connection region 65P, partially surrounds the fourth reverse pin junction 60D in plan view.

As shown in FIG. 52, the third connecting region 99 is arranged overlapping the third connecting region 67C of the diode-paired region 60 (refer to FIG. 51) in plan view. The third connecting region 99 has the same size and shape as the first connecting region 67A. The third connecting region 99 is connected to the entire third connecting region 67C. In other words, the third connecting region 67C is formed by the wiring connection region 65P.

As shown in FIG. 53, the TVS diode 10 in accordance with the seventh embodiment is formed by adding a fourth terminal opening 77D to the TVS diode 10 in accordance with the first embodiment. The first to third terminal openings 77A to 77C are laid out in the same manner as the first embodiment.

The fourth terminal opening 77D is separated, in plan view, from the third terminal 103 in both the X-direction and the Y-direction. More specifically, the fourth terminal opening 77D is located closer to the second side surface 20B and the third side surface 20C than the third terminal opening 77C is in plan view. In one example, the fourth terminal opening 77D and the second terminal opening 77B are located at the same position in the Y-direction.

As shown in FIG. 51, in the same manner as the first to third terminal openings 77A to 77C, the fourth terminal opening 77D exposes the pin connection portion 84A of the fourth connection electrode 84. The fourth terminal opening 77D is located at a position overlapping the fourth terminal contact region 133 in plan view. The TVS diode 10 in accordance with the seventh embodiment has the same advantages as the first embodiment.

### Eighth Embodiment

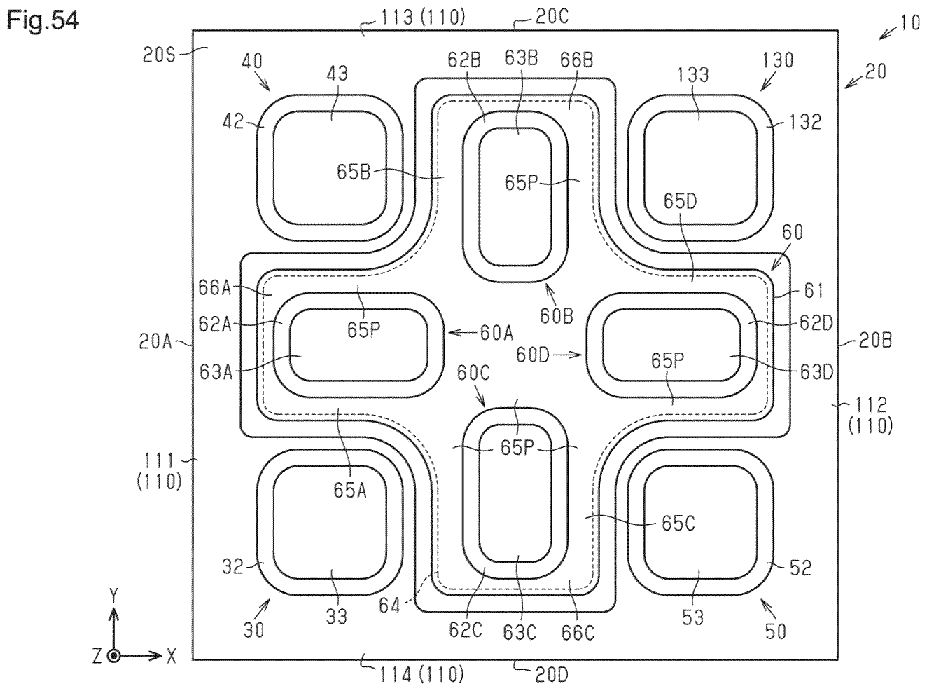

With reference to FIGS. 54 to 56, the TVS diode 10 in accordance with an eighth embodiment will now be described. The TVS diode 10 in accordance with the eighth embodiment differs from the TVS diode 10 in accordance with the seventh embodiment mainly in the planar structure of the TVS diode 10. The same reference characters are given to those components that are the same as the corresponding components of the seventh embodiment. Such components will not be described in detail.

As shown in FIG. 54, in the TVS diode 10 in accordance with the eighth embodiment, the first pin junction 30, the second pin junction 40, the third pin junction 50, and the fourth pin junction 130 are arranged in the four corners of the first surface 20S of the semiconductor chip 20 in plan view. The first pin junction 30 is located near the corner between the first side surface 20A and the fourth side surface 20D in the first surface 20S of the semiconductor chip 20 in plan view. The second pin junction 40 is located near the corner between the first side surface 20A and the third side surface 20C in the first surface 20S of the semiconductor chip 20. The third pin junction 50 is located near the corner between the second side surface 20B and the fourth side surface 20D in the first surface 20S of the semiconductor chip 20. The fourth pin junction 130 is located near the corner between the second side surface 20B and the third side surface 20C in the first surface 20S of the semiconductor chip 20. The first pin junction 30, the second pin junction 40, the third pin junction 50, and the fourth pin junction 130 each have the same cross-sectional structure as the seventh embodiment.

The diode-paired region 60 (high-concentration region 61) is cross-shaped in plan view. In the same manner as the seventh embodiment, the diode-paired region 60 includes the first to fourth regions 66A to 66D and the first to fourth reverse pin junctions 60A to 60D.

The first reverse pin junction 60A is arranged in the first region 66A. The first region 66A includes a part located between the first pin junction 30 and the second pin junction 40 in the Y-direction. In other words, the first pin junction 30 and the second pin junction 40 sandwich the first region 66A. Further, the first reverse pin junction 60A includes a part located between the first pin junction 30 and the second pin junction 40 in the Y-direction.

The first low-concentration region 62A and the first contact region 63A of the first reverse pin junction 60A are both rectangular in plan view, and longer in the X-direction and shorter in the Y-direction. In one example, the first low-concentration region 62A and the first contact region 63A both extend outward from the first pin junction 30 and the second pin junction 40 as viewed in the Y-direction.

The second reverse pin junction 60B is arranged in the second region 66B. The second region 66B includes a part located between the second pin junction 40 and the fourth pin junction 130 in the X-direction. In other words, the second pin junction 40 and the fourth pin junction 130 sandwich the second region 66B. Further, the second reverse pin junction 60B includes a part located between the second pin junction 40 and the fourth pin junction 130 in the X-direction.

The second low-concentration region 62B and the second contact region 63B of the second reverse pin junction 60B are both rectangular in plan view, and shorter in the X-direction and longer in the Y-direction. In one example, the second low-concentration region 62B and the second contact region 63B both extend outward from the second pin junction 40 and the fourth pin junction 130 as viewed in the X-direction.

The third reverse pin junction 60C is arranged in the third region 66C. The third region 66C includes a part located between the first pin junction 30 and the third pin junction 50 in the X-direction. In other words, the first pin junction 30 and the third pin junction 50 sandwich the third region 66C. Further, the third reverse pin junction 60C includes a part located between the first pin junction 30 and the third pin junction 50 in the X-direction.

The third low-concentration region 62C and the third contact region 63C of the third reverse pin junction 60C are both rectangular in plan view, and shorter in the X-direction and longer in the Y-direction. In one example, the third low-concentration region 62C and the third contact region 63C both extend outward from the first pin junction 30 and the third pin junction 50 as viewed in the X-direction.

The fourth reverse pin junction 60D is arranged in the fourth region 66D. The fourth region 66D includes a part located between the third pin junction 50 and the fourth pin junction 130 in the Y-direction. In other words, the third pin junction 50 and the fourth pin junction 130 sandwich the fourth region 66D. Further, the fourth reverse pin junction 60D includes a part located between the third pin junction 50 and the fourth pin junction 130 in the Y-direction.

The fourth low-concentration region 62D and the fourth contact region 63D of the fourth reverse pin junction 60D are both rectangular in plan view, and longer in the X-direction and shorter in the Y-direction. In one example, the fourth low-concentration region 62D and the fourth contact region 63D both extend outward from the third pin junction 50 and the fourth pin junction 130 as viewed in the Y-direction.

In the diode-paired region 60 (high-concentration region 61), the part connecting the first region 66A and the second region 66B, the part connecting the first region 66A and the third region 66C, the part connecting the second region 66B and the fourth region 66D, and the part connecting the third region 66C and the fourth region 66D are each curved in plan view. Further, the first to fourth regions 66A to 66D each have curved corners in plan view. The part connecting the first region 66A and the second region 66B, the part connecting the first region 66A and the third region 66C, the part connecting the second region 66B and the fourth region 66D, and the part connecting the third region 66C and the fourth region 66D each have a greater radius of curvature than the corners of the first to fourth regions 66A to 66D.

As shown by the broken lines in FIG. 54, the edges of the internal region 64 are located inward from the edges of the high-concentration region 61 in plan view. In one example, the internal region 64 is rectangular and slightly smaller than the high-concentration region 61 (diode-paired region 60) in plan view. Thus, the internal region 64 overlaps each of the reverse pin junctions 60A, 60B, 60C, and 60D in plan view. More specifically, the internal region 64 overlaps each of the first low-concentration region 62A, the second low-concentration region 62B, the third low-concentration region 62C, and the fourth low-concentration region 62D in plan view. The cross-sectional structure of the pn junction 60E (refer to FIG. 2) is the same as the first embodiment.

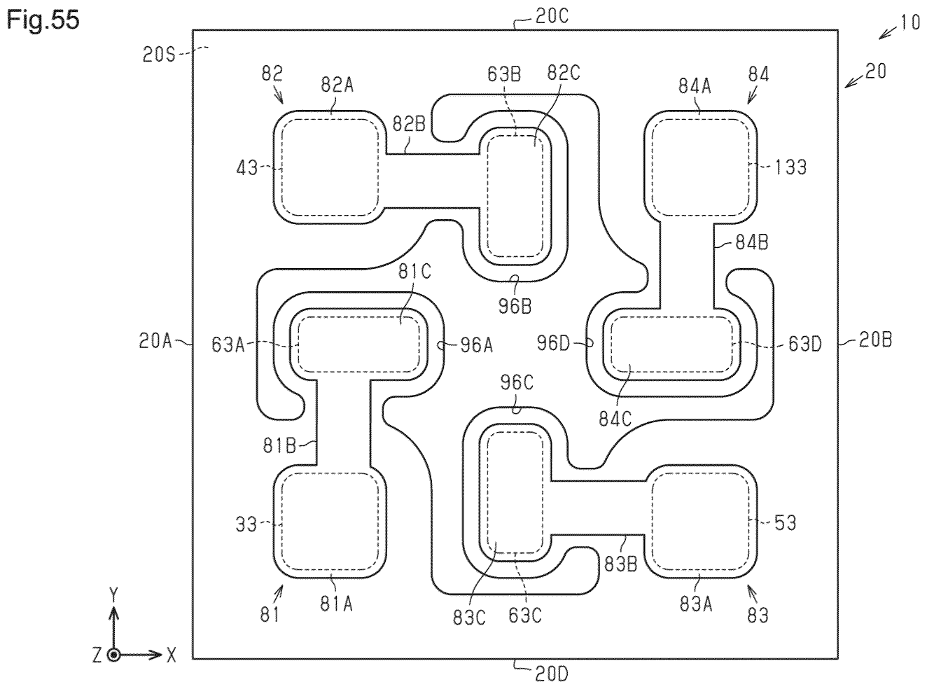

As shown in FIG. 55, the first to fourth connection electrodes 81 to 84 of the eighth embodiment are shaped differently from the first to fourth connection electrodes 81 to 84 of the seventh embodiment.

The first connection electrode 81 includes the pin connection portion 81A, the wiring portion 81B, and the reverse pin connection portion 81C. The pin connection portion 81A entirely covers the first terminal contact region 33 of the first pin junction 30 in plan view. The pin connection portion 81A is in contact with the first terminal contact region 33. The pin connection portion 81A is rectangular in plan view. The wiring portion 81B extends from the pin connection portion 81A toward the third side surface 20C in the Y-direction. The reverse pin connection portion 81C entirely covers the first contact region 63A of the first reverse pin junction 60A in plan view. The reverse pin connection portion 81C is in contact with the first contact region 63A. The reverse pin connection portion 81C is rectangular in plan view, and longer in the X-direction and shorter in the Y-direction. In the eighth embodiment, the first to fourth connection electrodes 81 to 84 are shaped identically in plan view. Thus, the second to fourth connection electrodes 82 to 84 will not be described in detail.

The wiring 90 of the eighth embodiment is shaped differently from the wiring 90 of the seventh embodiment. The wiring 90 partially surrounds each of the first to fourth connection electrodes 81 to 84. More specifically, in the same manner as the seventh embodiment, the wiring 90 includes the first to fourth recesses 96A to 96D. The first recess 96A of the wiring 90 is arranged in a manner avoiding the reverse pin connection portion 81C of the first connection electrode 81 in plan view. The first recess 96A is open toward the pin connection portion 81A to allow for passage of the wiring portion 81B. Thus, the wiring 90 partially surrounds the reverse pin connection portion 81C and the wiring portion 81B of the first connection electrode 81. The second recess 96B is arranged in a manner avoiding the reverse pin connection portion 82C of the second connection electrode 82 in plan view. The second recess 96B is open toward the pin connection portion 82A to allow for passage of the wiring portion 82B. Thus, the wiring 90 partially surrounds the reverse pin connection portion 82C and the wiring portion 82B of the second connection electrode 82. The third recess 96C is arranged in a manner avoiding the reverse pin connection portion 83C of the third connection electrode 83 in plan view. The third recess 96C is open toward the pin connection portion 83A to allow for passage of the wiring portion 83B. Thus, the wiring 90 partially surrounds the reverse pin connection portion 83C and the wiring portion 83B of the third connection electrode 83. The fourth recess 96D is arranged in a manner avoiding the reverse pin connection portion 84C of the fourth connection electrode 84 in plan view. The fourth recess 96D is open toward the pin connection portion 84A to allow for passage of the wiring portion 84B. Thus, the wiring 90 partially surrounds the reverse pin connection portion 84C and the wiring portion 84B of the fourth connection electrode 84.

Further, the first recess 96A surrounds the first low-concentration region 62A (refer to FIG. 54) of the diode-paired region 60 (high-concentration region 61) in plan view. The second recess 96B surrounds the second low-concentration region 62B (refer to FIG. 54) in plan view. The third recess 96C surrounds the third low-concentration region 62C (refer to FIG. 54) in plan view. The fourth recess 96D surrounds the fourth low-concentration region 62D (refer to FIG. 54) in plan view.

The wiring 90 is partially connected to the isolation region 65 of the diode-paired region 60 (high-concentration region 61). More specifically, as shown in FIG. 54, the isolation region 65 includes the first to fourth isolation regions 65A to 65D, which are not connected to the wiring 90, and the wiring connection region 65P, which is connected to the wiring 90. The first isolation region 65A is the part of the isolation region 65 corresponding to the first region 66A and covered by the wiring portion 81B (refer to FIG. 55). The second isolation region 65B is the part of the isolation region 65 corresponding to the second region 66B and covered by the wiring portion 82B (refer to FIG. 55). The third isolation region 65C is the part of the isolation region 65 corresponding to the third region 66C and covered by the wiring portion 83B (refer to FIG. 55). The fourth isolation region 65D is the part of the isolation region 65 corresponding to the fourth region 66D and covered by the wiring portion 84B (refer to FIG. 55). In this manner, the wiring connection region 65P partially surrounds each of the first to fourth low-concentration regions 62A to 62D in plan view. Thus, the wiring 90, which is connected to the wiring connection region 65P, partially surrounds each of the first to fourth low-concentration regions 62A to 62D in plan view.

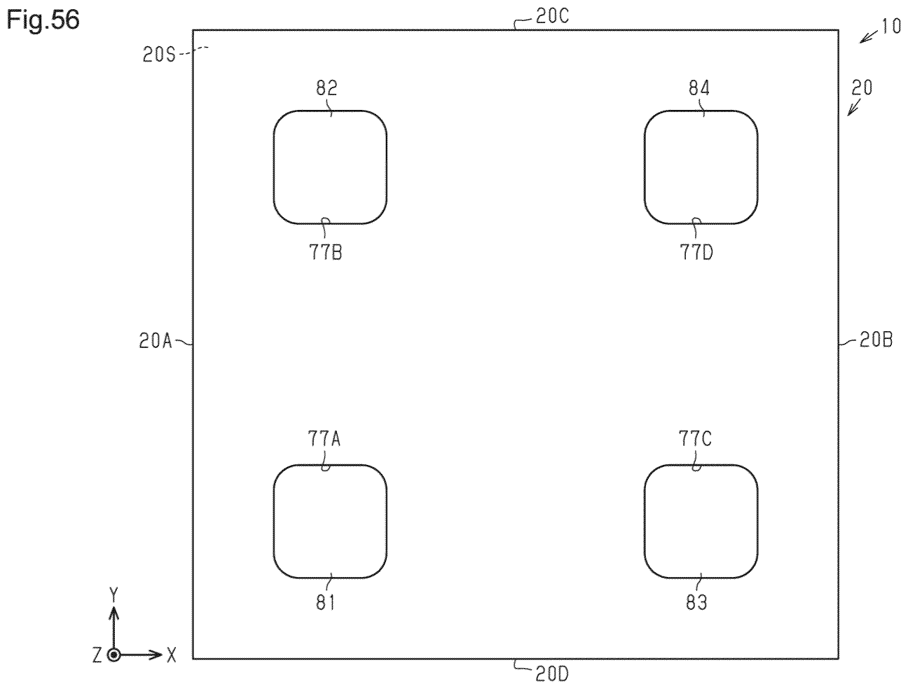

As shown in FIG. 56, the first to fourth terminal openings 77A to 77D of the TVS diode 10 in accordance with the eighth embodiment are located at the four corners in the first surface 20S of the semiconductor chip 20 in plan view. The first terminal opening 77A is located near the corner between the first side surface 20A and the fourth side surface 20D in the first surface 20S of the semiconductor chip 20. The second terminal opening 77B is located near the corner between the first side surface 20A and the third side surface 20C in the first surface 20S of the semiconductor chip 20. The third terminal opening 77C is located near the corner between the second side surface 20B and the fourth side surface 20D in the first surface 20S of the semiconductor chip 20. The fourth terminal opening 77D is located near the corner between the second side surface 20B and the third side surface 20C in the first surface 20S of the semiconductor chip 20.

The first terminal opening 77A is located at a position overlapping the first terminal contact region 33 (refer to FIG. 54) in plan view. The second terminal opening 77B is located at a position overlapping the second terminal contact region 43 (refer to FIG. 54) in plan view. The third terminal opening 77C is located at a position overlapping the third terminal contact region 53 (refer to FIG. 54) in plan view. The fourth terminal opening 77D is located at a position overlapping the fourth terminal contact region 133 (refer to FIG. 54) in plan view. The TVS diode 10 in accordance with the eighth embodiment has the same advantages as the first embodiment.

### Modified Examples

The above embodiments may be modified as described below. The above-described embodiments and the modified examples described below may be combined as long as there is no technical contradiction.

The second embodiment may be combined with the third embodiment. More specifically, the first pin junction 30 may include the first buffer region 35 and the first isolation trench structure 120A. The second pin junction 40 may include the second buffer region 45 and the second isolation trench structure 120B. The third pin junction 50 may include the third buffer region 55 and the third isolation trench structure 120C. In this case, the first partitioning region 34 may be omitted from the first pin junction 30. The second partitioning region 44 may be omitted from the second pin junction 40. The third partitioning region 54 may be omitted from the third pin junction 50.

The structure of at least one of the second and third embodiments may be applied to the fourth to eighth embodiments.

In the third embodiment, at least one of the first isolation electrode 123A, the second isolation electrode 123B, and the third isolation electrode 123C may be omitted.

In the third embodiment, at least one of the first isolation-insulation layer 122A, the second isolation-insulation layer 122B, and the third isolation-insulation layer 122C.

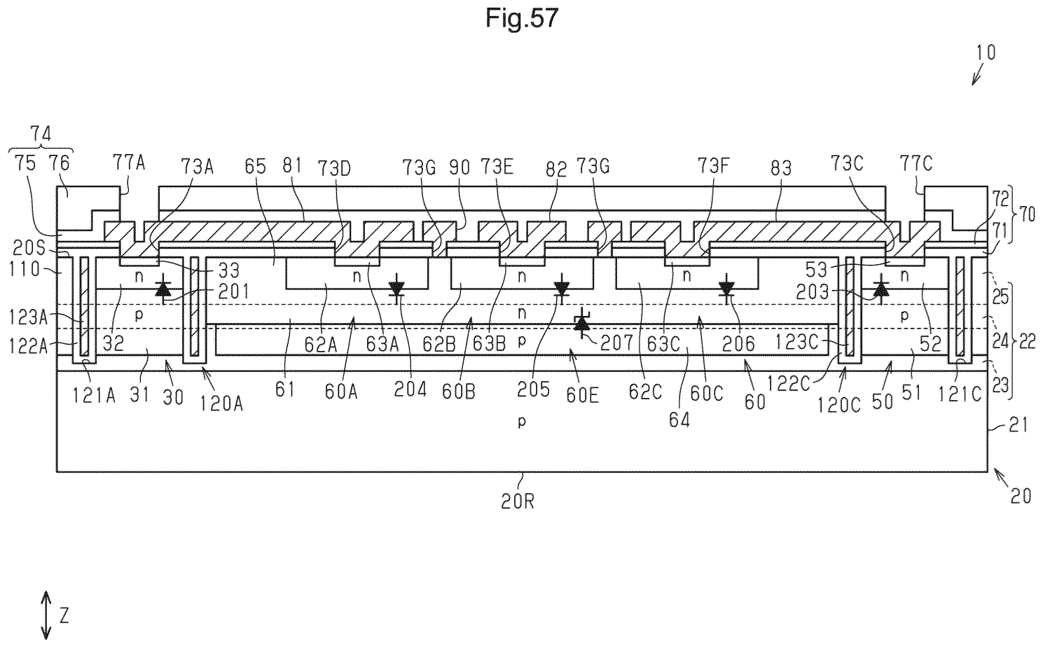

In the third embodiment, the high-concentration region 61 may have any size. FIG. 57 is a cross-sectional view of the TVS diode 10 including the high-concentration region 61 of a different size. As shown in FIG. 57, the high-concentration region 61 may be enlarged and extended to positions adjacent to the first isolation trench 121A and the third isolation trench 121C. Although not shown in the drawings, the high-concentration region 61 may be enlarged and extended to positions adjacent to the second isolation trench 121B. When the high-concentration region 61 is enlarged, the internal region 64 may also be enlarged. The TVS diode 10 of the modified example shown in FIG. 57 increases the joined area of the high-concentration region 61 and the internal region 64. This increases the surge absorption capability of the TVS diode 10.

In the modified example of FIG. 57, the high-concentration region 61, for example, may be enlarged and extended to a position adjacent to the first isolation trench 121A but be separated from the third isolation trench 121C. Alternatively, for example, the high-concentration region 61 may be enlarged and extended to a position adjacent to the third isolation trench 121C but be separated from the first isolation trench 121A.

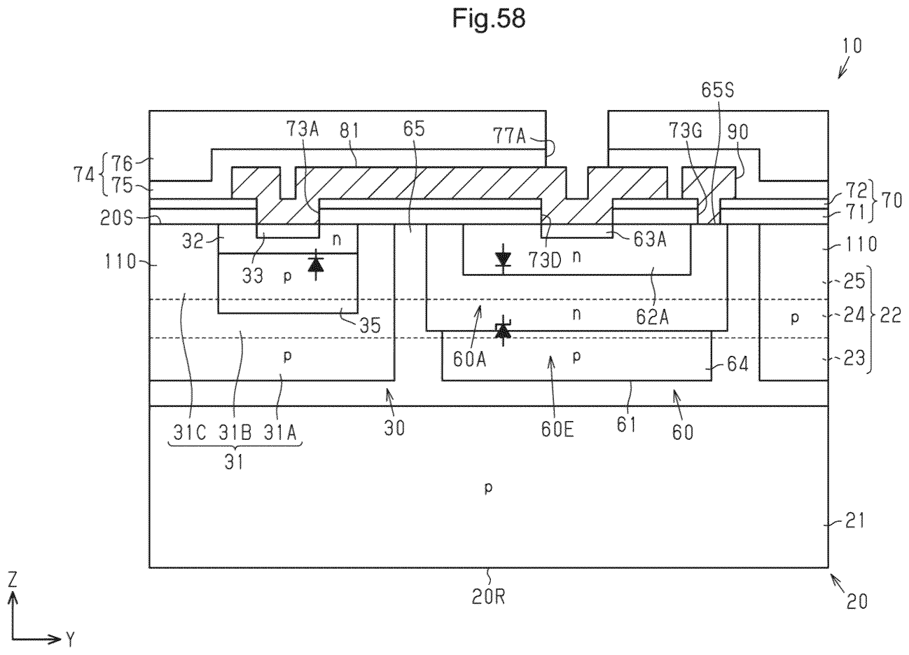

In the second embodiment, the TVS diode 10 may include the diode-paired region 60, which includes the first pin junction 30, the first reverse pin junction 60A, and the pn junction 60E. That is, the second pin junction 40, the third pin junction 50, the second reverse pin junction 60B, and the third reverse pin junction 60C may be omitted from the TVS diode 10. FIG. 58 is a schematic cross-sectional view of the TVS diode 10 in a modified example including the diode-paired region 60, which includes the first pin junction 30, the first reverse pin junction 60A, and the pn junction 60E.

As shown in FIG. 58, the edges of the internal region 64 in the diode-paired region 60 are located inward from the edges of the high-concentration region 61 in plan view. The edges of the internal region 64 are located at positions overlapping the isolation region 65 in plan view.

Although not shown in the drawing, the high-concentration region 61 is rectangular in plan view. The high-concentration region 61 includes four corners. Each corner of the high-concentration region 61 is curved in plan view. In one example, the internal region 64 is rectangular in plan view. The internal region 64 is slightly smaller than the high-concentration region 61 in plan view. Thus, the inner edges of the internal region 64 are located outward from the edges of the high-concentration region 61 in plan view. The internal region 64 is located at a position overlapping the first low-concentration region 62A in plan view. The internal region 64 includes four corners. The four corners are each curved in plan view.

In the first and third embodiments, the TVS diode 10 may include the first pin junction 30 and the diode-paired region 60, which includes the first reverse pin junction 60A and the pn junction 60E. That is, the second pin junction 40, the third pin junction 50, the second reverse pin junction 60B, and the third reverse pin junction 60C may be omitted from the TVS diode 10.

In the second embodiment, the p-type impurity concentration in the first buffer region 35 may be changed. In one example, the p-type impurity concentration in the first buffer region 35 may be greater than or equal to the p-type impurity concentration in the first terminal high-concentration region 31. In one example, the minimum value of the p-type impurity concentration in the first buffer region 35 may be less than the n-type impurity concentration in the first terminal low-concentration region 32. The p-type impurity concentration in the second buffer region 45 and the third buffer region 55 may also be changed.

In the second embodiment, the concentration gradient of the p-type impurity concentration in the first buffer region 35 may be changed. In one example, the p-type impurity concentration in the first buffer region 35 may be substantially constant in the Z-direction. The concentration gradient of the p-type impurity concentration in the second buffer region 45 and the third buffer region 55 may also be changed.

In the third to seventh embodiments, the diode-paired region 60 (high-concentration region 61) may have any shape in plan view. In one example, the diode-paired region 60 (high-concentration region 61) may be rectangular in plan view.

In the second embodiment, the diode-paired region 60 (high-concentration region 61) may be formed by a first diode-paired region, a second diode-paired region, and a third diode-paired region that are separated from one another. The first reverse pin junction 60A is arranged in the first diode-paired region. The second reverse pin junction 60B is arranged in the second diode-paired region. The third reverse pin junction 60C is arranged in the third diode-paired region. In this case, the internal region 64 may be formed by a first internal region, a second internal region, and a third internal region. The first internal region is in contact with a high-concentration region of the first diode-paired region. The second internal region is in contact with a high-concentration region of the second diode-paired region. The third internal region is in contact with a high-concentration region of the third diode-paired region.

In each of the above embodiments, the internal region 64 may overlap only one of the first low-concentration region 62A, the second low-concentration region 62B, and the third low-concentration region 62C in plan view. Alternatively, for example, in plan view, the internal region 64 may overlap both the first low-concentration region 62A and the third low-concentration region 62C and be separated from the second low-concentration region 62B. In another case, for example, in plan view, the internal region 64 may overlap both the second low-concentration region 62B and the third low-concentration region 62C and be separated from the first low-concentration region 62A.

In the first to third, fifth, and seventh embodiments, the first pin junction 30, the second pin junction 40, the third pin junction 50, and the first to third reverse pin junctions 60A to 60C may be laid out in any manner. In one example, the first pin junction 30 does not have to be arranged next to the first reverse pin junction 60A in the Y-direction in plan view. In one example, the first pin junction 30 is separated from the first reverse pin junction 60A in the X-direction in plan view. In one example, the second pin junction 40 does not have to be arranged next to the second reverse pin junction 60B in the Y-direction in plan view. In one example, the second pin junction 40 may be separated from the second reverse pin junction 60B in the X-direction in plan view. In one example, the third pin junction 50 does not have to be arranged next to the third reverse pin junction 60C in the Y-direction in plan view. In one example, the third pin junction 50 may be separated from the third reverse pin junction 60C in the X-direction in plan view.

In one example, the first pin junction 30 and the second reverse pin junction 60B do not have to be arranged next to each other in the X-direction in plan view. In one example, the first pin junction 30 and the second reverse pin junction 60B may be separated in the Y-direction so as to not overlap each other as viewed in the X-direction. In one example, the third pin junction 50 and the second reverse pin junction 60B do not have to be adjacent to each other in the X-direction in plan view. In one example, the third pin junction 50 and the second reverse pin junction 60B may be separated in the Y-direction so as not to not overlap each other as viewed in the X-direction. In one example, the first reverse pin junction 60A and the second pin junction 40 do not have to be adjacent to each other in the X-direction in plan view. In one example, the second pin junction 40 and the first reverse pin junction 60A may be separated in the Y-direction so as not to not overlap each other as viewed in the X-direction. In one example, the third reverse pin junction 60C and the second pin junction 40 do not have to be adjacent to each other in the X-direction in plan view. In one example, the second pin junction 40 and the third reverse pin junction 60C may be separated in the Y-direction so as not to not overlap each other as viewed in the X-direction.

In the seventh embodiment, the fourth pin junction 130 and the fourth reverse pin junction 60D do not have to be adjacent to each other in the Y-direction in plan view. In one example, the fourth pin junction 130 may be separated from the fourth reverse pin junction 60D in the X-direction in plan view.

In one example, the fourth pin junction 130 and the third reverse pin junction 60C do not have to be adjacent to each other in the X-direction in plan view. In one example, the fourth pin junction 130 and the third reverse pin junction 60C may be separated in the Y-direction so as not to not overlap each other as viewed in the X-direction. In one example, the fourth reverse pin junction 60D and the fourth pin junction 130 do not have to be adjacent to each other in the X-direction in plan view. In one example, the third pin junction 50 and the fourth reverse pin junction 60D may be separated in the Y-direction so as not to not overlap each other as viewed in the X-direction.

In each of the above embodiments, the edges of the internal region 64 may be located anywhere in plan view. In one example, the edges of the internal region 64 may overlap the edges of the high-concentration region 61in plan view. In one example, part of the internal region 64 may extend outward from the high-concentration region 61 in plan view. In one example, at least some of the edges of the internal region 64 may be separated from the isolation region 65 in plan view.

In each of the above embodiments, at least one of the corners of the internal region 64 may be right-angled instead of being curved in plan view.

In each of the above embodiments, the isolation region 65 may have any size and shape. The isolation region 65 is arranged to extend along the entire peripheral portion of the high-concentration region 61. That is, the isolation region 65 does not have to include a part surrounding the first reverse pin junction 60A in plan view. The isolation region 65 does not have to include a part surrounding the second reverse pin junction 60B in plan view. The isolation region 65 does not have to include a part surrounding the third reverse pin junction 60C in plan view. The isolation region 65 does not have to include a part surrounding the fourth reverse pin junction 60D in plan view.

In each of the above embodiments, the high-concentration region 90 may have any size. In one example, the area of the wiring 90 in plan view may be less than 75% of the area of the isolation region 65 in plan view. In one example, the area of the wiring 90 in plan view may be greater than 97% of the area of the isolation region 65 in plan view. In one example, the area of the wiring 90 in plan view may be greater than or equal to the area of the isolation region 65 in plan view. In one example, the area of the wiring 90 in plan view may be less than or equal to the area of the first connection electrode 81 in plan view. The area of the wiring 90 in plan view may be less than or equal to the area of the second connection electrode 82 in plan view.

In the first to third embodiments, the wiring 90 may have any shape in plan view. In one example, the wiring 90 may surround at least part of the first connection electrode 81 and the second connection electrode 82 in plan view.

In the fourth embodiment, the wiring 90 may have any shape in plan view. In one example, the wiring 90 may be arranged overlapping the peripheral portion of the isolation region 65 in plan view between the first reverse pin junction 60A and the second reverse pin junction 60B and/or between the second reverse pin junction 60B and the third reverse pin junction 60C. Further, in one example, the wiring 90 may be arranged only in parts between the first reverse pin junction 60A and the second reverse pin junction 60B and between the second reverse pin junction 60B and the third reverse pin junction 60C.

In the fifth embodiment, the wiring 90 may have any shape in plan view. In one example, the wiring 90 may be arranged overlapping the peripheral portion of the isolation region 65 in plan view at a part overlapping the first connecting region 67A. In one example, the wiring 90 may be arranged in only a part overlapping the first connecting region 67A.

In the sixth embodiment, the wiring 90 may have any shape in plan view. In one example, the wiring 90 may be arranged overlapping the peripheral portion of the isolation region 65 in plan view between the first reverse pin junction 60A and the second reverse pin junction 60B. In one example, the wiring 90 may be arranged in only a part between the first reverse pin junction 60A and the second reverse pin junction 60B.

In the seventh embodiment, the wiring 90 may have any shape in plan view. In one example, the wiring 90 may be arranged overlapping the peripheral portion of the isolation region 65 in plan view at a part overlapping at least one of the first to third connecting regions 67A to 67C. In one example, the wiring 90 may be arranged only in parts overlapping the first to third connecting regions 67A to 67C in plan view. In one example, the wiring 90 may be arranged only in parts overlapping the first connecting region 67A and the second connecting region 67B in plan view. In one example, the wiring 90 may be arranged only in parts overlapping the second connecting region 67B and the third connecting region 67C in plan view. In one example, the wiring 90 may be arranged only in parts overlapping the first connecting region 67A and the third connecting region 67C in plan view. In one example, the wiring 90 may be arranged only in parts overlapping the first to third connecting regions 67A to 67C in plan view.

In the eighth embodiment, the wiring 90 may be arranged overlapping the peripheral portion of the isolation region 65 in plan view and does not have to be arranged at the central part of the isolation region 65. In one example, the wiring 90 may be arranged only in a part overlapping the isolation region 65.

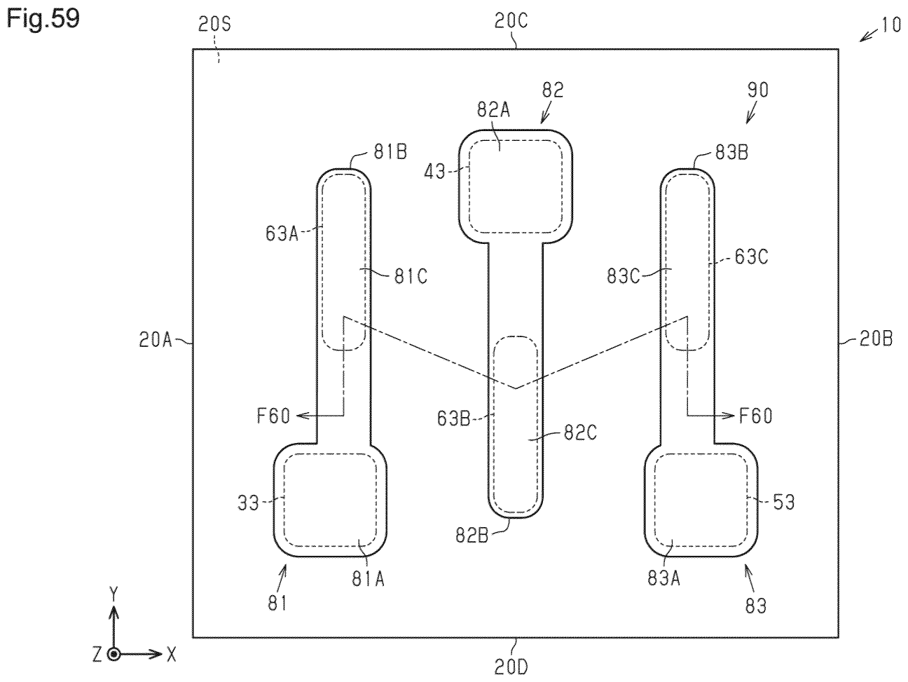

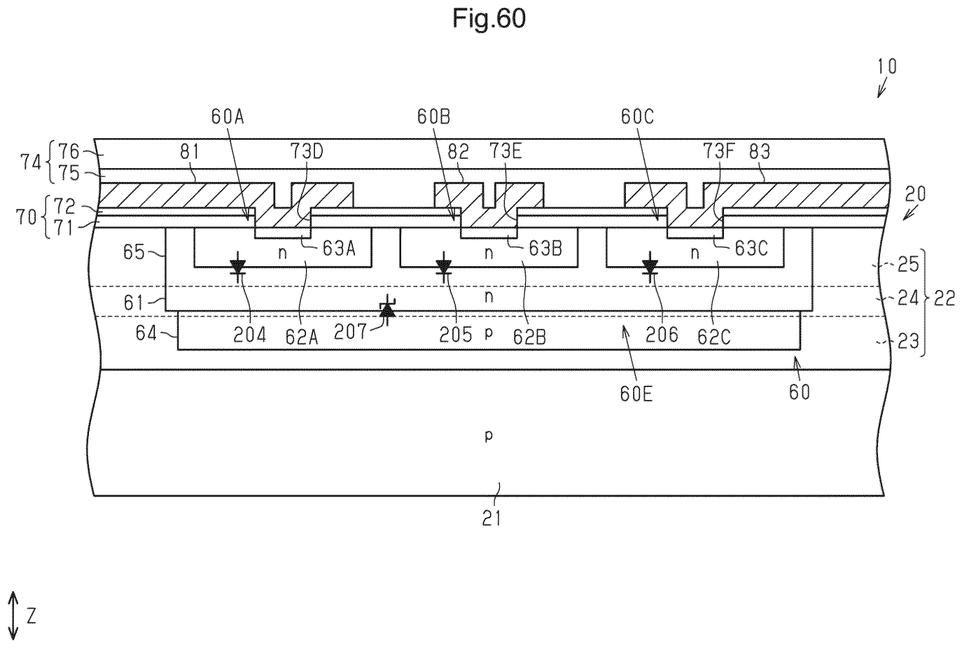

In each of the above embodiments, the wiring 90 may be omitted from the TVS diode 10. FIG. 59 is a schematic plan view of the TVS diode 10 in accordance with the first embodiment from which the wiring 90 is omitted. FIG. 60 is a schematic cross-sectional view of the TVS diode 10 taken along line F60-F60 in FIG. 59. As shown in FIG. 60, the protection layer 74 is arranged between the first to third connection electrodes 81 to 83. Thus, as shown in FIG. 60, the isolation region 65 of the diode-paired region 60 is covered by the insulation layer 70. The isolation region 65 is in contact with the insulation layer 70.

In each of the above embodiments, the semiconductor chip 20 may be structured by reversing each conductance type. That is, the p-type regions may be changed to n-type regions, and the n-type regions may be changed to p-type regions. In this case, the p-type is one example of “the first conductance type” and the n-type is one example of “the second conductance type.”

As long as the edges of the internal region 64 are located inward from the edges of the high-concentration region 61 in plan view, the TVS diode 10 may, for example, include the first pin junction 30 and the diode-paired region 60, which includes the first reverse pin junction 60A and the pn junction 60E, and not include the second pin junction 40, the third pin junction 50, the fourth pin junction 130, the second reverse pin junction 60B, the third reverse pin junction 60C, and the fourth reverse pin junction 60D.

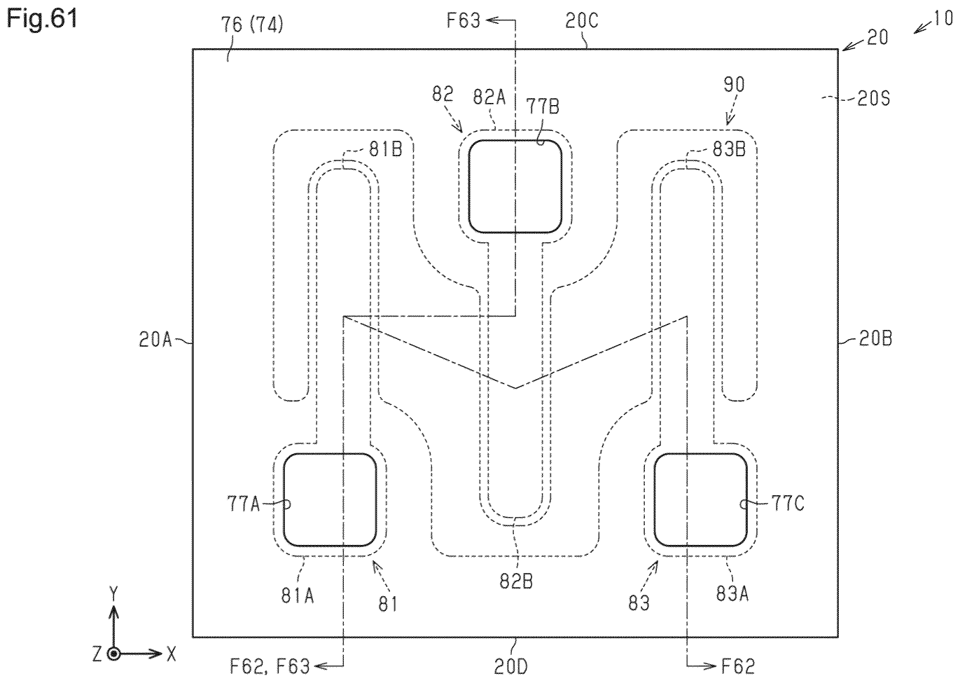

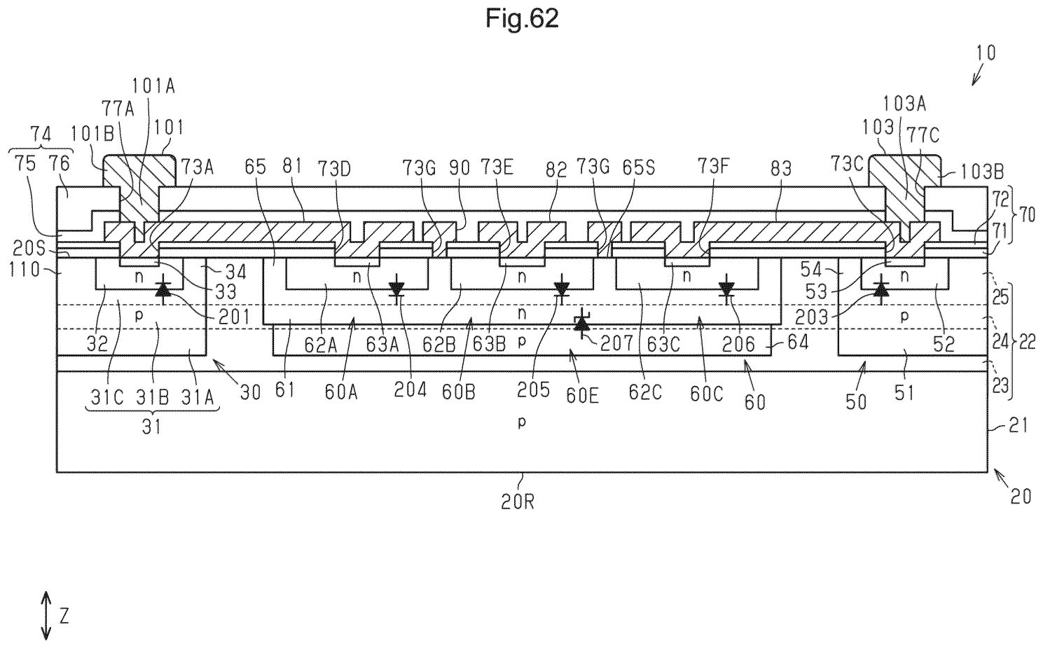

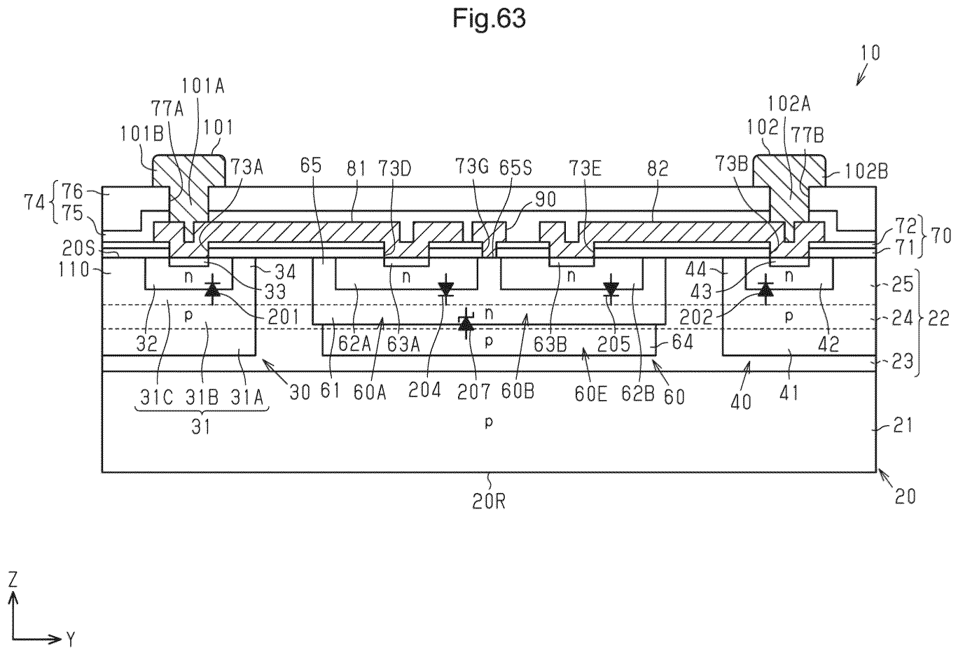

In each of the above embodiments, the TVS diode 10 may include terminals for mounting the TVS diode 10, for example, on a circuit board. FIGS. 61 to 63 show one example of the TVS diode 10 that includes terminals. FIG. 61 is a schematic plan view showing the TVS diode 10 of a modified example. FIG. 62 is a schematic cross-sectional view of the TVS diode 10 taken along line F62-F62 in FIG. 61. FIG. 63 is a schematic cross-sectional view of the TVS diode 10 taken along line F63-F63 in FIG. 61.

As shown in FIGS. 61 to 63, the TVS diode 10 includes a first terminal 101, the second terminal 102, and the third terminal 103, which are arranged on the protection layer 74.

As shown in FIG. 61, the first terminal 101, the second terminal 102, and the third terminal 103 are separated from one another. More specifically, the first terminal 101 and the third terminal 103 are located at the same position in the Y-direction and separated from each other in the X-direction. The first terminal 101 and the third terminal 103 are located closer to the fourth side surface 20D than the central part of the first surface 20S of the semiconductor chip 20 is in the Y-direction. The first terminal 101 is located closer to the first side surface 20A than the central part of the first surface 20S is in the X-direction. The third terminal 103 is located closer to the second side surface 20B than the central part of the first surface 20S is in the X-direction.

The second terminal 102 is located at a position separated from the first terminal 101 and the third terminal 103 in both the X-direction and the Y-direction. The second terminal 102 is located closer to the third side surface 20C than the central part of the first surface 20S of the semiconductor chip 20 is in the Y-direction. The second terminal 102 is located at the central part of the first surface 20S in the X-direction. Thus, the second terminal 102 is located between the first terminal 101 and the third terminal 103 in the X-direction as viewed in the Y-direction.

As shown in FIGS. 62 and 63, the first terminal 101 is arranged at a position overlapping the first pin junction 30 in plan view. The second terminal 102 is arranged at a position overlapping the second pin junction 40 in plan view. The third terminal 103 is arranged at a position overlapping the third pin junction 50 in plan view.

The first terminal 101 is arranged at a position overlapping the pin connection portion 81A of the first connection electrode 81 in plan view. The second terminal 102 is arranged at a position overlapping the pin connection portion 82A of the second connection electrode 82 in plan view. The third terminal 103 is arranged at a position overlapping the pin connection portion 83A of the third connection electrode 83 in plan view.

The first terminal 101 is electrically connected to the first connection electrode 81 through the first terminal opening 77A. The first terminal 101 includes a first contact portion 101A, which is arranged in the first terminal opening 77A in contact with the first connection electrode 81, and a first mounting portion 101B, which is arranged on the protection layer 74. In one example, the first contact portion 101A is integrated with the first mounting portion 101B.

The second terminal 102 is electrically connected to the second connection electrode 82 through the second terminal opening 77B. The second terminal 102 includes a second contact portion 102A, which is arranged in the second terminal opening 77B in contact with the second connection electrode 82, and a second mounting portion 102B, which is arranged on the protection layer 74. In one example, the second contact portion 102A is integrated with the second mounting portion 102B.

The third terminal 103 is electrically connected to the third connection electrode 83 through the third terminal opening 77C. The third terminal 103 includes a third contact portion 103A, which is arranged in the third terminal opening 77C in contact with the third connection electrode 83, and a third mounting portion 103B, which is arranged on the protection layer 74. In one example, the third contact portion 103A is integrated with the third mounting portion 103B.

Each of the first to third terminals 101 to 103 has, for example, a laminate structure formed by laminating a nickel (Ni) layer, a palladium (Pd) layer, and a gold (Au) layer in this order from the first surface 20S of the semiconductor chip 20.

In the same manner as the example shown in FIGS. 61 to 63, in the fifth and sixth embodiments, the TVS diode 10 may include the first terminal 101 and the second terminal 102. Further, in the same manner as the example shown in FIGS. 61 to 63, in the sixth and eighth, the TVS diode 10 may include the first terminal 101, the second terminal 102, the third terminal 103, and a fourth terminal.

One or more of the various examples described in this specification may be combined as long as there is no technical contradiction.

In this specification, the word “on” includes the meaning of “above” in addition to the meaning of “on” unless otherwise described in the context. Accordingly, for example, the expression of “first element arranged on second element” may mean that the first element is arranged directly on the second element in one embodiment and mean that the first element is arranged above the second element without contacting the second element in another embodiment. Thus, the word “on” will also allow for a structure in which another element is formed between the first element and the second element.

The Z-direction as referred to in this specification does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction.

### CLAUSES

Technical concepts that can be understood from the present disclosure will now be described. Reference characters used in the above embodiments are added to corresponding elements in the clauses to aid understanding without any intention to impose limitations to these elements. The reference characters are given as examples to aid understanding and not intended to limit elements to the elements denoted by the reference characters.

### Clause A1

A TVS diode (10), including:
a semiconductor chip (20) including a first surface (20S) and a second surface (20R) at a side opposite the first surface (20S), where
the semiconductor chip (20) includes
   a first pin junction (30) for a first polarity direction, arranged toward the first surface (20S) of the semiconductor chip (20),
   a second pin junction (40) for the first polarity direction, arranged toward the first surface (20S) of the semiconductor chip (20) in a region separated from the first pin junction (30) in a plan view taken in a thickness direction (Z) of the semiconductor chip (20), and
   a diode-paired region (60) separated from both the first pin junction (30) and the second pin junction (40) in the plan view,
the diode-paired region (60) includes
   a high-concentration region (61) of a first conductance type separated from the first surface (20S) of the semiconductor chip (20) and arranged toward the second surface (20R),
   a first low-concentration region (62A) and a second low-concentration region (62B) that have a lower impurity concentration than the high-concentration region (61) and are separated from each other and closer to the first surface (20S) than the high-concentration region (61) is at positions overlapping the high-concentration region (61) in the plan view,
   an isolation region (65) isolating the first low-concentration region (62A) and the second low-concentration region (62B), and arranged closer to the first surface (20S) than the high-concentration region (61) is at a position overlapping the high-concentration region (61) in the plan view,
   a first contact region (63A) of a second conductance type arranged in an outer portion of the first low-concentration region (62A),
   a second contact region (63B) of the second conductance type arranged in an outer portion of the second low-concentration region (62B), and
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form a first reverse pin junction (60A) for a second polarity direction,
the high-concentration region (61), the second low-concentration region (62B), and the second contact region (63B) form a second reverse pin junction (60B) for the second polarity direction,
the high-concentration region (61) and the internal region (64) form a pn junction (60E) for the first polarity direction, connected in a reverse direction to the first reverse pin junction (60A) and the second reverse pin junction (60B), and
the internal region (64) is arranged overlapping both the first low-concentration region (62A) and the second low-concentration region (62B) in the plan view.

### Clause A2

The TVS diode according to clause A1, where
the first polarity direction is a direction in which forward current flows from the second surface (20R) toward the first surface (20S) in the thickness direction (Z) of the semiconductor chip (20), and
the second polarity direction is a direction in which forward current flows opposite to the first polarity direction in the thickness direction (Z) of the semiconductor chip (20).

### Clause A3

The TVS diode according to clause A1 or A2, where
the isolation region (65) includes an exposed surface (65S) exposed from the first surface (20S), and
the TVS diode includes wiring (90) contacting the exposed surface (65S).

### Clause A4

The TVS diode according to clause A3, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first partitioning region (34) surrounding the first terminal low-concentration region (32) and arranged closer to the first surface (20S) than the first terminal high-concentration region (31) is at a position overlapping the first terminal high-concentration region (31) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42), and
   a second partitioning region (44) surrounding the second terminal low-concentration region (42) and arranged closer to the first surface (20S) than the second terminal high-concentration region (41) is at a position overlapping the second terminal high-concentration region (41) in the plan view, and
the first terminal high-concentration region (31), the first terminal low-concentration region (32), and the first terminal contact region (33) form the first pin junction (30), and
the second terminal high-concentration region (41), the second terminal low-concentration region (42), and the second terminal contact region (43) form the second pin junction (40).

### Clause A5

The TVS diode according to clause A4, further including:
an insulation layer (70) covering the first surface (20S);
a first connection electrode (81) arranged on the insulation layer (70) and connecting the first contact region (63A) and the first terminal contact region (33); and
a second connection electrode (82) arranged on the insulation layer (70) and connecting the second contact region (63B) and the second terminal contact region (43).

### Clause A6

The TVS diode according to clause A5, where
the isolation region (65) includes
   a first isolation region (65A) overlapping the first connection electrode (81) in the plan view,
   a second isolation region (65B) overlapping the second connection electrode (82) in the plan view, and
   a wiring connection region (65P) connected to the wiring (90), and
the wiring connection region (65P) is arranged partially surrounding each of the first reverse pin junction (60A) and the second reverse pin junction (60B) in the plan view.

### Clause A7

The TVS diode according to clause A6, where the wiring (90) is arranged individually and partially surrounding both the first connection electrode (81) and the second connection electrode (82) in the plan view.

### Clause A8

The TVS diode according to clause A6 or A7, where the wiring (90) has a larger area than the first connection electrode (81) in the plan view.

### Clause A9

The TVS diode according to any one of clauses A5 to A8, where the wiring (90) has a smaller area than the isolation region (65) in the plan view.

### Clause A10

The TVS diode according to clause A9, where the area of the wiring (90) is within a range from 75% to 97%, inclusive, of the area of the isolation region (65) in the plan view.

### Clause A11

The TVS diode according to any one of clauses A5 to A10, further including:
a protection layer (74) covering the first connection electrode (81) and the second connection electrode (82);
a first terminal (101) arranged on the protection layer (74) and electrically connected to the first pin junction (30); and
a second terminal (102) arranged on the protection layer (74) and electrically connected to the second pin junction (40), where
the protection layer (74) includes
   a first terminal opening (77A) partially exposing the first connection electrode (81), and
   a second terminal opening (77B) partially exposing the second connection electrode (82),
the first terminal (101) is electrically connected to the first connection electrode (81) through the first terminal opening (77A), and
the second terminal (102) is electrically connected to the second connection electrode (82) through the second terminal opening (77B).

### Clause A12

The TVS diode according to any one of clauses A1 to A11, where the internal region (64) has edges located inward from edges of the high-concentration region (61) in the plan view.

### Clause A13

The TVS diode according to clause A12, where
the edges of the internal region (64) form corners in the plan view, and
the corners are each curved in the plan view.

### Clause A14

The TVS diode according to clause A12 or A13, where the edges of the internal region (64) are located at positions overlapping the isolation region (65) in the plan view.

### Clause A15

The TVS diode according to any one of clauses A1 to A3, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first isolation trench (121A) arranged in the first surface (20S) and surrounding the first terminal high-concentration region (31), the first terminal low-concentration region (32), and the first terminal contact region (33),
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42), and
   a second isolation trench (121B) arranged in the first surface (20S) and surrounding the second terminal high-concentration region (41), the second terminal low-concentration region (42), and the second terminal contact region (43),
the first terminal high-concentration region (31), the first terminal low-concentration region (32), and the first terminal contact region (33) form the first pin junction (30), and
the second terminal high-concentration region (41), the second terminal low-concentration region (42), and the second terminal contact region (43) form the second pin junction (40).

### Clause A16

The TVS diode according to clause A15, where the semiconductor chip (20) includes
a first isolation-insulation layer (122A) arranged in the first isolation trench (121A), and
a second isolation-insulation layer (122B) arranged in the second isolation trench (121B).

### Clause A17

The TVS diode according to clause A16, further including:
a first isolation electrode (123A) embedded in the first isolation trench (121A) with the first isolation-insulation layer (122A) interposed;
a second isolation electrode (123B) embedded in the second isolation trench (121B) with the second isolation-insulation layer (122B) interposed,
where the first isolation electrode (123A) and the second isolation electrode (123B) are both in an electrically floating state.

### Clause A18

The TVS diode according to any one of clauses A15 to A17, where the high-concentration region (61) is adjacent to at least one of the first isolation trench (121A) and the second isolation trench (121B) in the plan view.

### Clause A19

The TVS diode according to any one of clauses A1 to A3, further including:
a third pin junction (50) for the first polarity direction, arranged toward the first surface (20S) of the semiconductor chip (20) in a region separated from both the first pin junction (30) and the second pin junction (40) in the plan view, where
the diode-paired region (60) includes
   a third low-concentration region (62C) of the first conductance type having a lower impurity concentration than the high-concentration region (61) and being arranged closer to the first surface (20S) than the high-concentration region (61) is separated from both the first low-concentration region (62A) and the second low-concentration region (62B) at a position overlapping the high-concentration region (61) in the plan view,
   a third contact region (63C) of the second conductance type arranged in an outer portion of the third low-concentration region (62C),
the isolation region (65) isolates the first low-concentration region (62A), the second low-concentration region (62B), and the third low-concentration region (62C),
the high-concentration region (61), the third low-concentration region (62C), and the third contact region (63C) form a third reverse pin junction (60C) for the second polarity direction,
the pn junction (60E) is configured to be connected in a reverse direction to the third reverse pin junction (60C), and
the internal region (64) overlaps the first low-concentration region (62A), the second low-concentration region (62B), and the third low-concentration region (62C) in the plan view.

### Clause A20

The TVS diode according to clause A19, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first partitioning region (34) surrounding the first terminal low-concentration region (32) and arranged closer to the first surface (20S) than the first terminal high-concentration region (31) is at a position overlapping the first terminal high-concentration region (31) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42),
   a second partitioning region (44) surrounding the second terminal low-concentration region (42) and arranged closer to the first surface (20S) than the second terminal high-concentration region (41) is at a position overlapping the second terminal high-concentration region (41) in the plan view,
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged closer to the first surface (20S) than the third terminal high-concentration region (51) is at a position overlapping the third terminal high-concentration region (51) in the plan view,
   a third terminal contact region (53) of the first conductance type arranged in an outer portion of the third terminal low-concentration region (52), and
   a third partitioning region (54) surrounding the third terminal low-concentration region (52) and arranged closer to the first surface (20S) than the third terminal high-concentration region (51) is at a position overlapping the third terminal high-concentration region (51) in the plan view,
the first terminal high-concentration region (31), the first terminal low-concentration region (32), and the first terminal contact region (33) form the first pin junction (30),
the second terminal high-concentration region (41), the second terminal low-concentration region (42), and the second terminal contact region (43) form the second pin junction (40), and
the third terminal high-concentration region (51), the third terminal low-concentration region (52), and the third terminal contact region (53) form the third pin junction (50).

### Clause A21

The TVS diode according to clause A20, further including:
an insulation layer (70) covering the first surface (20S);
a first connection electrode (81) arranged on the insulation layer (70) and connecting the first contact region (63A) and the first terminal contact region (33);
a second connection electrode (82) arranged on the insulation layer (70) and connecting the second contact region (63B) and the second terminal contact region (43); and
a third connection electrode (83) arranged on the insulation layer (70) and connecting the third contact region (63C) and the third terminal contact region (53).

### Clause A22

The TVS diode according to clause A21, where
the isolation region (65) includes an exposed surface (65S) exposed from the first surface (20S),
the TVS diode includes wiring (90) contacting the exposed surface (65S),
the isolation region (65) includes
   a first isolation region (65A) overlapping the first connection electrode (81) in the plan view,
   a second isolation region (65B) overlapping the second connection electrode (82) in the plan view,
   a third isolation region (65C) overlapping the third connection electrode (83) in the plan view, and
   a wiring connection region (65P) connected to the wiring (90), and
the wiring connection region (65P) is arranged partially surrounding each of the first reverse pin junction (60A), the second reverse pin junction (60B), and the third reverse pin junction (60C) in the plan view.

### Clause A23

The TVS diode according to clause A22, where the wiring (90) is arranged partially surrounding each of the first connection electrode (81), the second connection electrode (82), and the third connection electrode (83) in the plan view.

### Clause A24

The TVS diode according to clause A19, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first isolation trench (121A) arranged in the first surface (20S) and surrounding the first terminal high-concentration region (31), the first terminal low-concentration region (32), and the first terminal contact region (33),
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42),
   a second isolation trench (121B) arranged in the first surface (20S) and surrounding the second terminal high-concentration region (41), the second terminal low-concentration region (42), and the second terminal contact region (43),
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged closer to the first surface (20S) than the third terminal high-concentration region (51) is at a position overlapping the third terminal high-concentration region (51) in the plan view,
   a third terminal contact region (53) of the first conductance type arranged in an outer portion of the third terminal low-concentration region (52), and
   a third isolation trench (121C) arranged in the first surface (20S) and surrounding the third terminal high-concentration region (51), the third terminal low-concentration region (52), and the third terminal contact region (53),
the first terminal high-concentration region (31), the first terminal low-concentration region (32), and the first terminal contact region (33) form the first pin junction (30),
the second terminal high-concentration region (41), the second terminal low-concentration region (42), and the second terminal contact region (43) form the second pin junction (40), and
the third terminal high-concentration region (51), the third terminal low-concentration region (52), and the third terminal contact region (53) form the third pin junction (50).

### Clause A25

The TVS diode according to clause A24, where the semiconductor chip (20) includes
a first isolation-insulation layer (122A) arranged in the first isolation trench (121A),
a second isolation-insulation layer (122B) arranged in the second isolation trench (121B), and
a third isolation-insulation layer (122C) arranged in the third isolation trench (121C).

### Clause A26

The TVS diode according to clause A25, further including:
a first isolation electrode (123A) embedded in the first isolation trench (121A) with the first isolation-insulation layer (122A) interposed;
a second isolation electrode (123B) embedded in the second isolation trench (121B) with the second isolation-insulation layer (122B) interposed; and
a third isolation electrode (123C) embedded in the third isolation trench (121C) with the third isolation-insulation layer (122C) interposed,
where the first isolation electrode (123A), the second isolation electrode (123B), and the third isolation electrode (123C) are each in an electrically floating state.

### Clause A27

The TVS diode according to clause A19, further including:
a fourth pin junction (130) for the first polarity direction, arranged toward the first surface (20S) of the semiconductor chip (20) in a region separated from each of the first pin junction (30), the second pin junction (40), and the third pin junction (50) in the plan view, where
the diode-paired region (60) includes
   a fourth low-concentration region (62D) of the first conductance type having a lower impurity concentration than the high-concentration region (61) and arranged closer to the first surface (20S) than the high-concentration region (61) is separated from each of the first low-concentration region (62A), the second low-concentration region (62B), and the third low-concentration region (62C) at a position overlapping the high-concentration region (61) in the plan view, and
   a fourth contact region (63D) of the second conductance type arranged in an outer portion of the fourth low-concentration region (62D),
the isolation region (65) isolates the first low-concentration region (62A), the second low-concentration region (62B), the third low-concentration region (62C), and the fourth low-concentration region (62D),
   the high-concentration region (61), the fourth low-concentration region (62D), and the fourth contact region (63D) form a fourth reverse pin junction (60D) for the second polarity direction,
   the pn junction (60E) is configured to be connected in a reverse direction to the fourth reverse pin junction (60D), and
   the internal region (64) overlaps the first low-concentration region (62A), the second low-concentration region (62B), the third low-concentration region (62C), and the fourth low-concentration region (62D) in the plan view.

### Clause A28

The TVS diode according to clause A27, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first partitioning region (34) surrounding the first terminal low-concentration region (32) and arranged closer to the first surface (20S) than the first terminal high-concentration region (31) is at a position overlapping the first terminal high-concentration region (31) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42),
   a second partitioning region (44) surrounding the second terminal low-concentration region (42) and arranged closer to the first surface (20S) than the second terminal high-concentration region (41) is at a position overlapping the second terminal high-concentration region (41) in the plan view,
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged closer to the first surface (20S) than the third terminal high-concentration region (51) is at a position overlapping the third terminal high-concentration region (51) in the plan view,
   a third terminal contact region (53) of the first conductance type arranged in an outer portion of the third terminal low-concentration region (52),
   a third partitioning region (54) surrounding the third terminal low-concentration region (52) and arranged closer to the first surface (20S) than the third terminal high-concentration region (51) is at a position overlapping the third terminal high-concentration region (51) in the plan view,
   a fourth terminal high-concentration region (131) of the second conductance type separated from the first surface (20S) of the semiconductor chip (20) and arranged toward the second surface (20R), the fourth terminal high-concentration region (131) being separated from each of the first terminal high-concentration region (31), the second terminal high-concentration region (41), and the third terminal high-concentration region (51) in the plan view,
   a fourth terminal low-concentration region (132) of the first conductance type arranged closer to the first surface (20S) than the fourth terminal high-concentration region (131) is at a position overlapping the fourth terminal high-concentration region (131) in the plan view,
   a fourth terminal contact region (133) of the first conductance type arranged in an outer portion of the fourth terminal low-concentration region (132), and
   a fourth partitioning region (134) surrounding the fourth terminal low-concentration region (132) and arranged closer to the first surface (20S) than the fourth terminal high-concentration region (131) is at a position overlapping the fourth terminal high-concentration region (131),
the first terminal high-concentration region (31), the first terminal low-concentration region (32), and the first terminal contact region (33) form the first pin junction (30),
the second terminal high-concentration region (41), the second terminal low-concentration region (42), and the second terminal contact region (43) form the second pin junction (40),
the third terminal high-concentration region (51), the third terminal low-concentration region (52), and the third terminal contact region (53) form the third pin junction (50), and
the fourth terminal high-concentration region (131), the fourth terminal low-concentration region (132), and the fourth terminal contact region (133) form the fourth pin junction (130).

### Clause A29

The TVS diode according to clause A28, further including:
an insulation layer (70) covering the first surface (20S);
a first connection electrode (81) arranged on the insulation layer (70) and connecting the first contact region (63A) and the first terminal contact region (33);
a second connection electrode (82) arranged on the insulation layer (70) and connecting the second contact region (63B) and the second terminal contact region (43);
a third connection electrode (83) arranged on the insulation layer (70) and connecting the third contact region (63C) and the third terminal contact region (53); and
a fourth connection electrode (84) arranged on the insulation layer (70) and connecting the fourth contact region (63D) and the fourth terminal contact region (133).

### Clause A30

The TVS diode according to clause A29, where
the isolation region (65) includes an exposed surface (65S) exposed from the first surface (20S),
the TVS diode includes wiring (90) contacting the exposed surface (65S),
the isolation region (65) includes
   a first isolation region (65A) overlapping the first connection electrode (81) in the plan view,
   a second isolation region (65B) overlapping the second connection electrode (82) in the plan view,
   a third isolation region (65C) overlapping the third connection electrode (83) in the plan view,
   a fourth isolation region (65D) overlapping the fourth connection electrode (84) in the plan view, and
   a wiring connection region (65P) connected to the wiring (90), and
the wiring connection region (65P) is arranged partially surrounding each of the first reverse pin junction (60A), the second reverse pin junction (60B), the third reverse pin junction (60C), and the fourth reverse pin junction (60D) in the plan view.

### Clause A31

The TVS diode according to clause A30, where the wiring (90) is arranged partially surrounding each of the first connection electrode (81), the second connection electrode (82), the third connection electrode (83), and the fourth connection electrode (84) in the plan view.

### Clause A32

A TVS diode (10), including:
a semiconductor chip (20) including a first surface (20S) and a second surface (20R) at a side opposite the first surface (20S), where
the semiconductor chip (20) includes
   a first pin junction (30) for a first polarity direction, arranged toward the first surface (20S) of the semiconductor chip (20), and
   a diode-paired region (60) including a first reverse pin junction (60A) for a second polarity direction, separated from the first pin junction (30) in a plan view taken in a thickness direction (Z) of the semiconductor chip (20), and a pn junction (60E) for the first polarity direction, forming a diode pair with the first reverse pin junction (60A),
the diode-paired region (60) includes
   a high-concentration region (61) of a first conductance type separated from the first surface (20S) of the semiconductor chip (20) and arranged toward the second surface (20R),
   a first low-concentration region (62A) having a lower impurity concentration than the high-concentration region (61) and arranged closer to the first surface (20S) than the high-concentration region (61) is separated from the high-concentration region (61) at a position overlapping the high-concentration region (61) in the plan view,
   a first contact region (63A) of a second conductance type arranged in an outer portion of the first low-concentration region (62A),
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form a first reverse pin junction (60A) for a second polarity direction,
the high-concentration region (61) and the internal region (64) form a pn junction (60E) for the first polarity direction, connected in a reverse direction to the first reverse pin junction (60A), and
the internal region (64) has edges located inward from edges of the high-concentration region (61) in the plan view.

### Clause A33

The TVS diode according to clause A32, where
the edges of the internal region (64) form corners in the plan view, and
the corners are each curved in the plan view.

### Clause A34

The TVS diode according to clause A32 or A33, further comprising:
an isolation region (65) isolating the first low-concentration region (62A) and the second low-concentration region (62B), and arranged closer to the first surface (20S) than the high-concentration region (61) is at a position overlapping the high-concentration region (61) in the plan view,
where the edges of the internal region (64) are located at positions overlapping the isolation region (65) in the plan view.

### Clause B1

A TVS diode (10), including:
a semiconductor chip (20) including a first surface (20S) and a second surface (20R) at a side opposite the first surface (20S), where
the semiconductor chip (20) includes
   a first pin junction (30) and a second pin junction (40) that are for a first polarity direction and are arranged in a region located toward the first surface (20S) of the semiconductor chip (20), and
   a diode-paired region (60) including a first reverse pin junction (60A) and a second reverse pin junction (60B) that are for a second polarity direction and arranged toward the first surface (20S) of the semiconductor chip (20), and a pn junction (60E) for the first polarity direction, arranged at a position overlapping the first reverse pin junction (60A) and the second reverse pin junction (60B) in a plan view taken in a thickness direction (Z) of the semiconductor chip (20) and forming a diode pair with the first reverse pin junction (60A) and the second reverse pin junction (60B), in which the diode-paired region (60) is separated from both the first pin junction (30) and the second pin junction (40), and
the diode-paired region (60) is located between the first pin junction (30) and the second pin junction (40) in the plan view.

### Clause B2

The TVS diode according to clause B1, where
the first pin junction (30) and the first reverse pin junction (60A) are arranged next to each other in a first direction (Y) in the plan view,
the second pin junction (40) and the second reverse pin junction (60B) are arranged next to each other in the first direction (Y) in the plan view,
the first pin junction (30) and the second reverse pin junction (60B) are adjacent to each other in a second direction (X), orthogonal to the first direction (Y), in the plan view,
the first reverse pin junction (60A) and the second pin junction (40) are adjacent to each other in the second direction (X) in the plan view, and
the diode-paired region (60) includes a region (67A) located between the first pin junction (30) and the second pin junction (40) in a direction intersecting both the first direction (Y) and the second direction (X) in the plan view.

### Clause B3

The TVS diode according to clause B2, where
the diode-paired region (60) includes
   a first region (66A) in which the first reverse pin junction (60A) is arranged, and
   a second region (66B) in which the second reverse pin junction (60B) is arranged, and
the second region (66B) includes a part shifted from the first region (66A) in the first direction (Y).

### Clause B4

The TVS diode according to clause B3, where
the first region (66A) is adjacent to the second pin junction (40) in the second direction (X) in the plan view, and
the second region (66B) is adjacent to the first pin junction (30) in the second direction (X) in the plan view.

### Clause B5

The TVS diode according to clause B1, where
the diode-paired region (60) is located between the first pin junction (30) and the second pin junction (40) in a first direction (Y) in the plan view,
the first pin junction (30) is arranged next to both the first reverse pin junction (60A) and the second reverse pin junction (60B) in the plan view, and
the second pin junction (40) is arranged next to both the first reverse pin junction (60A) and the second reverse pin junction (60B) in the plan view.

### Clause B6

The TVS diode according to any one of clauses B2 to B4, where
the diode-paired region (60) includes
   a high-concentration region (61) of a first conductance type separated from the first surface (20S) of the semiconductor chip (20) and arranged toward the second surface (20R),
   a first low-concentration region (62A) and a second low-concentration region (62B) that have a lower impurity concentration than the high-concentration region (20) and are separated from each other and close to the first surface (20S) of the semiconductor chip (20) at positions overlapping the high-concentration region (61) in the plan view,
   an isolation region (65) electrically isolating the first low-concentration region (62A) and the second low-concentration region (62B), and arranged closer to the first surface (20S) than the high-concentration region (61) is at a position overlapping the high-concentration region (61) in the plan view,
   a first contact region (63A) of a second conductance type arranged in an outer portion of the first low-concentration region (62A),
   a second contact region (63B) of the second conductance type arranged in an outer portion of the second low-concentration region (62B), and
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form the first reverse pin junction (60A),
the high-concentration region (61), the second low-concentration region (62B), and the second contact region (63B) form the second reverse pin junction (60B), and
the high-concentration region (61) and the internal region (64) form the pn junction (60E) connected in a reverse direction to the first reverse pin junction (60A) and the second reverse pin junction (60B).

### Clause B7

The TVS diode according to clause B6, further including:
an insulation layer (70) covering the first surface (20S);
a first connection electrode (81) arranged on the insulation layer (70) and electrically connecting the first contact region (63A) and the first pin junction (30); and
a second connection electrode (82) arranged on the insulation layer (70) and electrically connecting the second contact region (63B) and the second pin junction (40).

### Clause B8

The TVS diode according to clause B7, where
the first connection electrode (81) and the second connection electrode (82) are separated from each other in the second direction (X) in the plan view, and
the first connection electrode (81) and the second connection electrode (82) each extend in the first direction (Y) in the plan view.

### Clause B9

The TVS diode according to clause B7 or B8, further including:
a protection layer (74) covering the first connection electrode (81) and the second connection electrode (82);
a first terminal (101) arranged on the protection layer (74) and electrically connected to the first pin junction (30); and
a second terminal (102) arranged on the protection layer (74) and electrically connected to the second pin junction (40), where
the protection layer (74) includes
   a first terminal opening (77A) partially exposing the first connection electrode (81), and
   a second terminal opening (77B) partially exposing the second connection electrode (82),
the first terminal (101) is electrically connected to the first connection electrode (81) through the first terminal opening (77A), and
the second terminal (102) is electrically connected to the second connection electrode (82) through the second terminal opening (77B).

### Clause B10

The TVS diode according to any one of clauses B2 to B4, where
the semiconductor chip (20) includes
   a third pin junction (50) for the first polarity direction, arranged toward the first surface (20S) of the semiconductor chip (20), and
   a third reverse pin junction (60C) for the second polarity direction, arranged toward the first surface (20S) of the semiconductor chip (20), and forming the diode pair with the pn junction (60E),
the third pin junction (50) and the third reverse pin junction (60C) are electrically connected and arranged next to each other in the first direction (Y) in the plan view,
the third pin junction (50) and the third reverse pin junction (60C) are arranged adjacent to each other at a side of the second pin junction (40) and the second reverse pin junction (60B) opposite the first pin junction (30) and the first reverse pin junction (60A) in the second direction (X) in the plan view,
the third pin junction (50) and the second reverse pin junction (60B) are adjacent to each other in the second direction (X) in the plan view,
the third reverse pin junction (60C) and the second pin junction (40) are adjacent to each other in the second direction (X) in the plan view, and
the diode-paired region (60) includes a region (67B) located between the second pin junction (40) and the third pin junction (50) in a direction intersecting both the first direction (Y) and the second direction (X) in the plan view.

### Clause B11

The TVS diode according to clause B10, where
the diode-paired region (60) includes
   a high-concentration region (61) of a first conductance type separated from the first surface (20S) of the semiconductor chip (20) and arranged toward the second surface (20R),
   a first low-concentration region (62A), a second low-concentration region (62B), and a third low-concentration region (62C) that are of the first conductance type, have a lower impurity concentration than the high-concentration region (61), and are separated from one another and toward the first surface (20S) of the semiconductor chip (20) at positions overlapping the high-concentration region (61) in the plan view,
   an isolation region (65) electrically isolating the first low-concentration region (62A), the second low-concentration region (62B), and the third low-concentration region (62C), and arranged closer to the first surface (20S) than the high-concentration region (61) is at a position overlapping the high-concentration region (61) in the plan view,
   a first contact region (63A) of a second conductance type arranged in an outer portion of the first low-concentration region (62A),
   a second contact region (63B) of the second conductance type arranged in an outer portion of the second low-concentration region (62B),
   a third contact region (63C) of the second conductance type arranged in an outer portion of the third low-concentration region (62C), and
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form the first reverse pin junction (60A),
the high-concentration region (61), the second low-concentration region (62B), and the second contact region (63B) form the second reverse pin junction (60B),
the high-concentration region (61), the third low-concentration region (62C), and the third contact region (63C) form the third reverse pin junction (60C), and
the high-concentration region (61) and the internal region (64) form the pn junction (60E) connected in a reverse direction to the first reverse pin junction (60A), the second reverse pin junction (60B), and the third reverse pin junction (60C).

### Clause B12

The TVS diode according to clause B11, where
the high-concentration region (61) includes
   a first region (66A) in which the first reverse pin junction (60A) is arranged,
   a second region (66B) in which the second reverse pin junction (60B) is arranged, and
   a third region (66C) in which the third reverse pin junction (60C) is arranged,
the second region (66B) includes a part shifted from both the first region (66A) and the third region (66C) in the first direction (Y).

### Clause B13

The TVS diode according to clause B12, where
the second region (66B) includes a part located between the first pin junction (30) and the third pin junction (50) in the second direction (X), and
the first region (66A) and the third region (66C) each include a part adjacent to the second pin junction (40) in the second direction (X).

### Clause B14

The TVS diode according to any one of clauses B11 to B13, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged toward the first surface (20S) of the semiconductor chip (20) at a position overlapping the first terminal high-concentration region (31) in the plan view,
   a first terminal contact region (33) of the first conductance type arranged in an outer portion of the first terminal low-concentration region (32),
   a first partitioning region (34) surrounding the first terminal low-concentration region (32) and arranged toward the first surface (20S) of the semiconductor chip (20) at a position overlapping the first terminal high-concentration region (31) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged toward the first surface (20S) of the semiconductor chip (20) at a position overlapping the second terminal high-concentration region (41) in the plan view,
   a second terminal contact region (43) of the first conductance type arranged in an outer portion of the second terminal low-concentration region (42),
   a second partitioning region (44) surrounding the second terminal low-concentration region (42) and arranged toward the first surface (20S) of the semiconductor chip (20) at a position overlapping the second terminal high-concentration region (41) in the plan view,
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged toward the first surface (20S) of the semiconductor chip (20) at a position overlapping the third terminal high-concentration region (51) in the plan view,
   a third terminal contact region (53) of the first conductance type arranged in an outer portion of the third terminal low-concentration region (52),
   a third partitioning region (54) surrounding the third terminal low-concentration region (52) and arranged toward the first surface (20S) of the semiconductor chip (20) at a position overlapping the third terminal high-concentration region (51) in the plan view,
the first terminal high-concentration region (31), the first terminal low-concentration region (32), and the first terminal contact region (33) form the first pin junction (30),
the second terminal high-concentration region (41), the second terminal low-concentration region (42), and the second terminal contact region (43) form the second pin junction (40), and
the third terminal high-concentration region (51), the third terminal low-concentration region (52), and the third terminal contact region (53) form the third pin junction (50).

### Clause B15

The TVS diode according to clause B14, further including:
an insulation layer (70) covering the first surface (20S);
a first connection electrode (81) arranged on the insulation layer (70) and connecting the first contact region (63A) and the first terminal contact region (33);
a second connection electrode (82) arranged on the insulation layer (70) and connecting the second contact region (63B) and the second terminal contact region (43);
a third connection electrode (83) arranged on the insulation layer (70) and connecting the third contact region (63C) and the third terminal contact region (53).

### Clause B16

The TVS diode according to clause B15, where
the first connection electrode (81), the second connection electrode (82), and the third connection electrode (83) are separated from one another in the second direction (X) in the plan view, and
the first connection electrode (81), the second connection electrode (82), and the third connection electrode (83) each extend in the first direction (Y) in the plan view.

### Clause B17

The TVS diode according to clause B15 or B16, further including:
a protection layer (74) covering the first connection electrode (81), the second connection electrode (82), and the third connection electrode (83);
a first terminal (101) arranged on the protection layer (74) and electrically connected to the first pin junction (30);
a second terminal (102) arranged on the protection layer (74) and electrically connected to the second pin junction (40), and
a third terminal (103) arranged on the protection layer (74) and electrically connected to the third pin junction (50), where
the protection layer (74) includes
   a first terminal opening (77A) partially exposing the first connection electrode (81),
   a second terminal opening (77B) partially exposing the second connection electrode (82), and
   a third terminal opening (77C) partially exposing the third connection electrode (83),
the first terminal (101) is electrically connected to the first connection electrode (81) through the first terminal opening (77A),
the second terminal (102) is electrically connected to the second connection electrode (82) through the second terminal opening (77B), and
the third terminal (103) is electrically connected to the third connection electrode (83) through the third terminal opening (77C).

### Clause B18

The TVS diode according to any one of clauses B2 to B4, where
the semiconductor chip (20) includes
   a third pin junction (50) and a fourth pin junction (130) that are for the first polarity direction and are arranged in a region located toward the first surface (20S) of the semiconductor chip (20), and
   a third reverse pin junction (60C) and a fourth reverse pin junction (60D) that are for the second polarity direction, are arranged in a region located toward the first surface (20S) of the semiconductor chip (20), and form the diode pair with the pn junction (60E),
the third pin junction (50) and the third reverse pin junction (60C) are arranged next to each other in the first direction (Y) in the plan view, the fourth pin junction (130) and the fourth reverse pin junction (60D) are arranged next to each other in the first direction (Y) in the plan view,
the third pin junction (50) and the third reverse pin junction (60C) are arranged adjacent to each other at a side of the second pin junction (40) and the second reverse pin junction (60B) opposite the first pin junction (30) and the first reverse pin junction (60A) in the second direction (X) in the plan view,
the fourth pin junction (130) and the fourth reverse pin junction (60D) are arranged adjacent to each other at a side of the third pin junction (50) and the third reverse pin junction (60C) opposite the second pin junction (40) and the second reverse pin junction (60B) in the second direction (X) in the plan view,
the third pin junction (50) and the second reverse pin junction (60B) are adjacent to each other in the second direction (X) in the plan view,
the third reverse pin junction (60C) and the second pin junction (40) are adjacent to each other in the second direction (X) in the plan view,
the fourth pin junction (130) and the third reverse pin junction (60C) are adjacent to each other in the second direction (X) in the plan view,
the fourth reverse pin junction (60D) and the third pin junction (50) are adjacent to each other in the second direction (X) in the plan view, and
the diode-paired region (60) includes a region (67C) located between the third pin junction (50) and the fourth pin junction (130) in a direction intersecting both the first direction (Y) and the second direction (Y) in the plan view.

### Clause B19

The TVS diode according to clause B1, where
the semiconductor chip (20) includes
   a third pin junction (50) and a fourth pin junction (130) that are for the first polarity direction and are arranged in a region located toward the first surface (20S) of the semiconductor chip (20), and
   a third reverse pin junction (60C) and a fourth reverse pin junction (60D) that are for the second polarity direction, are arranged in a region located toward the first surface (20S) of the semiconductor chip (20), and form the diode pair with the pn junction (60E),
the first pin junction (30), the first reverse pin junction (60A), and the second pin junction (40) are arranged next to one another in a first direction (Y) in the plan view, and the first reverse pin junction (60A) is located between the first pin junction (30) and the second pin junction (40) in the first direction (Y),
the third pin junction (50), the fourth reverse pin junction (60D), and the fourth pin junction (130) are arranged next to one another in the first direction (Y) in the plan view, and the fourth reverse pin junction (60D) is located between the third pin junction (50) and the fourth pin junction (130) in the first direction (Y),
the first pin junction (30), the third reverse pin junction (60C), and the third pin junction (50) are arranged next to one another in a second direction (X), orthogonal to the first direction (Y), in the plan view, and the third reverse pin junction (60C) is located between the first pin junction (30) and the third pin junction (50) in the second direction (X), and
the second pin junction (40), the second reverse pin junction (60B), and the fourth pin junction (130) are arranged next to one another in the second direction (X) in the plan view, and the second reverse pin junction (60B) is located between the second pin junction (40) and the fourth pin junction (130) in the second direction (X).

### Clause B20

The TVS diode according to any one of clauses B1 to B19, where
the first polarity direction is a direction in which forward current flows from the second surface (20R) toward the first surface (20S) in the thickness direction (Z) of the semiconductor chip (20), and
the second polarity direction is a direction in which forward current flows opposite to the first polarity direction in the thickness direction (Z) of the semiconductor chip (20).

### Clause B21

The TVS diode according to clause B18, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged toward the first surface (20S) of the semiconductor chip (20) at a position overlapping the first terminal high-concentration region (31) in the plan view,
   a first terminal contact region (33) of the first conductance type arranged in an outer portion of the first terminal low-concentration region (32),
   a first partitioning region (34) surrounding the first terminal low-concentration region (32) and arranged toward the first surface (20S) of the semiconductor chip (20) at a position overlapping the first terminal high-concentration region (31) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged toward the first surface (20S) of the semiconductor chip (20) at a position overlapping the second terminal high-concentration region (41) in the plan view,
   a second terminal contact region (43) of the first conductance type arranged in an outer portion of the second terminal low-concentration region (42),
   a second partitioning region (44) surrounding the second terminal low-concentration region (42) and arranged toward the first surface (20S) of the semiconductor chip (20) at a position overlapping the second terminal high-concentration region (41) in the plan view,
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged toward the first surface (20S) of the semiconductor chip (20) at a position overlapping the third terminal high-concentration region (51) in the plan view,
   a third terminal contact region (53) of the first conductance type arranged in an outer portion of the third terminal low-concentration region (52),
   a third partitioning region (54) surrounding the third terminal low-concentration region (52) and arranged toward the first surface (20S) of the semiconductor chip (20) at a position overlapping the third terminal high-concentration region (51) in the plan view,
   a fourth terminal high-concentration region (131) of the second conductance type separated from the first surface (20S) of the semiconductor chip (20) and arranged toward the second surface (20R), the fourth terminal high-concentration region (131) being separated from each of the first terminal high-concentration region (31), the second terminal high-concentration region (41), and the third terminal high-concentration region (51) in the plan view,
   a fourth terminal low-concentration region (132) of the first conductance type arranged toward the first surface (20S) of the semiconductor chip (20) at a position overlapping the fourth terminal high-concentration region (131) in the plan view,
   a fourth terminal contact region (133) of the first conductance type arranged in an outer portion of the fourth terminal low-concentration region (132), and
   a fourth partitioning region (134) surrounding the fourth terminal low-concentration region (132) and arranged toward the first surface (20S) of the semiconductor chip (20) at a position overlapping the fourth terminal high-concentration region (131) in the plan view,
the first terminal high-concentration region (31), the first terminal low-concentration region (32), and the first terminal contact region (33) form the first pin junction (30),
the second terminal high-concentration region (41), the second terminal low-concentration region (42), and the second terminal contact region (43) form the second pin junction (40),
the third terminal high-concentration region (51), the third terminal low-concentration region (52), and the third terminal contact region (53) form the third pin junction (50), and
the fourth terminal high-concentration region (131), the fourth terminal low-concentration region (132), and the fourth terminal contact region (133) form the fourth pin junction (130).

### Clause B22

The TVS diode according to clause B21, where
the semiconductor chip (20) includes the diode-paired region (60) including the first reverse pin junction (60A), the second reverse pin junction (60B), the third reverse pin junction (60C), the fourth reverse pin junction (60D), and the pn junction (60E),
the diode-paired region (60) includes
   a high-concentration region (61) of the first conductance type separated from the first surface (20S) of the semiconductor chip (20) and arranged toward the second surface (20R),
   a first low-concentration region (62A), a second low-concentration region (62B), a third low-concentration region (62C), and a fourth low-concentration region (62D) that are of the first conductance type, have a lower impurity concentration than the high-concentration region (61), and are separated from one another and toward the first surface (20S) of the semiconductor chip (20) at positions overlapping the high-concentration region (61) in the plan view,
   an isolation region (65) electrically isolating the first low-concentration region (62A), the second low-concentration region (62B), the third low-concentration region (62C), and the fourth low-concentration region (62D) from one another, and arranged toward the first surface (20S) of the semiconductor chip (20) at a position overlapping the high-concentration region (61) in the plan view,
   a first contact region (63A) of a second conductance type arranged in an outer portion of the first low-concentration region (62A),
   a second contact region (63B) of the second conductance type arranged in an outer portion of the second low-concentration region (62B),
   a third contact region (63C) of the second conductance type arranged in an outer portion of the third low-concentration region (62C),
   a fourth contact region (63D) of the second conductance type arranged in an outer portion of the fourth low-concentration region (62D), and
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form the first reverse pin junction (60A),
the high-concentration region (61), the second low-concentration region (62B), and the second contact region (63B) form the second reverse pin junction (60B),
the high-concentration region (61), the third low-concentration region (62C), and the third contact region (63C) form the third reverse pin junction (60C),
the high-concentration region (61), the fourth low-concentration region (62D), and the fourth contact region (63D) form the fourth reverse pin junction (60D), and
the high-concentration region (61) and the internal region (64) form the pn junction (60E) connected in a reverse direction to each of the first reverse pin junction (60A), the second reverse pin junction (60B), the third reverse pin junction (60C), and the fourth reverse pin junction (60D).

### Clause B23

The TVS diode according to clause B22, where the internal region (64) is arranged overlapping the first low-concentration region (62A), the second low-concentration region (62B), the third low-concentration region (62C), and the fourth low-concentration region (62D) in the plan view.

### Clause B24

The TVS diode according to clause B22 or B23, further including:
an insulation layer (70) covering the first surface (20S);
a first connection electrode (81) arranged on the insulation layer (70) and connecting the first contact region (63A) and the first terminal contact region (33);
a second connection electrode (82) arranged on the insulation layer (70) and connecting the second contact region (63B) and the second terminal contact region (43);
a third connection electrode (83) arranged on the insulation layer (70) and connecting the third contact region (63C) and the third terminal contact region (53); and
a fourth connection electrode (84) arranged on the insulation layer (70) and connecting the fourth contact region (63D) and the fourth terminal contact region (133).

### Clause B25

The TVS diode according to clause B24, further including:
a protection layer (74) covering the first connection electrode (81), the second connection electrode (82), the third connection electrode (83), and the fourth connection electrode (84);
a first terminal (101) arranged on the protection layer (74) and electrically connected to the first pin junction (30);
a second terminal (102) arranged on the protection layer (74) and electrically connected to the second pin junction (40);
a third terminal (103) arranged on the protection layer (74) and electrically connected to the third pin junction (50); and
a fourth terminal arranged on the protection layer (74) and electrically connected to the fourth pin junction (130), where
the protection layer (74) includes
   a first terminal opening (77A) partially exposing the first connection electrode (81),
   a second terminal opening (77B) partially exposing the second connection electrode (82),
   a third terminal opening (77C) partially exposing the third connection electrode (83), and
   a fourth terminal opening (77D) partially exposing the fourth connection electrode (84),
the first terminal (101) is electrically connected to the first connection electrode (81) through the first terminal opening (77A),
the second terminal (102) is electrically connected to the second connection electrode (82) through the second terminal opening (77B),
the third terminal (103) is electrically connected to the third connection electrode (83) through the third terminal opening (77C), and
the fourth terminal is electrically connected to the fourth connection electrode (84) through the fourth terminal opening (77D).

### Clause B26

The TVS diode according to any one of clauses B1 to B9, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first partitioning region (34) surrounding the first terminal low-concentration region (32) and arranged closer to the first surface (20S) than the first terminal high-concentration region (31) is at a position overlapping the first terminal high-concentration region (31) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42), and
   a second partitioning region (44) surrounding the second terminal low-concentration region (42) and arranged closer to the first surface (20S) than the second terminal high-concentration region (41) is at a position overlapping the second terminal high-concentration region (41) in the plan view,
the first terminal high-concentration region (31), the first terminal low-concentration region (32), and the first terminal contact region (33) form the first pin junction (30), and
the second terminal high-concentration region (41), the second terminal low-concentration region (42), and the second terminal contact region (43) form the second pin junction (40).

### Clause B27

The TVS diode according to any one of clauses B1 to B9, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first isolation trench (121A) arranged in the first surface (20S) and surrounding the first terminal high-concentration region (31), the first terminal low-concentration region (32), and the first terminal contact region (33),
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42), and
   a second isolation trench (121B) arranged in the first surface and surrounding the second terminal high-concentration region (41), the second terminal low-concentration region (42), and the second terminal contact region (43),
the first terminal high-concentration region (31), the first terminal low-concentration region (32), and the first terminal contact region (33) form the first pin junction (30), and
the second terminal high-concentration region (41), the second terminal low-concentration region (42), and the second terminal contact region (43) form the second pin junction (40).

### Clause B28

The TVS diode according to clause B27, where the semiconductor chip (20) includes
a first isolation-insulation layer (122A) arranged in the first isolation trench (121A), and
a second isolation-insulation layer (122B) arranged in the second isolation trench (121B).

### Clause B29

The TVS diode according to clause B28, further including:
a first isolation electrode (123A) embedded in the first isolation trench (121A) with the first isolation-insulation layer (122A) interposed; and
a second isolation electrode (123B) embedded in the second isolation trench (121B) with the second isolation-insulation layer (122B) interposed,
where the first isolation electrode (123A) and the second isolation electrode (123B) are both in an electrically floating state.

### Clause B30

The TVS diode according to clause B10, where
the semiconductor chip (20) includes
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32),
   a first isolation trench (121A) arranged in the first surface (20S) and surrounding the first terminal high-concentration region (31), the first terminal low-concentration region (32), and the first terminal contact region (33),
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42),
   a second isolation trench (121B) arranged in the first surface (20S) and surrounding the second terminal high-concentration region (41), the second terminal low-concentration region (42), and the second terminal contact region (43),
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged closer to the first surface (20S) than the third terminal high-concentration region (51) is at a position overlapping the third terminal high-concentration region (51) in the plan view,
   a third terminal contact region (53) of the first conductance type arranged in an outer portion of the third terminal low-concentration region (52), and
   a third isolation trench (121C) arranged in the first surface (20S) and surrounding the third terminal high-concentration region (51), the third terminal low-concentration region (52), and the third terminal contact region (53), where
the first terminal high-concentration region (31), the first terminal low-concentration region (32), and the first terminal contact region (33) form the first pin junction (30),
the second terminal high-concentration region (41), the second terminal low-concentration region (42), and the second terminal contact region (43) form the second pin junction (40), and
   the third terminal high-concentration region (51), the third terminal low-concentration region (52), and the third terminal contact region (53) form the third pin junction (50).

### Clause B31

The TVS diode according to clause B30, where the semiconductor chip (20) includes
a first isolation-insulation layer (122A) arranged in the first isolation trench (121A),
a second isolation-insulation layer (122B) arranged in the second isolation trench (121B), and
a third isolation-insulation layer (122C) arranged in the third isolation trench (121C).

### Clause B32

The TVS diode according to clause B31, further including:
a first isolation electrode (123A) embedded in the first isolation trench (121A) with the first isolation-insulation layer (122A) interposed;
a second isolation electrode (123B) embedded in the second isolation trench (121B) with the second isolation-insulation layer (122B) interposed;
a third isolation electrode (123C) embedded in the third isolation trench (121C) with the third isolation-insulation layer (122C) interposed,
where the first isolation electrode (123A), the second isolation electrode (123B), and the third isolation electrode (123C) are each in an electrically floating state.

### Clause C1

A TVS diode (10), including:
a semiconductor chip (20) including a first surface (20S) and a second surface (20R) at a side opposite the first surface (20S), where
the semiconductor chip (20) includes
   a first pin junction (30) for a first polarity direction, arranged toward the first surface (20S) of the semiconductor chip (20),
   a diode-paired region (60) including a first reverse pin junction (60A) for a second polarity direction, separated from the first pin junction (30) in a plan view taken in a thickness direction (Z) of the semiconductor chip (20), and a pn junction (60E) for the first polarity direction, forming a diode pair with the first reverse pin junction (60A),
   a first terminal high-concentration region (31) of the second conductance type separated from the first surface (20S) of the semiconductor chip (20) and arranged toward the second surface (20R),
   a first terminal low-concentration region (32) of the first conductance type arranged closer to the first surface (20S) than the first terminal high-concentration region (31) is at a position overlapping the first terminal high-concentration region (31) in the plan view,
   a first terminal contact region (33) of the first conductance type arranged in an outer portion of the first terminal low-concentration region (32), and
   a first buffer region (35) of the second conductance type contacting the first terminal high-concentration region (31) between the first terminal high-concentration region (31) and the first terminal low-concentration region (32) in the thickness direction (Z) of the semiconductor chip (20), and
the first terminal contact region (33), the first terminal low-concentration region (32), and the first buffer region (35) form a pin diode.

### Clause C2

The TVS diode according to clause C1, where
the semiconductor chip (20) includes a first partitioning region (34) surrounding the first terminal low-concentration region (32) and arranged closer to the first surface (20S) than the first terminal high-concentration region (31) is at a position overlapping the first terminal high-concentration region (31) in the plan view, and
the first partitioning region (34) is arranged surrounding the first buffer region (35) in the plan view.

### Clause C3

The TVS diode according to clause C1 or C2, where the first buffer region (35) has a lower second conductance type impurity concentration than the first terminal high-concentration region (31).

### Clause C4

The TVS diode according to any one of clauses C1 to C3, where the first buffer region (35) has a second conductance type impurity concentration that decreases in the thickness direction (Z) of the semiconductor chip (20) from the first terminal high-concentration region (31) toward the first terminal low-concentration region (32).

### Clause C5

The TVS diode according to clause C3 or C4, where the first buffer region (35) has a second conductance type impurity concentration that is greater than or equal to a first conductance type impurity concentration in the first terminal low-concentration region (32).

### Clause C6

The TVS diode according to any one of clauses C1 to C5, where
the diode-paired region (60) includes
   a high-concentration region (61) of the first conductance type separated from the first surface (20S) of the semiconductor chip (20) and arranged toward the second surface (20R),
   a first low-concentration region (62A) having a lower impurity concentration than the high-concentration region (61) and arranged closer to the first surface (20S) than the high-concentration region (61) is separated from the high-concentration region (61) at a position overlapping the high-concentration region (61) in the plan view,
   a first contact region (63A) of a second conductance type arranged in an outer portion of the first low-concentration region (62A), and
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form the first reverse pin junction (60A), and
the high-concentration region (61) and the internal region (64) form the pn junction (60E) connected in a reverse direction to the first reverse pin junction (60A).

### Clause C7

The TVS diode according to any one of clauses C1 to C6, where
the semiconductor chip (20) includes
   a second pin junction (40) for the first polarity direction, arranged toward the first surface (20S) of the semiconductor chip (20) in a region separated from the first pin junction (30) in the plan view,
   a second terminal high-concentration region (41) of the second conductance type separated from the first surface (20S) of the semiconductor chip (20) and arranged toward the second surface (20R), the second terminal high-concentration region (41) being separated from the first terminal high-concentration region (31) in the plan view,
   a second terminal low-concentration region (42) of the first conductance type arranged closer to the first surface (20S) than the second terminal high-concentration region (41) is at a position overlapping the second terminal high-concentration region (41) in the plan view,
   a second terminal contact region (43) of the first conductance type arranged in an outer portion of the second terminal low-concentration region (42), and
   a second buffer region (45) of the first conductance type contacting the second terminal high-concentration region (41) between the second terminal high-concentration region (41) and the second terminal low-concentration region (42) in the thickness direction (Z) of the semiconductor chip (20), and
the second buffer region (45), the second terminal low-concentration region (42), and the second terminal contact region (43) form the second pin junction (40).

### Clause C8

The TVS diode according to clause C7, where
the semiconductor chip (20) includes a second partitioning region (44) surrounding the second terminal low-concentration region (42) and arranged closer to the first surface (20S) than the second terminal high-concentration region (41) is at a position overlapping the second terminal high-concentration region (41) in the plan view, and
the second partitioning region (44) is arranged surrounding the second buffer region (45) in the plan view.

### Clause C9

The TVS diode according to clause C7 or C8, where the second buffer region (45) has a lower second conductance type impurity concentration than the second terminal high-concentration region (41).

### Clause C10

The TVS diode according to any one of clauses C7 to C9, where the second buffer region (45) has a second conductance type impurity concentration that decreases in the thickness direction (Z) of the semiconductor chip (20) from the second terminal high-concentration region (41) toward the second terminal low-concentration region (42).

### Clause C11

The TVS diode according to clause C9 or C10, where the second conductance type impurity concentration in the second buffer region (45) is greater than or equal to a first conductance type impurity concentration in the second terminal low-concentration region (42).

### Clause C12

The TVS diode according to any one of clauses C7 to C11, where
the diode-paired region (60) includes
   a second reverse pin junction (60B) for the second polarity direction, forming the diode pair with the pn junction (60E),
   a high-concentration region (61) of the first conductance type separated from the first surface (20S) of the semiconductor chip (20) and arranged toward the second surface (20R),
a first low-concentration region (62A) and a second low-concentration region (62B) that have a lower impurity concentration than the high-concentration region (61) and are separated from each other and closer to the first surface (20S) than the high-concentration region (61) is at positions overlapping the high-concentration region (61) in the plan view,
an isolation region (65) electrically isolating the first low-concentration region (62A) and the second low-concentration region (62B), and arranged closer to the first surface (20S) than the high-concentration region (61) is at a position overlapping the high-concentration region (61) in the plan view,
   a first contact region (63A) of a second conductance type arranged in an outer portion of the first low-concentration region (62A),
   a second contact region (63B) of the second conductance type arranged in an outer portion of the second low-concentration region (62B),
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form the first reverse pin junction (60A),
the high-concentration region (61), the second low-concentration region (62B), and the second contact region (63B) form the second reverse pin junction (60B), and
the high-concentration region (61) and the internal region (64) form the pn junction (60E) connected in a reverse direction to the first reverse pin junction (60A) and the second reverse pin junction (60B).

### Clause C13

The TVS diode according to clause C12, where the internal region (64) has edges located inward from edges of the high-concentration region (61) in the plan view.

### Clause C14

The TVS diode according to clause C13, where the edges of the internal region (64) are located at positions overlapping the isolation region (65) in the plan view.

### Clause C15

The TVS diode according to any one of clauses C12 to C14, where
the edges of the internal region (64) form corners in the plan view, and
the corners are each curved in the plan view.

### Clause C16

The TVS diode according to clause C7, where the semiconductor chip (20) includes
a first isolation trench (121A) arranged in the first surface (20S) and partitioning the first pin junction (30) from the diode-paired region (60), and
a second isolation trench (121B) arranged in the first surface (20S) and partitioning the second pin junction (40) from the diode-paired region (60).

### Clause C17

The TVS diode according to clause C16, further including:
a first isolation-insulation layer (122A) arranged in the first isolation trench (121A); and
a second isolation-insulation layer (122B) arranged in the second isolation trench (121B).

### Clause C18

The TVS diode according to clause C17, further including:
a first isolation electrode (123A) embedded in the first isolation trench (121A) with the first isolation-insulation layer (122A) interposed; and
a second isolation electrode (123B) embedded in the second isolation trench (121B) with the second isolation-insulation layer (122B) interposed,
where the first isolation electrode (123A) and the second isolation electrode (123B) are both in an electrically floating state.

### Clause C19

The TVS diode according to any one of clauses C1 to C18, where
the first polarity direction is a direction in which forward current flows from the second surface (20R) toward the first surface (20S) in the thickness direction (Z) of the semiconductor chip (20), and
the second polarity direction is a direction in which forward current flows opposite to the first polarity direction in the thickness direction (Z) of the semiconductor chip (20).

### Clause C20

The TVS diode according to any one of clauses C7 to C18, where
the semiconductor chip (20) includes
   a third pin junction (50) for the first polarity direction, arranged toward the first surface (20S) of the semiconductor chip (20) in a region separated from both the first pin junction (30) and the second pin junction (40) in the plan view,
   a third terminal high-concentration region (51) of the second conductance type separated from the first surface (20S) of the semiconductor chip (20) and arranged toward the second surface (20R), the third terminal high-concentration region (51) being separated from both the first terminal high-concentration region (31) and the second terminal high-concentration region (41) in the plan view,
   a third terminal low-concentration region (52) of the first conductance type arranged closer to the first surface (20S) than the third terminal high-concentration region (51) is at a position overlapping the third terminal high-concentration region (51) in the plan view,
   a third terminal contact region (53) of the first conductance type arranged in an outer portion of the third terminal low-concentration region (52), and
   a third buffer region (55) of the first conductance type contacting the third terminal high-concentration region (51) between the third terminal high-concentration region (51) and the third terminal low-concentration region (52) in the thickness direction (Z) of the semiconductor chip (20), and
the third buffer region (55), the third terminal low-concentration region (52), and the third terminal contact region (53) form the third pin junction (50).

### Clause C21

The TVS diode according to clause C20, where
the semiconductor chip (20) includes a third partitioning region (54) surrounding the third terminal low-concentration region (52) and arranged closer to the first surface (20S) than
the third terminal high-concentration region (51) is at a position overlapping the third terminal high-concentration region (51) in the plan view,
where the third partitioning region (54) is arranged surrounding the third buffer region (55) in the plan view.

### Clause C22

The TVS diode according to clause C20 or C21, where the third buffer region (55) has a lower second conductance type impurity concentration than the third terminal high-concentration region (51).

### Clause C23

The TVS diode according to clause C22, where the second conductance type impurity concentration in the third buffer region (55) decreases in the thickness direction (Z) of the semiconductor chip (20) from the third terminal high-concentration region (51) toward the third terminal low-concentration region (52).

### Clause C24

The TVS diode according to clause C23, where the second conductance type impurity concentration in the third buffer region (55) is greater than or equal to a first conductance type impurity concentration in the third terminal low-concentration region (52).

### Clause C25

The TVS diode according to any one of clauses C20 to C24, where
the diode-paired region (60) includes
   a second reverse pin junction (60B) and a third reverse pin junction (60C) that are for the second polarity direction and form a diode pair with the pn junction (60E),
   a high-concentration region (61) of the first conductance type separated from the first surface (20S) of the semiconductor chip (20) and arranged toward the second surface (20R),
   a first low-concentration region (62A), a second low-concentration region (62B), and a third low-concentration region (62C) that are of the first conductance type, have a lower impurity concentration than the high-concentration region (61), and are separated from one another and closer to the first surface (20S) than the high-concentration region (61) is at positions overlapping the high-concentration region (61) in the plan view,
   an isolation region (65) electrically isolating the first low-concentration region (62A), the second low-concentration region (62B), and the third low-concentration region (62C), and arranged closer to the first surface (20S) than the high-concentration region (61) is at a position overlapping the high-concentration region (61) in the plan view,
   a first contact region (63A) of a second conductance type arranged in an outer portion of the first low-concentration region (62A),
   a second contact region (63B) of the second conductance type arranged in an outer portion of the second low-concentration region (62B),
   a third contact region (63C) of the second conductance type arranged in an outer portion of the third low-concentration region (62C), and
   an internal region (64) of the second conductance type contacting the high-concentration region (61) and arranged closer to the second surface (20R) than the high-concentration region (61) is at a position overlapping the high-concentration region (61) in the plan view,
the high-concentration region (61), the first low-concentration region (62A), and the first contact region (63A) form the first reverse pin junction (60A),
the high-concentration region (61), the second low-concentration region (62B), and the second contact region (63B) form the second reverse pin junction (60B),
the high-concentration region (61), the third low-concentration region (62C), and the third contact region (63C) form the third reverse pin junction (60C), and
the high-concentration region (61) and the internal region (64) form the pn junction (60E) connected in a reverse direction to the first reverse pin junction (60A), the second reverse pin junction (60B), and the third reverse pin junction (60C).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A TVS diode, comprising:
a semiconductor chip including a first surface and a second surface at a side opposite the first surface, wherein
the semiconductor chip includes
a first pin junction for a first polarity direction, arranged toward the first surface of the semiconductor chip,
a second pin junction for the first polarity direction, arranged toward the first surface of the semiconductor chip in a region separated from the first pin junction in a plan view taken in a thickness direction of the semiconductor chip, and
a diode-paired region separated from both the first pin junction and the second pin junction in the plan view,
the diode-paired region includes
a high-concentration region of a first conductance type separated from the first surface of the semiconductor chip and arranged toward the second surface,
a first low-concentration region and a second low-concentration region that have a lower impurity concentration than the high-concentration region and are separated from each other and closer to the first surface than the high-concentration region is at positions overlapping the high-concentration region in the plan view,
an isolation region isolating the first low-concentration region and the second low-concentration region, and arranged closer to the first surface than the high-concentration region is at a position overlapping the high-concentration region in the plan view,
a first contact region of a second conductance type arranged in an outer portion of the first low-concentration region,
a second contact region of the second conductance type arranged in an outer portion of the second low-concentration region, and
an internal region of the second conductance type contacting the high-concentration region and arranged closer to the second surface than the high-concentration region is at a position overlapping the high-concentration region in the plan view,
the high-concentration region, the first low-concentration region, and the first contact region form a first reverse pin junction for a second polarity direction,
the high-concentration region, the second low-concentration region, and the second contact region form a second reverse pin junction for the second polarity direction,
the high-concentration region and the internal region form a pn junction for the first polarity direction, connected in a reverse direction to the first reverse pin junction and the second reverse pin junction, and
the internal region is arranged overlapping both the first low-concentration region and the second low-concentration region in the plan view.

2. The TVS diode according to claim 1, wherein
the first polarity direction is a direction in which forward current flows from the second surface toward the first surface in the thickness direction of the semiconductor chip, and
the second polarity direction is a direction in which forward current flows opposite to the first polarity direction in the thickness direction of the semiconductor chip.

3. The TVS diode according to claim 1, wherein
the isolation region includes an exposed surface exposed from the first surface, and
the TVS diode comprises wiring contacting the exposed surface.

4. The TVS diode according to claim 3, wherein
the semiconductor chip includes
a first terminal high-concentration region of the second conductance type separated from the first surface of the semiconductor chip and arranged toward the second surface,
a first terminal low-concentration region of the first conductance type arranged closer to the first surface than the first terminal high-concentration region is at a position overlapping the first terminal high-concentration region in the plan view,
a first partitioning region surrounding the first terminal low-concentration region and arranged closer to the first surface than the first terminal high-concentration region is at a position overlapping the first terminal high-concentration region in the plan view,
a first terminal contact region of the first conductance type arranged in an outer portion of the first terminal low-concentration region,
a second terminal high-concentration region of the second conductance type separated from the first surface of the semiconductor chip and arranged toward the second surface, the second terminal high-concentration region being separated from the first terminal high-concentration region in the plan view,
a second terminal low-concentration region of the first conductance type arranged closer to the first surface than the second terminal high-concentration region is at a position overlapping the second terminal high-concentration region in the plan view,
a second terminal contact region of the first conductance type arranged in an outer portion of the second terminal low-concentration region, and
a second partitioning region surrounding the second terminal low-concentration region and arranged closer to the first surface than the second terminal high-concentration region is at a position overlapping the second terminal high-concentration region in the plan view,
the first terminal high-concentration region, the first terminal low-concentration region, and the first terminal contact region form the first pin junction, and
the second terminal high-concentration region, the second terminal low-concentration region, and the second terminal contact region form the second pin junction.

5. The TVS diode according to claim 4, further comprising:
an insulation layer covering the first surface;
a first connection electrode arranged on the insulation layer and connecting the first contact region and the first terminal contact region; and
a second connection electrode arranged on the insulation layer and connecting the second contact region and the second terminal contact region.

6. The TVS diode according to claim 5, wherein
the isolation region includes
a first isolation region overlapping the first connection electrode in the plan view,
a second isolation region overlapping the second connection electrode in the plan view, and
a wiring connection region connected to the wiring, and
the wiring connection region is arranged partially surrounding each of the first reverse pin junction and the second reverse pin junction in the plan view.

7. The TVS diode according to claim 6, wherein the wiring is arranged individually and partially surrounding both the first connection electrode and the second connection electrode in the plan view.

8. The TVS diode according to claim 6, wherein the wiring has a larger area than the first connection electrode in the plan view.

9. The TVS diode according to claim 6, wherein the wiring has a smaller area than the isolation region in the plan view.

10. The TVS diode according to claim 9, wherein the area of the wiring is within a range from 75% to 97%, inclusive, of the area of the isolation region in the plan view.

11. The TVS diode according to claim 5, further comprising
a protection layer covering the first connection electrode and the second connection electrode;
a first terminal arranged on the protection layer and electrically connected to the first pin junction; and
a second terminal arranged on the protection layer and electrically connected to the second pin junction, wherein
the protection layer includes
a first terminal opening partially exposing the first connection electrode, and
a second terminal opening partially exposing the second connection electrode,
the first terminal is electrically connected to the first connection electrode through the first terminal opening, and
the second terminal is electrically connected to the second connection electrode through the second terminal opening.

12. The TVS diode according to claim 1, wherein the internal region has edges located inward from edges of the high-concentration region in the plan view.

13. The TVS diode according to claim 12, wherein
the edges of the internal region form corners in the plan view, and
the corners are each curved in the plan view.

14. The TVS diode according to claim 12, where the edges of the internal region are located at positions overlapping the isolation region in the plan view.

15. The TVS diode according to claim 1, wherein
the semiconductor chip includes
a first terminal high-concentration region of the second conductance type separated from the first surface of the semiconductor chip and arranged toward the second surface,
a first terminal low-concentration region of the first conductance type arranged closer to the first surface than the first terminal high-concentration region is at a position overlapping the first terminal high-concentration region in the plan view,
a first terminal contact region of the first conductance type arranged in an outer portion of the first terminal low-concentration region,
a first isolation trench arranged in the first surface and surrounding the first terminal high-concentration region, the first terminal low-concentration region, and the first terminal contact region,
a second terminal high-concentration region of the second conductance type separated from the first surface of the semiconductor chip and arranged toward the second surface, the second terminal high-concentration region being separated from the first terminal high-concentration region in the plan view,
a second terminal low-concentration region of the first conductance type arranged closer to the first surface than the second terminal high-concentration region is at a position overlapping the second terminal high-concentration region in the plan view,
a second terminal contact region of the first conductance type arranged in an outer portion of the second terminal low-concentration region, and
a second isolation trench arranged in the first surface and surrounding the second terminal high-concentration region, the second terminal low-concentration region, and the second terminal contact region,
the first terminal high-concentration region, the first terminal low-concentration region, and the first terminal contact region form the first pin junction, and
the second terminal high-concentration region, the second terminal low-concentration region, and the second terminal contact region form the second pin junction.

16. The TVS diode according to claim 15, wherein the semiconductor chip includes
a first isolation-insulation layer arranged in the first isolation trench, and
a second isolation-insulation layer arranged in the second isolation trench.

17. The TVS diode according to claim 16, further comprising:
a first isolation electrode embedded in the first isolation trench with the first isolation-insulation layer interposed;
a second isolation electrode embedded in the second isolation trench with the second isolation-insulation layer interposed,
wherein the first isolation electrode and the second isolation electrode are both in an electrically floating state.

18. The TVS diode according to claim 15, wherein the high-concentration region is adjacent to at least one of the first isolation trench and the second isolation trench in the plan view.
